(19) United States
(12) Patent Application Publication
(10) Pub. No.: US 2024/0153944 A1
(43) Pub. Date: May 9, 2024

(54) SEMICONDUCTOR DEVICE

(71) Applicant: ROHM CO., LTD., Kyoto-shi (JP)

(72) Inventors: Yuji OSUMI, Kyoto-shi (JP); Hajime OKUDA, Kyoto-shi (JP)

(73) Assignee: ROHM CO., LTD., Kyoto-shi (JP)

(21) Appl. No.: 18/414,478

(22) Filed: Jan. 17, 2024

Related U.S. Application Data
(63) Continuation of application No. PCT/JP2022/023152, filed on Jun. 8, 2022.

(30) Foreign Application Priority Data
Jul. 21, 2021 (JP) 2021-121046
Jul. 21, 2021 (JP) 2021-121047

(51) Int. Cl. H01L 27/02; H01L 29/06; H01L 29/423; H01L 29/866

(52) U.S. Cl. CPC H01L 27/0255; H01L 29/0615; H01L 29/0696; H01L 29/4236; H01L 29/866

(57) ABSTRACT

The semiconductor device includes a chip which has a main surface, a diode region which is arranged in the main surface, trench structures which are formed in the main surface at an interval in the diode region, the trench structures each having an electrode structure including an upper electrode and a lower electrode which are embedded in a trench across an insulator in an up/down direction, and a diode which has a pn-junction portion that is formed in a surface layer portion of the main surface at a region between the trench structures.

### CROSS-REFERENCE TO RELATED APPLICATIONS

The present application is a bypass continuation of International Patent Application No. PCT/JP2022/023152, filed on Jun. 8, 2022, which claims priorities to Japanese Patent Application No. 2021-121046 filed in the Japan Patent Office on Jul. 21, 2021 and Japanese Patent Application No. 2021-121047 filed in the Japan Patent Office on Jul. 21, 2021, and the entire disclosures of these applications are incorporated herein by reference.

### BACKGROUND

### 1. Field of the Disclosure

The present disclosure relates to a semiconductor device.

### 2. Description of the Related Art

In U.S. Patent Application Publication No. 2015/0207407, FIG. 6 discloses a semiconductor device having a semiconductor layer, two trench field plate structures and a rectifier element. The trench field plate structure includes a field electrode which is embedded in a trench. The rectifier element includes an n-type semiconductor region and a p-type semiconductor region and is formed in the semiconductor layer at a region between the two trench field plate structures.

### BRIEF DESCRIPTION OF THE DRAWINGS

FIG. 1 is a schematic plan view of a semiconductor device according to a first embodiment.

FIG. 2 is a schematic cross-sectional view of the semiconductor device shown in FIG. 1.

FIG. 3 is a schematic block circuit diagram which shows an electric structure of the semiconductor device shown in FIG. 1.

FIG. 4 is an equivalent circuit diagram of a main transistor and a monitor transistor shown in FIG. 3.

FIG. 5 is another equivalent circuit diagram of the main transistor and the monitor transistor shown in FIG. 4.

FIG. 6A is a circuit diagram which shows an operation example of the main transistor.

FIG. 6B is a circuit diagram which shows an operation example of the main transistor.

FIG. 6C is a circuit diagram which shows an operation example of the main transistor.

FIG. 7 is a block circuit diagram which shows a specific electric configuration example of the semiconductor device shown in FIG. 1 (=a configuration example where a two-system main transistor and a two-system monitor transistor are applied to the semiconductor device according to the first embodiment).

FIG. 8 is an enlarged view of a region VIII shown in FIG. 1 and a plan view which shows a layout example of an output region 7.

FIG. 9 is an enlarged view of a region IX shown in FIG. 8.

FIG. 10 is an enlarged view of a region X shown in FIG. 8.

FIG. 11 is a cross-sectional view taken along line XI-XI shown in FIG. 9.

FIG. 12 is a cross-sectional view taken along line XII-XII shown in FIG. 9.

FIG. 13 is a cross-sectional view taken along line XIII-XIII shown in FIG. 9.

FIG. 14 is a cross-sectional view taken along line XIV-XIV shown in FIG. 9.

FIG. 15 is a cross-sectional perspective view which shows a first channel configuration example.

FIG. 16 is a cross-sectional perspective view which shows a second channel configuration example.

FIG. 17 is a cross-sectional perspective view which shows a third channel configuration example.

FIG. 18 is a cross-sectional perspective view which shows a fourth channel configuration example.

FIG. 19 is an enlarged view of a region XIX shown in FIG. 8.

FIG. 20 is a cross-sectional view taken along line XX-XX shown in FIG. 19.

FIG. 21 is a cross-sectional view taken along line XXI-XXI shown in FIG. 19.

FIG. 22 is a cross-sectional view taken along line XXII-XXII shown in FIG. 19.

FIG. 23 is a cross-sectional view taken along line XXIII-XXIII shown in FIG. 19.

FIG. 24 is a cross-sectional perspective view which shows an output region and a first temperature detecting region.

FIG. 25 is an enlarged plan view which partially shows another embodiment example of the first temperature detecting region.

FIG. 26 is a graph which shows temperature characteristics of a first temperature-sensitive diode shown in FIG. 19.

FIG. 27 is an enlarged view of a region XXVII shown in FIG. 1.

FIG. 28 is a graph which shows breakdown characteristics of an ESD diode shown in FIG. 27.

FIG. 29 is a graph which shows a relationship of a breakdown current of the ESD diode with a planar area of the ESD diode shown in FIG. 27.

FIG. 30A is a cross-sectional perspective view which shows an operation example of a main transistor.

FIG. 30B is a cross-sectional perspective view which shows an operation example of the main transistor.

FIG. 30C is a cross-sectional perspective view which shows an operation example of the main transistor.

FIG. 31 is a timing chart which shows a control example of the main transistor.

FIG. 32 is a schematic plan view which shows a semiconductor device according to a second embodiment.

FIG. 33 is a schematic cross-sectional view of the semiconductor device shown in FIG. 32.

FIG. 34 is a schematic plan view which shows a semiconductor device according to a third embodiment.

FIG. 35 is a schematic cross-sectional view of the semiconductor device shown in FIG. 34.

FIG. 36 is a schematic plan view which shows a semiconductor module according to a fourth embodiment.

### DETAILED DESCRIPTION OF THE PREFERRED EMBODIMENTS

Hereinafter, a detailed description of the embodiments shall be given. The attached drawings are not drawn precisely but are schematic views and are not necessarily matched in scale, etc. In addition, the same reference signs are given to corresponding structures in the attached drawings and redundant descriptions shall be omitted or simplified. A description of a structure, before omission or simplification, is applied to a structure the description of which is omitted or simplified.

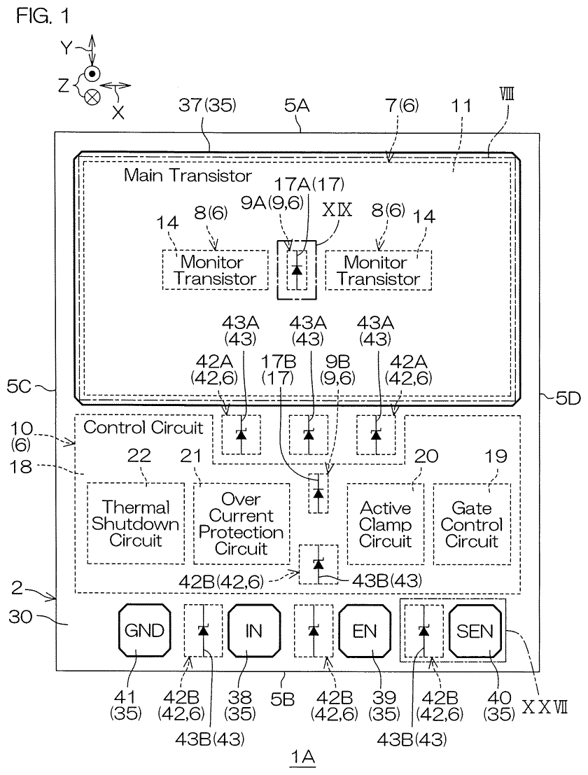

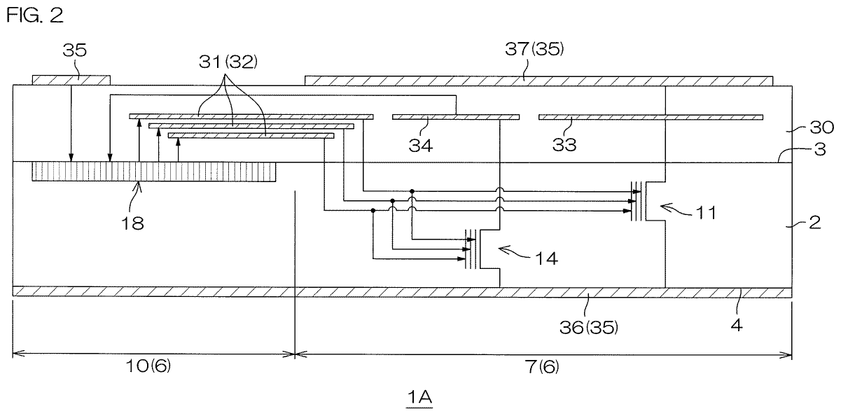

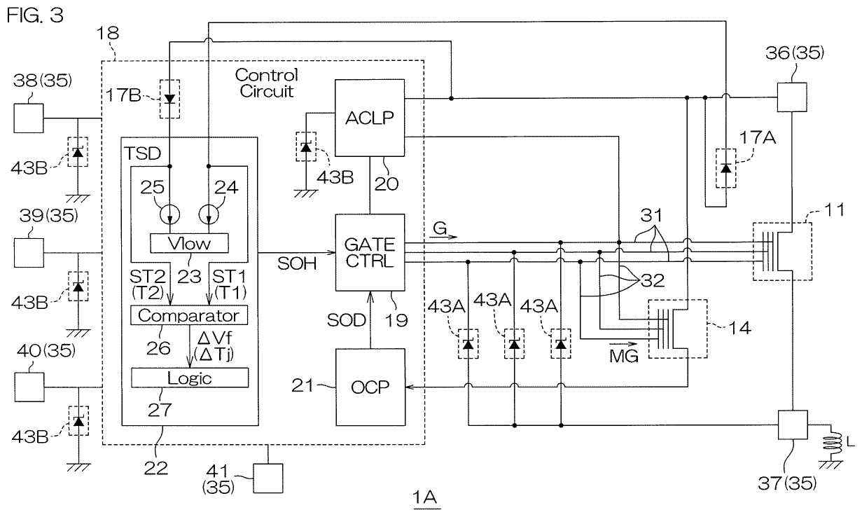

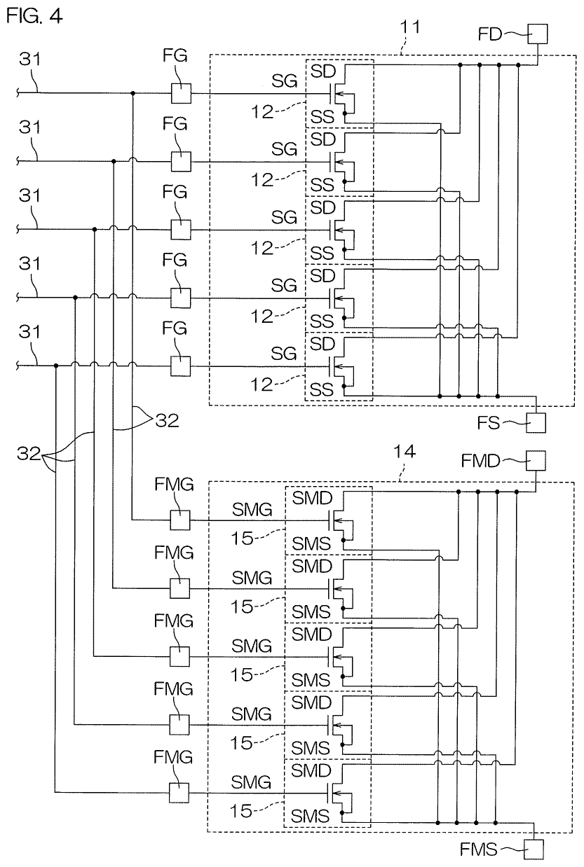

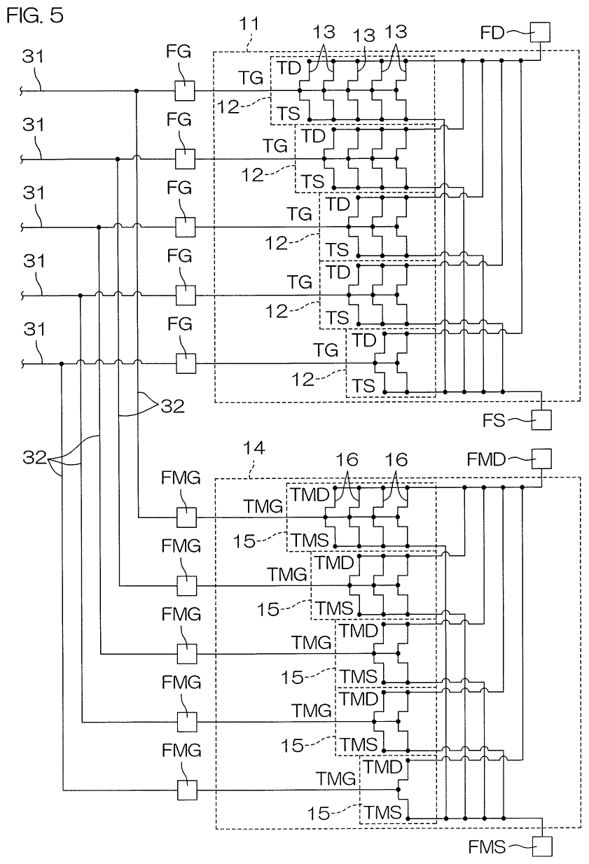

FIG. 1 is a schematic plan view of a semiconductor device 1A according to a first embodiment. FIG. 2 is a schematic cross-sectional view of the semiconductor device 1A shown in FIG. 1. FIG. 3 is a schematic block circuit diagram which shows an electric structure of the semiconductor device 1A shown in FIG. 1. FIG. 4 is an equivalent circuit diagram of the main transistor 11 and the monitor transistor 14 shown in FIG. 3. FIG. 5 is another equivalent circuit diagram of the main transistor 11 and the monitor transistor 14 shown in FIG. 4. In FIG. 3, an example where an inductive load L is connected to a source terminal 37 is shown.

With reference to FIG. 1, in this embodiment, the semiconductor device 1A includes a chip 2 (semiconductor chip) which is formed in a rectangular parallelepiped shape. The chip 2 may be constituted of the chip 2 which includes an Si monocrystal or an SiC monocrystal. In this embodiment, the chip 2 is constituted of the chip 2 which includes an Si monocrystal.

The chip 2 has a first main surface 3 on one side, a second main surface 4 on the other side, and first to fourth side surfaces 5A to 5D which connect the first main surface 3 and the second main surface 4. The first main surface 3 and the second main surface 4 are formed in a quadrilateral shape in a plan view as viewed from a normal direction Z thereto (hereinafter, simply referred to as “plan view”).

The first main surface 3 is a circuit surface on which an electric circuit is formed. The second main surface 4 is a mounting surface and may be constituted of a ground surface having ground marks. The first to fourth side surfaces 5A to 5D include a first side surface 5A, a second side surface 5B, a third side surface 5C, and a fourth side surface 5D. The first side surface 5A and the second side surface 5B extend in a first direction X along the first main surface 3 and face each other (face opposite to each other) in a second direction Y that intersects (specifically, orthogonal to) in the first direction X. The third side surface 5C and the fourth side surface 5D extend in the second direction Y and oppose the first direction X.

The semiconductor device 1A includes a circuit region 6 which is arranged in the first main surface 3. The circuit region 6 is a region which has an electric circuit and includes a plurality of device regions that are demarcated according to a type of a functional device which constitutes a part of the electric circuit. In this embodiment, the circuit region 6 includes an output region 7, at least one current detecting region 8, at least one temperature detecting region 9 and a control region 10.

In this embodiment, the semiconductor device 1A includes the plurality of current detecting regions 8 and the plurality of temperature detecting regions 9. The output region 7, the current detecting region 8, the temperature detecting region 9 and the control region 10 may be respectively referred to as a “first device region,” a “second device region,” a “third device region” and a “fourth device region.”

The output region 7 is a region that has a circuit device configured so as to generate an output signal which is to be output to the outside. In this embodiment, the output region 7 is demarcated in a region on the first side surface 5A side in the first main surface 3. The output region 7 may be demarcated in a quadrilateral shape or may be demarcated in a polygonal shape other than the quadrilateral shape in a plan view. The position, size and planar shape of the output region 7 are arbitrary and not restricted to a particular mode.

The plurality of current detecting regions 8 are regions each having a circuit device which is configured so as to generate an output monitor signal that monitors an output signal. It is preferable that the plurality of current detecting regions 8 are adjacent to the output region 7. In this embodiment, the plurality of current detecting regions 8 each have a planar area which is less than a planar area of the output region 7 and are arranged at an inner portion of the output region 7. Specifically, the current detecting region 8 is formed by utilizing a part of the output region 7.

The plurality of current detecting regions 8 are preferably each arranged so as to be adjacent to the output region 7 at least in two directions in a plan view. The plurality of current detecting regions 8 may be each adjacent to the output region 7 in four directions in a plan view. The position, size and planar shape of the current detecting region 8 are arbitrary and not restricted to a particular mode.

The control region 10 is a region that has plural types of circuit devices which are configured so as to generate a control signal which controls the output region 7. In this embodiment, the control region 10 is demarcated in a region on the second side surface 5B side with respect to the output region 7 and faces the output region 7 in the second direction Y. The control region 10 may be demarcated in a quadrilateral shape or may be demarcated in a polygonal shape other than the quadrilateral shape in a plan view. The position, size and planar shape of the control region are arbitrary and not restricted to a particular mode.

The control region 10 preferably has a planar area which is not more than a planar area of the output region 7. The control region 10 is preferably formed so as to have an area ratio of not less than 0.1 and not more than 1 with respect to the output region 7. The area ratio is a ratio of the planar area of the control region 10 to the planar area of the output region 7. The area ratio is preferably less than 1. As a matter of course, the control region 10 that has a planar area exceeding the planar area of the output region 7 may be adopted.

The plurality of temperature detecting regions 9 are regions each having a circuit device which is configured so as to detect a temperature of the chip 2. The plurality of temperature detecting regions 9 are arranged in the first main surface 3 at an interval so that the temperature of the chip 2 can be detected in different regions. In this embodiment, the plurality of temperature detecting regions 9 include a first temperature detecting region 9A and a second temperature detecting region 9B. The first temperature detecting region 9A is arranged so as to be adjacent to the output region 7 and detects a temperature of the output region 7. The second temperature detecting region 9B is arranged so as to be adjacent to the control region 10 and detects a temperature of the control region 10.

In this embodiment, the first temperature detecting region 9A has a planar area less than a planar area of the output region 7 and is demarcated at an inner portion of the output region 7. That is, the first temperature detecting region 9A is surrounded by the output region 7 in a plan view. Here, “surrounded” includes a mode in which an entire periphery of the first temperature detecting region 9A is surrounded by the output region 7 and also includes a mode in which the first temperature detecting region 9A is adjacent to the output region 7 at least in two directions.

For example, the first temperature detecting region 9A may be sandwiched by the output region 7 from one side and from the other side in the first direction X or may be sandwiched by the output region 7 from one side and from the other side in the second direction Y. Further, the first temperature detecting region 9A may be adjacent to the output region 7 in the first direction X and in the second direction Y. In this case, the first temperature detecting region 9A may be adjacent to the output region 7 in two directions or in three directions. In this embodiment, the first temperature detecting region 9A is adjacent to the output region 7 in four directions in a plan view.

In this embodiment, the temperature detecting region 9 is arranged inside the single output region 7 together with the current detecting region 8. The first temperature detecting region 9A faces the current detecting region 8 in one of or in both of the first direction X and the second direction Y (in this embodiment, in the first direction X). The position, size and planar shape of the first temperature detecting region 9A are arbitrary and not restricted to a particular mode. The first temperature detecting region 9A preferably has a planar area less than a planar area of the control region 10.

The second temperature detecting region 9B is preferably adjacent to the control region 10 at least in two directions in a plan view. In this embodiment, the second temperature detecting region 9B has a planar area less than a planar area of the control region 10 and is demarcated at an inner portion of the control region 10. That is, in this embodiment, the second temperature detecting region 9B is adjacent to the control region 10 in four directions in a plan view.

The position, size and planar shape of the second temperature detecting region 9B are arbitrary and not restricted to a particular mode. The second temperature detecting region 9B preferably has a planar area less than a planar area of the output region 7. The second temperature detecting region 9B preferably has a planar area less than a planar area of the control region 10. The second temperature detecting region 9B preferably has a planar area which is substantially equal to a planar area of the first temperature detecting region 9A.

When the output region 7 generates an output signal and the control region 10 generates a control signal, the output region 7 reaches a first temperature TE1 and the control region 10 reaches a second temperature TE2 which is different from the first temperature TE1 (TE1≠TE2). Specifically, the second temperature TE2 is less than the first temperature TE1 (TE1>TE2). The first temperature detecting region 9A generates a first temperature detecting signal ST1 which detects the first temperature TE1, and the second temperature detecting region 9B generates a second temperature detecting signal ST2 which detects the second temperature TE2.

With reference to FIG. 2 to FIG. 5, the semiconductor device 1A includes an n-system insulating gate type main transistor 11 which is formed in the output region 7. “n” is not less than 2 (n≥2). The main transistor 11 may be referred to as a “gate divided transistor.” The main transistor 11 includes an n-number of first gates FG, one first drain FD, and one first source FS. The first gate FG, the first drain FD and the first source FS may be respectively referred to as a “main gate,” a “main drain” and a “main source.”

The main transistor 11 is configured so that the same or different n-number of gate signals G (gate voltages) are input into the n-number of the first gates FG at arbitrary timings. Each gate signal G includes an on signal which controls a part of the main transistor 11 so as to be in an on state and an off signal which controls a part of the main transistor 11 so as to be in an off state.

The main transistor 11 generates a single output current IO (output signal) in response to the n-number of the gate signals G. That is, the main transistor 11 is constituted of a multi-input/single-output type switching device. Specifically, the output current IO is a drain-source current which flows between the first drain FD and the first source FS. The output current IO is output to the outside of the chip 2.

With reference to FIG. 4, the main transistor 11 includes an n-number of system transistors 12. The n-number of the system transistors 12 are formed to concentrate in the single output region 7 and configured so as to be controlled in an on state and in an off state electrically independently of each other. Specifically, the n-number of the system transistors 12 are connected in parallel to each other so that the n-number of the gate signals G are individually input, thereby configuring one system parallel circuit (=main transistor 11). That is, the n-system main transistor 11 is configured so that the system transistor 12 in an on state coexists with the system transistor 12 in an off state at an arbitrary timing.

The n-number of the system transistors 12 each include a second gate SG, a second drain SD, and a second source SS. The second gate SG, the second drain SD, and the second source SS may be respectively referred to as a “system gate,” a “system drain,” and a “system source.” The n-number of the second gates SG are each connected to the n-number of the first gates FG in a one-to-one correspondence. The n-number of the second drains SD are each connected to one first drain FD. The n-number of the second sources SS are each connected to one first source FS.

That is, the n-number of the second gates SG, the n-number of the second drains SD and the n-number of the second sources SS of the n-number of the system transistors 12 respectively configure the n-number of the first gates FG, one first drain FD and one first source FS of the main transistor 11. The n-number of the first gates FG are substantially constituted of the n-number of the second gates SG.

The n-number of the system transistors 12 each generate a system current IS in response to the corresponding gate signal G. Specifically, the n-number of the system currents IS are a drain-source current which flows between the second drain SD and the second source SS of each of the n-number of the system transistors 12. The n-number of the system currents IS may be values different from each other or may be values equal to each other. The n-number of the system currents IS are added between the first drain FD and the first source FS. Thereby, a single output current IO which is constituted of an added value of the n-number of the system currents IS is generated.

With reference to FIG. 5, the n-number of the system transistors 12 each include a single or a plurality of unit transistors 13 which are systematized (grouped) as an individually controlled object. In this embodiment, the plurality of unit transistors 13 are each constituted of a trench gate type. Specifically, the n-number of the system transistors 12 each have a unit parallel circuit which is constituted of the single or the plurality of unit transistors 13.

A case that the system transistor 12 is constituted of the single unit transistor 13 is also included in a “unit parallel circuit” described here. Although the number of the unit transistors 13 included in each system transistor 12 is arbitrary, at least one system transistor 12 preferably includes the plurality of unit transistors 13. The n-number of the system transistors 12 may be constituted of the same number or different numbers of the unit transistors 13.

Each unit transistor 13 includes a third gate TG, a third drain TD, and a third source TS. The third gate TG, the third drain TD, and the third source TS may be respectively referred to as a “unit gate,” a “unit drain” and a “unit source.”

In each of the system transistors 12, the third gates TG are electrically connected to the second gate SG, the third drains TD are electrically connected to the second drain SD, and the third sources TS are electrically connected to the second source SS. That is, the third gate TG, the third drain TD and the third source TS of the single or the plurality of unit transistors 13 which was systematized configure the second gate SG, the second drain SD and the second source SS of each system transistor 12, respectively.

The plurality of unit transistors 13 may have a substantially equal gate threshold voltage or may have different gate threshold voltages. The plurality of unit transistors 13 may have a channel area that is substantially equal or may have a channel area that is different for each unit area.

That is, the plurality of unit transistors 13 may have substantially similar on-resistance characteristics or may have different on-resistance characteristics. Electrical characteristics of each system transistor 12 are precisely adjusted by adjusting the number, a gate threshold voltage, a channel area, etc., of the plurality of unit transistors 13.

With reference to FIG. 2 to FIG. 5, the semiconductor device 1A includes an m-system insulating gate type monitor transistor 14 which is formed in the current detecting region 8. “m” is not less than 1 (m≥1). In this embodiment, the monitor transistor 14 is formed in an inner portion (preferably at a central portion) of the output region 7 at an interval from a peripheral edge of the output region 7 and is arranged so as to be adjacent to the plurality of system transistors 10. The monitor transistor 14 is preferably adjacent to the plurality of system transistors 12 in at least two directions in a plan view. That is, monitor transistor 14 is preferably formed so as to concentrate in the single output region 7 together with the plurality of system transistors 12.

The monitor transistor 14 may be configured so as to be connected in parallel to at least one system transistor 12 and monitor at least one system current IS. The monitor transistor 14 is preferably constituted of the m-system (m 2) monitor transistor 14 which is configured so as to be connected in parallel to the plurality of system transistors 12 and monitor the plurality of system currents IS.

In this embodiment, the monitor transistor 14 is constituted of the n-system (m=n) monitor transistor 14 which is configured so as to be connected in parallel to the n-number of the system transistors 12 to monitor the n-number of the system currents IS. Hereinafter, a description of a configuration of the monitor transistor 14 shall be given by replacing the “m-system” or the “m-number” by the “n-system” or the “n-number,” whenever necessary.

In this embodiment, the monitor transistor 14 includes an n-number of first monitor gates FMG, one first monitor drain FMD and one first monitor source FMS. The first monitor gate FMG, the first monitor drain FMD and the first monitor source FMS may be respectively referred to as a “main monitor gate,” a “main monitor drain” and a “main monitor source.”

The n-number of the first monitor gates FMG are each configured so that an n-number of monitor gate signals MG are input. The first monitor drain FMD is electrically connected to the first drain FD. The first monitor source FMS is electrically separated from the first source FS.

The n-number of the monitor gate signals MG (monitor gate voltages) which are the same or different are input into the n-number of the first monitor gates FMG at arbitrary timings. Each monitor gate signal MG includes an on signal which controls a part of the monitor transistor 14 so as to be in an on state and an off signal which controls a part of the monitor transistor 14 so as to be in an off state.

In this embodiment, the monitor transistor 14 generates a single output monitor current IOM (output monitor signal) which monitors the n-number of the system currents IS (output currents IO) in response to the n-number of the monitor gate signals MG. That is, in this embodiment, the monitor transistor 14 is constituted of a multi-input/single-output type switching device. Specifically, the output monitor current IOM is a drain-source current which flows between the first monitor drain FMD and the first monitor source FMS.

In this embodiment, the n-number of the first monitor gates FMG are each electrically connected to the n-number of the first gates FG in a one-to-one correspondence. Therefore, the n-number of the first monitor gates FMG are configured so that each monitor gate signal MG constituted of the gate signal G are individually input. That is, the monitor transistor 14 is subjected to on/off control at the same timing with the n-number of the system transistors 12 and generates the output monitor current IOM which is increased or decreased in conjunction with an increase or a decrease in the output current IO.

The output monitor current IOM is output to the outside of the output region 7 via a current path which is electrically independent of a current path of the output current IO. The output monitor current IOM is not more than the output current IO (IOM≤IO). The output monitor current IOM is preferably less than the output current IO (IOM<IO). A current ratio IOM/IO of the output monitor current IOM to the output current IO is arbitrary. The current ratio IOM/IO may be not less than 1/10000 and not more than 1 (preferably, less than 1).

With reference to FIG. 4, the monitor transistor 14 includes an m-number (in this embodiment, an n-number) of system monitor transistors 15. The number of the systems of the monitor transistor 14 is adjusted by the number of the system monitor transistors 15. That is, where the m-system (m≥1) monitor transistor 14 monitors at least one system current IS, at least one system monitor transistor is electrically connected (specifically, connected in parallel) to at least one system transistor 12.

Also, where the m-system (m≥2) monitor transistor 14 monitors the plurality of system currents IS, the plurality of system monitor transistors 15 are electrically connected to the plurality of system transistors 12. In this embodiment, the n-number of the system monitor transistors 15 are electrically connected to the n-number of the system transistors 12 and monitor the n-number of the system currents IS.

The n-number of the system monitor transistors are formed to concentrate in the single output region 7 and configured so as to be controlled in an on state and in an off state electrically independently of each other. Specifically, the n-number of the system monitor transistors are connected in parallel to each other so that the n-number of the monitor gate signals MG are individually input, thereby configuring one system monitor parallel circuit (=monitor transistor 14). That is, the monitor transistor 14 is configured so that the system monitor transistor 15 in an on state coexists with the system monitor transistor 15 in an off state at an arbitrary timing.

The n-number of the system monitor transistors each include a second monitor gate SMG, a second monitor drain SMD and a second monitor source SMS. The second monitor gate SMG, the second monitor drain SMD and the second monitor source SMS may be respectively referred to as a “system monitor gate,” a “system monitor drain” and a “system monitor source.”

The n-number of the second monitor gates SMG are each connected to the n-number of the first monitor gates FMG in a one-to-one correspondence. The n-number of the second monitor drains SMD are each connected to one first monitor drain FMD. The n-number of the second monitor sources SMS are each connected to one first monitor source FMS.

The n-number of the second monitor gates SMG, the n-number of the second monitor drains SMD and the n-number of the second monitor sources SMS of the n-number of the system monitor transistors 15 configure the n-number of the first monitor gates FMG, one first monitor drain FMD and one first monitor source FMS of the monitor transistor 14, respectively. The n-number of the first monitor gates FMG are substantially constituted of the n-number of the second monitor gates SMG.

The n-number of the monitor gate signals MG which are the same or different are input into the n-number of the second monitor gates SMG at arbitrary timings. The n-number of the system monitor transistors 15 each generate a system monitor current ISM (system monitor signal) which monitors the system current IS of the corresponding system transistor 12 in response to the corresponding monitor gate signal MG.

Specifically, each system monitor current ISM is a drain-source current which flows between the second monitor drain SMD and the second monitor source SMS of each of the system monitor transistors 15. The n-number of the system monitor currents ISM are added between the first monitor drain FMD and the first monitor source FMS. Thereby, the single output monitor current IOM constituted of an added value of the n-number of the system monitor currents ISM is generated.

In this embodiment, the n-number of the system monitor transistors 15 are each configured so as to be electrically connected to the corresponding system transistor 12 in a one-to-one correspondence and controlled in conjunction with the corresponding system transistor 12. Specifically, the n-number of the system monitor transistors are each connected in parallel to the corresponding system transistor 12 so that the system monitor current ISM is output to a current path electrically independent of a current path of the system current IS.

The n-number of the second monitor gates SMG are each electrically connected to the corresponding first gate FG in a one-to-one correspondence. The second monitor drain SMD is electrically connected to the first drain FD. The second monitor source SMS is electrically separated from the first source FS. That is, in this embodiment, the monitor gate signal MG constituted of the gate signal G is input into each of the n-number of the second monitor gates SMG.

Thereby, the n-number of the system monitor transistors 15 are subjected to on/off control at the same timing with the corresponding system transistors 12 and each generate the system monitor current ISM which is increased or decreased in conjunction with an increase or a decrease in the corresponding system current IS. The system monitor current ISM is electrically independent of the system current IS and taken out from the second monitor drain SMD and the second monitor source SMS. Each system monitor current ISM is not more than the corresponding system current IS (ISM≤IS).

Each system monitor current ISM is preferably less than the corresponding system current IS (ISM<IS). A current ratio ISM/IS of the system monitor current ISM to the system current IS is arbitrary. The current ratio ISM/IS may be not less than 1/10000 and not more than 1 (preferably, less than 1).

With reference to FIG. 5, the n-number of the system monitor transistors 15 each include a single or a plurality of unit monitor transistors 16 which are systematized (grouped) as an individually controlled object. In this embodiment, the plurality of unit monitor transistors 16 are each constituted of a trench gate type. Specifically, the n-number of the system monitor transistors each have a unit monitor parallel circuit which is constituted of the single or the plurality of unit monitor transistors 16.

A case that the system monitor transistor 15 is constituted of the single unit monitor transistor 16 is also included in the “unit monitor parallel circuit” described here. The number of the unit monitor transistors 16 included in each system monitor transistor 15 is arbitrary. The n-number of the system monitor transistors 15 may be constituted of the same number or different numbers of the unit monitor transistors 16. The number of the unit monitor transistors 16 included in each system monitor transistor is preferably less than the number of the unit transistors 13 included in the corresponding system transistor 12. In this case, it is possible to easily generate the system monitor current ISM which is not more than the system current IS.

Each unit monitor transistor 16 includes a third monitor gate TMG, a third monitor drain TMD and a third monitor source TMS. The third monitor gate TMG, the third monitor drain TMD and the third monitor source TMS may be respectively referred to as a “unit monitor gate,” a “unit monitor drain” and a “unit monitor source.”

In each of the system monitor transistors 15, the third monitor gate TMG is electrically connected to the second monitor gate SMG, the third monitor drain TMD is electrically connected to the second monitor drain SMD, and the third monitor source TMS is electrically connected to the second monitor source SMS.

That is, the third monitor gate TMG, the third monitor drain TMD and the third monitor source TMS of the single or the plurality of unit monitor transistors 16 which was systematized respectively configure the second monitor gate SMG, the second monitor drain SMD and the second monitor source SMS of each of the system monitor transistors 15.

The plurality of unit monitor transistors 16 may have a substantially equal gate threshold voltage or may have different gate threshold voltages. The plurality of unit monitor transistors 16 may have a substantially equal channel area or may have a different channel area for each unit area. That is, the plurality of unit monitor transistors 16 may have substantially similar on-resistance characteristics or may have different on-resistance characteristics.

The gate threshold voltage, the channel area, the on-resistance characteristics, etc., of the unit monitor transistor 16 included in the system monitor transistors 15 may be substantially equal or similar to or may be different from the gate threshold voltage, the channel area, the on-resistance characteristics, etc., of the unit transistors 13 included in each of the corresponding system transistor 12.

The channel area of the unit monitor transistor 16 included in each system monitor transistor 15 is preferably less than the channel area of the unit transistor 13 included in the corresponding system transistor 12. Electrical characteristics of each system monitor transistor 15 are precisely adjusted by adjusting the number of the plurality of unit monitor transistors 16, the gate threshold voltage, the channel area, etc.

With reference to FIG. 1 and FIG. 3, the semiconductor device 1A includes a plurality of temperature-sensitive diodes 17 (diodes) which are formed in the plurality of temperature detecting regions 9. The plurality of temperature-sensitive diodes 17 include a first temperature-sensitive diode 17A which is formed in the first temperature detecting region 9A and a second temperature-sensitive diode 17B which is formed in the second temperature detecting region 9B. In this embodiment, the first temperature-sensitive diode 17A is formed in the output region 7, and the second temperature-sensitive diode 17B is formed in the control region 10. That is, the main transistor 11, the monitor transistor 14 and the temperature-sensitive diode 17 are formed to concentrate in the output region 7.

The first temperature-sensitive diode 17A includes an anode and a cathode. An anode potential is to be applied to the anode of the first temperature-sensitive diode 17A, and a cathode potential is to be applied to the cathode of the first temperature-sensitive diode 17A. A voltage between the anode potential and the cathode potential may be not less than a forward direction voltage of the first temperature-sensitive diode 17A (for example, not less than 5 V). The anode potential may be an arbitrary high potential (for example, a power potential VB). The cathode potential may be an arbitrary potential lower than the anode potential (for example, a potential lower by about 5 V than the power potential VB).

The first temperature-sensitive diode 17A generates the first temperature detecting signal ST1 which detects the first temperature TE1 of the output region 7 in the first temperature detecting region 9A. The first temperature-sensitive diode 17A has a first forward direction voltage Vf1 that has temperature characteristics which change in response to the first temperature TE1 of the output region 7. Specifically, the first forward direction voltage Vf1 has negative temperature characteristics in which the first forward direction voltage Vf1 linearly decreases with an increase in the first temperature TE1. The first temperature detecting signal ST1 changes in response to the first temperature TE1 of the output region 7 and indirectly detects the first temperature TE1.

The second temperature-sensitive diode 17B includes an anode and a cathode. An anode potential is to be applied to the anode of the second temperature-sensitive diode 17B, and a cathode potential is to be applied to the cathode of the second temperature-sensitive diode 17B. A voltage between the anode potential and the cathode potential may be not less than a forward direction threshold voltage of the second temperature-sensitive diode 17B (for example, not less than 5 V). The anode potential may be an arbitrary high potential (for example, the power potential VB). The cathode potential may be an arbitrary low potential lower than the anode potential (for example, a potential lower by about 5 V than the power potential VB).

The second temperature-sensitive diode 17B generates the second temperature detecting signal ST2 which detects the second temperature TE2 of the control region 10 in the second temperature detecting region 9B. The second temperature-sensitive diode 17B has a second forward direction voltage Vf2 that has temperature characteristics which change in response to the second temperature TE2 of the control region 10. Specifically, the second forward direction voltage Vf2 has negative temperature characteristics in which the second forward direction voltage Vf2 linearly decreases with an increase in the second temperature TE2. The second temperature detecting signal ST2 changes in response to the second temperature TE2 of the control region 10 and indirectly detects the second temperature TE2.

It is preferable that the second temperature-sensitive diode 17B has substantially the same configuration as that of the first temperature-sensitive diode 17A and has substantially the same electrical characteristics as that of the first temperature-sensitive diode 17A. When the main transistor 11 generates the output current IO, the second temperature TE2 is less than the first temperature TE1 (T1>T2). Therefore, during generation of the output current IO, the second forward direction voltage Vf2 of the second temperature-sensitive diode 17B exceeds the first forward direction voltage Vf1 of the first temperature-sensitive diode 17A (Vf1<Vf2).

The semiconductor device 1A includes a control circuit 18 which is formed in the control region 10. The control circuit 18 may be referred to as a “control IC (Control Integrated Circuit). The control circuit 18 configures an IPD (Intelligent Power Device) together with the main transistor 11. The IPD may be referred to as an “IPM (Intelligent Power Module).” The control circuit 18 includes multiple types of functional circuits which realize various functions in response to an electric signal input from the outside.

The multiple types of functional circuits include a gate drive circuit 19, an active clamp circuit 20, an overcurrent protection circuit 21 and a thermal shutdown circuit 22. The overcurrent protection circuit 21 may be referred to as an “OCP (Over Current Protection) circuit” and the thermal shutdown circuit 22 may be referred to as a “TSD (Thermal Shutdown) circuit.” Although not shown, the control circuit 18 may include multiple types of abnormality detection circuits which detect abnormalities (for example, overvoltage, etc.) of the main transistor 11, the monitor transistor 14, etc.

The gate drive circuit 19 is electrically connected to the first gate FG of the main transistor 11 and the first monitor gate FMG of the monitor transistor 14 and controls the main transistor 11 and the monitor transistor 14 in response to an electric signal from the outside. Specifically, the gate drive circuit 19 is configured so as to be electrically connected to the n-number of the first gates FG of the main transistor 11 (second gates SG of n-number of the system transistors 12) and individually control the n-number of the system transistors 12.

Further, the gate drive circuit 19 is configured so as to be electrically connected to the n-number of the first monitor gates FMG of the monitor transistor 14 (n-number of the second monitor gates SMG) and individually control the n-number of the system monitor transistors 15. In this embodiment, the n-number of the first monitor gates FMG (n-number of the second monitor gates SMG) of the monitor transistor 14 are each electrically connected to the corresponding first gate FG. Therefore, the gate drive circuit 19 individually controls the n-number of the first monitor gates FMG so as to work in conjunction with the n-number of the first gates FG.

The active clamp circuit 20 is electrically connected to the main transistor 11 and the gate drive circuit 19. The active clamp circuit 20 is configured so as to protect the main transistor 11 from a back electromotive force by restricting (clamping) an output voltage VO when the back electromotive force is input into the main transistor 11 due to an energy accumulated in the inductive load L. That is, the active clamp circuit 20 is configured so as to restrict the output voltage VO until the back electromotive force is consumed by making the main transistor 11 perform an active clamp operation when the back electromotive force is input.

Specifically, the active clamp circuit 20 is electrically connected to a part (not all) of the first gate FG and the first drain FD of the main transistor 11. The active clamp circuit 20 controls some of the system transistors 12 so as to be in an on state and controls the rest of the system transistors 12 so as to be in an off state during an active clamp operation. That is, the active clamp circuit 20 raises an on-resistance of the main transistor 11 during the active clamp operation and protects the main transistor 11 from the back electromotive force.

Further, the active clamp circuit 20 is electrically connected to the monitor transistor 14 and the gate drive circuit 19. The active clamp circuit 20 is configured so as to protect the monitor transistor 14 from a back electromotive force by restricting (clamping) the output voltage VO when the back electromotive force is input into the monitor transistor 14 due to an energy accumulated in the inductive load L. That is, the active clamp circuit restricts the output voltage VO until the back electromotive force is consumed by making the monitor transistor 14 perform an active clamp operation when the back electromotive force is input.

Specifically, the active clamp circuit 20 is electrically connected to a part (not all) of the first monitor gate FMG and the first monitor drain FMD of the monitor transistor 14. The active clamp circuit 20 controls some of the system monitor transistors 15 so as to be in an on state and controls the rest of the system monitor transistors 15 so as to be in an off state during the active clamp operation.

Specifically, the active clamp circuit 20 performs on/off control of the n-system monitor transistor 14 so as to work in conjunction with an on/off state of the n-system main transistor 11 during the active clamp operation. More specifically, the active clamp circuit 20 controls the system monitor transistor 15 corresponding to the on-state system transistor 12 so as to be in an on state and controls the system monitor transistor 15 corresponding to the off-state system transistor 12 so as to be in an off state during the active clamp operation.

That is, the active clamp circuit 20 raises an on-resistance of the monitor transistor 14 during the active clamp operation and protects the monitor transistor 14 from a back electromotive force. The active clamp circuit 20 may be configured so that when the first source FS of the main transistor 11 is at a voltage not more than a predetermined voltage (for example, a predetermined negative voltage), on/off control of the n-number of the system transistors 12 is performed and on/off control of the n-number of the system monitor transistors 15 is performed.

The overcurrent protection circuit 21 is electrically connected to the monitor transistor 14 and the gate drive circuit 19. The overcurrent protection circuit 21 is configured so as to be electrically connected to the first monitor source FMS of the monitor transistor 14 and obtain a part or all (in this embodiment, all) of the output monitor current IOM. The overcurrent protection circuit 21 is configured so as to protect the main transistor 11 from an overcurrent by controlling the gate signal G generated by the gate drive circuit 19 in response to the output monitor current IOM and restricting the output current IO to a value not more than a predetermined value (for example, 0 A).

The overcurrent protection circuit 21 may be configured so as to obtain at least one of the plurality of system monitor currents ISM. Of the output monitor current IOM (plurality of system monitor currents ISM), a current which is input into the overcurrent protection circuit 21 is regulated by branching or not branching the output monitor current IOM (plurality of system monitor currents ISM) according to a circuit configuration of the control circuit 18. The overcurrent protection circuit 21 indirectly monitors the output current IO by the output monitor current IOM.

The overcurrent protection circuit 21 may be configured so as to generate an overcurrent detecting signal SOD and output the overcurrent detecting signal SOD to the gate drive circuit 19 when the output monitor current IOM exceeds a predetermined threshold. The overcurrent detecting signal SOD is a signal for restricting some of or all of the n-number of the gate signals G generated in the gate drive circuit 19 to a value not more than a predetermined value (for example, off).

The gate drive circuit 19 restricts some of or all of the n-number of the gate signals G in response to the overcurrent detecting signal SOD and suppresses an overcurrent that flows through the main transistor 11. When the output monitor current IOM is at a value not more than a predetermined threshold, the overcurrent protection circuit 21 shifts the gate drive circuit 19 (main transistor 11) to normal control.

The above-described configuration (operation) of the overcurrent protection circuit 21 is merely an example. The overcurrent protection circuit 21 may have a variety of current voltage characteristics and a variety of operation methods. The overcurrent protection circuit 21 may have a circuit configuration including at least one current/voltage characteristics among constant current/voltage dropping type characteristics, foldback current limiting characteristics and constant power control voltage dropping type characteristics. The overcurrent protection circuit 21 may have a circuit configuration including an automatic recovery type or a latch type (shutdown type with no automatic recovery) operation method.

The thermal shutdown circuit 22 is electrically connected to the gate drive circuit 19 and at least one temperature-sensitive diode 17. In this embodiment, the thermal shutdown circuit 22 is electrically connected to both of the first temperature-sensitive diode 17A and the second temperature-sensitive diode 17B and configured so that a part of or an entirety of the first temperature detecting signal ST1 (hereinafter, simply referred to as the “first temperature detecting signal ST1”) is input from the first temperature-sensitive diode 17A and a part of or an entirety of the second temperature detecting signal ST2 (hereinafter, simply referred to as the “second temperature detecting signal ST2”) is input from the second temperature-sensitive diode 17B.

Specifically, the thermal shutdown circuit 22 is configured so as to control the gate signal G which is generated in the gate drive circuit 19 in response to the first temperature detecting signal ST1 and the second temperature detecting signal ST2 and so as to protect the main transistor 11 from overheating by restricting the output current IO to a predetermined value or lower (for example, 0 A).

For example, the thermal shutdown circuit 22 may include a low potential imparting portion 23, a first current source 24, a second current source 25, a difference circuit 26 and a logic circuit 27. The low potential imparting portion 23 is a portion which imparts a low potential less than the power potential VB to other circuits. The low potential imparting portion 23 may be a circuit device such as a constant voltage regulator and a Zener diode, etc., or an arbitrary low potential wiring.

The first current source 24 is electrically connected to the first temperature-sensitive diode 17A and the low potential imparting portion 23 and allows a constant current to flow toward the low potential imparting portion 23. The first current source 24 configures a first node N1 with the first temperature-sensitive diode 17A. The second current source 25 is electrically connected to the second temperature-sensitive diode 17B and the low potential imparting portion 23 and allows a constant current to flow toward the low potential imparting portion 23. The second current source 25 may be configured so as to generate a constant current which is substantially equal to that of the first current source 24. The second current source 25 configures a second node N2 with the second temperature-sensitive diode 17B.

The difference circuit 26 is electrically connected to the first node N1 and the second node N2. The difference circuit 26 may include a comparator which has a non-inverting input terminal (−) and an inverting input terminal (+). The comparator may have hysteresis characteristics which reduce noises between the non-inverting input terminal (−) and the inverting input terminal (+). The first node N1 may be electrically connected to the non-inverting input terminal (−) of the comparator, and the second node N2 may be electrically connected to the inverting input terminal (+) of the comparator.

The difference circuit 26 is configured so as to output a difference signal ΔVf (ΔVf=Vf2−Vf1, Vf2>Vf1) which indicates a difference value between the first temperature detecting signal ST1 (first forward direction voltage Vf1) and the second temperature detecting signal ST2 (second forward direction voltage Vf2). The difference signal ΔVf indirectly indicates a temperature difference ΔTj (ΔTj=TE1−TE2: TE2<TE1) between the first temperature TE1 of the output region 7 and the second temperature TE2 of the control region 10.

The logic circuit 27 is electrically connected to the difference circuit 26 and the gate drive circuit 19. For example, the logic circuit 27 is configured so as to generate an overheat detecting signal SOH and output the overheat detecting signal SOH to the gate drive circuit 19 when the difference signal ΔVf exceeds a predetermined threshold VT (VT<ΔVf). The overheat detecting signal SOH is a signal which restricts a part of or an entirety of the n-number of the gate signals G, which are generated in the gate drive circuit 19, so as to be in an off state.

The gate drive circuit 19 controls a part of or an entirety of the main transistor 11 so as to be in an off state in response to the overheat detecting signal SOH and suppresses an increase in temperature of the output region 7. Further, the gate drive circuit 19 controls a part of or an entirety of the monitor transistor 14 so as to be in an off state in response to the overheat detecting signal SOH and suppresses an increase in temperature of the current detecting region 8 (output region 7). For example, the logic circuit 27 shifts the gate drive circuit 19 to ordinary control when the difference signal ΔVf is lower than the threshold VT (VT>ΔVf).

As a matter of course, the thermal shutdown circuit 22 may be configured so that only the first temperature detecting signal ST1 from the first temperature-sensitive diode 17A is input and the gate signal G is controlled in response to only the first temperature detecting signal ST1. In this case, the thermal shutdown circuit 22 may be configured so that a part of or an entirety of the main transistor 11 is controlled so as to be in an off state where the first temperature detecting signal ST1 exceeds the threshold VT (ST1>VT) and the main transistor 11 is controlled so as to be in an on state where the first temperature detecting signal ST1 is lower than the threshold VT (ST1<VT).

With reference to FIG. 2, the semiconductor device 1A includes an interlayer insulating layer 30 which covers the first main surface 3. The interlayer insulating layer 30 collectively covers the output region 7, the current detecting region 8, the temperature detecting region 9 and the control region 10. In this embodiment, the interlayer insulating layer 30 is constituted of a multi-layer wiring structure having a laminated structure in which a plurality of insulating layers and a plurality of wiring layers are alternately laminated.

Each of the insulating layers may include at least one of a silicon oxide film and a silicon nitride film. Each of the wiring layers may include at least one among a pure Al layer (Al layer with purity of not less than 99%), a Cu layer (Cu layer with purity of not less than 99%), an AlCu alloy layer, an AlSiCu alloy layer and an AlSi alloy layer.

With reference to FIG. 2 to FIG. 5, the semiconductor device 1A includes an n-number of main gate wirings 31 as an example of a control wiring arranged anywhere above the first main surface 3. The n-number of the main gate wirings 31 are constituted of the n-number of the wiring layers selectively routed inside the interlayer insulating layer 30. The n-number of the main gate wirings 31 are electrically connected to the n-number of the first gates FG of the main transistor 11 in a one-to-one correspondence in a state electrically independent of each other in the output region 7.

The n-number of the main gate wirings 31 are each electrically connected to the control circuit 18 (gate drive circuit 19) in the control region 10. The n-number of the main gate wirings 31 individually transmit the n-number of the gate signals G generated by the control circuit 18 (gate drive circuit 19) to the n-number of the first gates FG of the main transistor 11.

The n-number of the main gate wirings 31 are each electrically connected to the third gate TG of one or the plurality of unit transistors 13 which are to be systematized as an individually controlled object from an assembly constituted of the plurality of unit transistors 13. The n-number of the main gate wirings 31 may include one or the plurality of main gate wirings 31 electrically connected to one unit transistor 13 which is to be systematized as an individually controlled object. Also, the n-number of the main gate wirings 31 may include one or the plurality of main gate wirings 31 which connect in parallel the plurality of unit transistors 13 which are to be systematized as an individually controlled object.

The semiconductor device 1A includes an n-number of monitor gate wirings 32 as an example of a monitor control wiring that is arranged anywhere above the first main surface 3. The n-number of the monitor gate wirings 32 are constituted of the n-number of the wiring layers selectively routed inside the interlayer insulating layer 30. The n-number of the monitor gate wirings 32 are electrically connected to the n-number of the first monitor gates FMG of the monitor transistor 14 in a one-to-one correspondence in a state electrically independent of each other in the output region 7.

The n-number of the monitor gate wirings 32 are each electrically connected to the control circuit 18 (gate drive circuit 19) in the control region 10. The n-number of the monitor gate wirings 32 individually transmit the n-number of the monitor gate signals MG generated by the control circuit 18 (gate drive circuit 19) to the n-number of the first monitor gates FMG of the monitor transistor 14.

The n-number of the monitor gate wirings 32 are each electrically connected to the third monitor gate TMG of one or the plurality of unit monitor transistors 16 which are to be systematized as an individually controlled object from an assembly constituted of the plurality of unit monitor transistors 16. The n-number of the monitor gate wirings 32 may include one or the plurality of monitor gate wirings 32 electrically connected to one unit monitor transistor 16 which is to be systematized as an individually controlled object.

The n-number of the monitor gate wirings 32 may include one or the plurality of monitor gate wirings 32 which connect in parallel the plurality of unit monitor transistors 16 which are to be systematized as an individually controlled object. In this embodiment, the n-number of the monitor gate wirings 32 are each electrically connected to the corresponding main gate wiring 31 in a one-to-one correspondence. The n-number of the monitor gate wirings 32 may be each integrally formed with the corresponding main gate wiring 31.

The n-number of the monitor gate wirings 32 are each electrically connected to the control circuit 18 (gate drive circuit 19) via the corresponding main gate wiring 31. The n-number of the monitor gate wirings 32 individually transmit the n-number of the gate signals G (n-number of the monitor gate signals MG) generated by the control circuit 18 (gate drive circuit 19) to the n-number of the first monitor gates FMG of the monitor transistor 14.

The semiconductor device 1A includes one or a plurality of main source wirings 33 which are arranged inside the interlayer insulating layer 30. One or the plurality of main source wirings 33 are constituted of the wiring layer formed inside the interlayer insulating layer 30. One or the plurality of main source wirings 33 are selectively routed inside the interlayer insulating layer and electrically connected to the first source FS of the main transistor 11.

The semiconductor device 1A includes one or a plurality of monitor source wirings 34 which are arranged inside the interlayer insulating layer 30. One or the plurality of monitor source wirings 34 are constituted of the wiring layer formed inside the interlayer insulating layer 30. One or the plurality of monitor source wirings 34 are selectively routed inside the interlayer insulating layer 30 and electrically connected to the first monitor source FMS of the monitor transistor 14 and the overcurrent protection circuit 21.

With reference to FIG. 1 and FIG. 2, the semiconductor device 1A includes a plurality of terminal electrodes 35. The number, the arrangement and planar shape of the plurality of terminal electrodes 35 are adjusted according to specifications of the main transistor 11 and specifications of the control circuit 18 and not limited to a mode shown in FIG. 1. In this embodiment, the plurality of terminal electrodes 35 include a drain terminal 36 (power terminal), the source terminal 37 (output terminal), an input terminal 38, an enable terminal 39, a sense terminal and a ground terminal 41.

The drain terminal 36 directly covers the second main surface 4 of the chip 2 and is electrically connected to the second main surface 4. The drain terminal 36 may include at least one among a Ti layer, an Ni layer, an Au layer, an Ag layer and an Al layer. The drain terminal 36 may have a laminated structure in which at least two of the Ti layer, the Ni layer, the Au layer, the Ag layer and the Al layer are laminated in an arbitrary mode. The drain terminal 36 is electrically connected to the first drain FD of the main transistor 11, the first monitor drain FMD of the monitor transistor 14, and the control circuit 18 and transmits the power potential VB.

The terminal electrodes 35 other than the drain electrode 36 is arranged on the interlayer insulating layer at the first main surface 3. The source terminal 37 is arranged above the output region 7. The source terminal 37 has a planar area which is less than a planar area of the drain terminal 36. The source terminal 37 is electrically connected to the first source FS of the main transistor 11 and the control circuit 18. The source terminal 37 transmits to the outside the output current IO generated by the main transistor 11.

The terminal electrodes 38 to 41 other than the source terminal 37 are each arranged above a region of the first main surface 3 outside the output region 7 (specifically, the control region 10). The terminal electrodes 38 to 41 other than the source terminal 37 each have a planar area which is less than the planar area of the source terminal 37. The input terminal 38 transmits an input voltage which drives the control circuit 18.

The enable terminal 39 transmits an electric signal for enabling or disabling some of or all of the functions of the control circuit 18. The sense terminal 40 transmits an electric signal for detecting abnormalities of the main transistor 11, the monitor transistor 14, the control circuit 18, etc. The ground terminal 41 transmits a ground voltage GND to the control circuit 18 via a ground wiring (not shown) routed inside the interlayer insulating layer 30.

The terminal electrodes 37 to 40 other than the drain terminal 36 may include at least one among a pure Al layer, a pure Cu layer, an AlCu alloy layer, an AlSiCu alloy layer and an AlSi alloy layer. The semiconductor device 1A may include a plurality of plating layers that respectively cover outer surfaces of the terminal electrodes 37 to 40 other than the drain terminal 36. The plating layer may include at least one among a Ni layer, a Pd layer and an Au layer.

The semiconductor device 1A includes at least one protection region 42 (in this embodiment, a plurality of protection regions 42) which is arranged in the first main surface 3. The protection regions 42 configure parts of the circuit region 6. The protection region 42 may be referred to as a “fifth device region.” Each of the protection regions 42 is a region having a circuit device which is configured so as to protect an electric circuit from static electricity. The plurality of protection regions 42 are arranged in the first main surface 3 at an interval and covered by the interlayer insulating layer 30.

In FIG. 1, an example where the plurality of protection regions 42 include a plurality (three) of first protection regions 42A and a plurality (four) of second protection regions 42B is shown as an example. The plurality of first protection regions 42A are arranged mainly for the purpose of protecting the output region 7 (main transistor 11) from static electricity. The plurality of second protection regions 42B are arranged mainly for the purpose of protecting the control region 10 (control circuit 18) from static electricity.

In this embodiment, the plurality of first protection regions 42A are arranged at an inner portion of the first main surface 3 (preferably a region in close proximity to the output region 7) in a plan view. The plurality of second protection region 42B is arranged at a peripheral edge portion of the first main surface 3 in a plan view. The plurality of second protection regions 42B are preferably each arranged at a position in close proximity to the terminal electrodes 36 to 40 in a plan view.

For example, the plurality of second protection regions 42B may be arranged at intervals from the plurality of terminal electrodes 35 in the first direction X or in the second direction Y and face at least one terminal electrode 35 in the first direction X or in the second direction Y. The plurality of second protection regions 42B may overlap with at least one terminal electrode 35 (for example, the terminal electrodes 37 to 40) in a plan view. In FIG. 1, an example where the plurality of second protection regions 42B are each arranged so as to be in close proximity to the terminal electrode 35 other than the source terminal 37 is shown.

Each of the protection regions 42 preferably has a planar area less than a planar area of the output region 7. Each of the protection regions 42 preferably has a planar area less than a planar area of the control region 10. Each of the protection regions 42 preferably has a planar area exceeding a planar area of each of the temperature detecting regions 9 in a plan view. The number, position, size, planar shape, etc., of the protection regions 42 are arbitrary and adjusted according to the number, position, size, planar shape, etc., of protection objects.

With reference to FIG. 1 and FIG. 3, the semiconductor device 1A includes a plurality of ESD diodes 43 (diodes) which are formed in the plurality of protection regions 42. ESD is an abbreviation of “Electro Static Discharge.” The ESD diode 43 may be referred to as an “electrostatic breakdown protection diode.” The plurality of ESD diodes 43 include a plurality of first ESD diodes 43A which are formed in the plurality of first protection regions 42A and a plurality of second ESD diodes 43B which are formed in the plurality of second protection regions 42B.

The plurality of first ESD diodes 43A are each interposed between the plurality of main gate wirings 31 and an arbitrary application end of low potential so that a forward direction current flows to the plurality of main gate wirings 31 side, thereby protecting the main transistor 11 and the monitor transistor 14 from static electricity. The plurality of first ESD diodes 43A each include an anode and a cathode. The anodes of the plurality of first ESD diodes 43A are electrically connected to an arbitrary application end of low potential (for example, the source terminal 37 or the ground terminal 41). The cathodes of the plurality of first ESD diodes 43A are each electrically connected to the plurality of main gate wirings 31.

The plurality of second ESD diodes 43B are interposed between the plurality of terminal electrodes 35 and an arbitrary application end of low potential so that a forward direction current flows to the plurality of terminal electrodes 35 side, thereby protecting the control circuit 18 from static electricity. Further, at least one second ESD diode 43B is interposed between the active clamp circuit and an arbitrary application end of low potential so that a forward direction current flows to the active clamp circuit 20 side.

The plurality of second ESD diodes 43B each include an anode and a cathode. The anodes of the plurality of second ESD diodes 43B are electrically connected to an arbitrary application end of low potential (for example, the source terminal 37 or the ground terminal 41). The cathodes of the plurality of second ESD diodes 43B are each electrically connected to the corresponding terminal electrode 35 or the corresponding active clamp circuit 20.

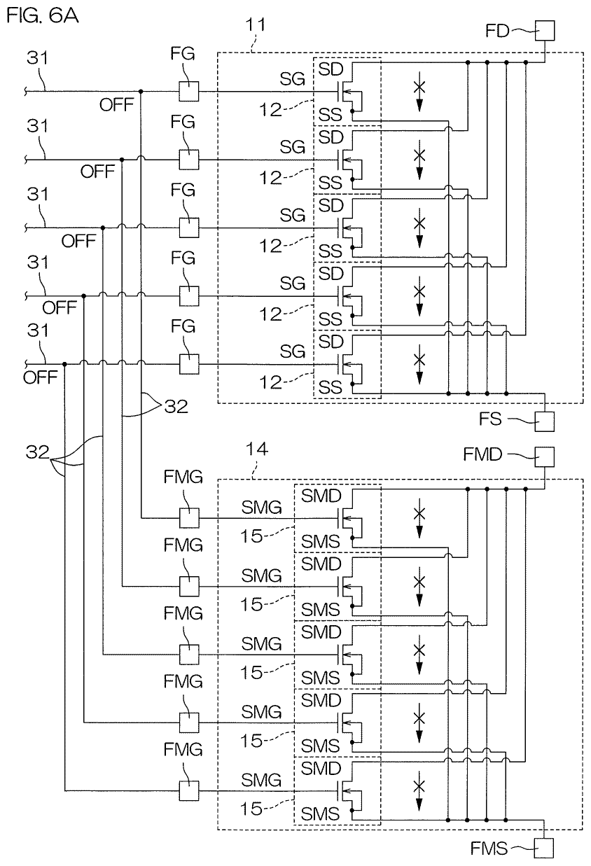

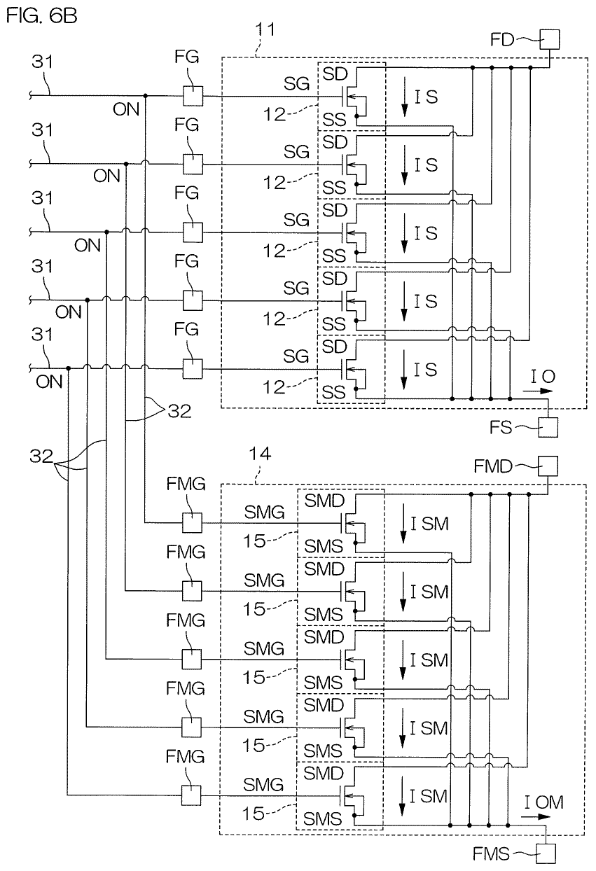

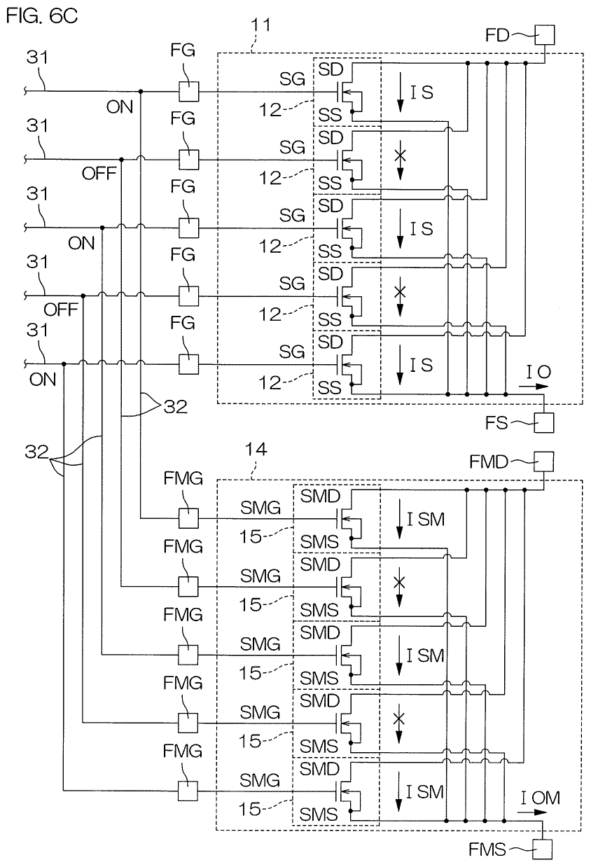

FIG. 6A to FIG. 6C each correspond to FIG. 4 and are circuit diagrams for describing operation examples of the main transistor 11 and the monitor transistor 14. With reference to FIG. 6A, the gate signal G (that is, off signal) less than the gate threshold voltage is input into all of the n-number of the main gate wirings 31. For example, this control is applied during an off operation of the main transistor 11. Thereby, all of the system transistors 12 are turned into an off state.

Thereby, the main transistor 11 is turned into an off state. On the other hand, in the monitor transistor 14, the n-number of the system monitor transistors 15 are turned into an off state in conjunction with the n-number of the system transistors 12. Thereby, the monitor transistor 14 is turned into an off state in conjunction with the main transistor 11.

With reference to FIG. 6B, the gate signal G which is not less than the gate threshold voltage (that is, on signal) is input into all of the n-number of the main gate wirings 31. For example, this control is applied during a normal operation of the main transistor 11. Thereby, as a result of the n-number of the system transistors 12 being turned into an on state, the main transistor 11 is turned into an on state. The main transistor 11 generates the output current IO including the n-number of the system currents IS generated by the n-number of the system transistors 12. In this case, the main transistor 11 is relatively increased in channel utilization rate and relatively decreased in on-resistance.

On the other hand, in the monitor transistor 14, the n-number of the system monitor transistors 15 are turned into an on state in conjunction with the n-number of the system transistors 12. Thereby, the monitor transistor 14 is turned into an on state in conjunction with the main transistor 11. The monitor transistor 14 generates the output monitor current IOM which monitors the output current IO. The output monitor current IOM includes the n-number of the system monitor currents ISM generated by the n-number of the system monitor transistors 15. In this case, the monitor transistor 14 is relatively increased in channel utilization rate and relatively decreased in on-resistance.

With reference to FIG. 6C, the gate signal G which is not less than the gate threshold voltage (that is, on signal) is input into an x number (1≤x<n) of the main gate wirings 31, and the gate signal G which is less than the gate threshold voltage (that is, off signal) is input into the (n-x) number of the main gate wirings 31. This control is applied during an active clamp operation of the main transistor 11. Thereby, as a result of the x number of the system transistors 12 being turned into an on state and the (n-x) number of the system transistors 12 being turned into an off state, the main transistor 11 is turned into an on state in such a state that some of the current paths are conductive and some of the current paths are non-conductive.

The main transistor 11 generates the output current IO including the x number of the system currents IS generated by the x number of the system transistors 12. In other words, the main transistor 11 generates the output current IO including the x number of the system currents IS exceeding 0 A and the (n-x) number of the system currents IS constituted of 0 A. In this case, the main transistor 11 is relatively decreased in channel utilization rate and relatively increased in on-resistance.

On the other hand, in the monitor transistor 14, the x number of the system monitor transistors 15 are turned into an on state in conjunction with the x number of the system transistors 12, and the (n-x) number of the system monitor transistors 15 are turned into an off state in conjunction with the (n-x) number of the system transistors 12. Thereby, the monitor transistor 14 is turned into an on state so as to be in conjunction with the main transistor 11 in such a state that some of the current paths are conductive and some of the current paths are non-conductive.

The monitor transistor 14 generates the output monitor current IOM which includes the x number of the system monitor currents ISM generated by the x number of the system monitor transistors 15 and monitors the output current IO. In other words, the monitor transistor 14 generates the output monitor current IOM including the x number of the system monitor currents ISM exceeding 0 A and the (n-x) number of the system monitor currents ISM constituted of 0 A. In this case, the monitor transistor 14 is relatively decreased in channel utilization rate and relatively increased in on-resistance.

In FIG. 6A to FIG. 6C, some of or all (in this embodiment, all) of the output monitor currents IOM generated by the monitor transistor 14 are input into the overcurrent protection circuit 21 (see FIG. 3). When the output monitor current IOM exceeds a predetermined threshold, the overcurrent protection circuit 21 generates the overcurrent detecting signal SOD and outputs the overcurrent detecting signal SOD to the gate drive circuit 19.

The gate drive circuit 19 limits some of or all of the n-number of the gate signals G in response to the overcurrent detecting signal SOD and limits some of or all of the n-number of the system currents IS generated by the n-number of the system transistors 12. Thereby, an overcurrent state of the main transistor 11 is eliminated. When the output monitor current IOM is at a value not more than a predetermined threshold, the overcurrent protection circuit 21 stops generation of the overcurrent detecting signal SOD and shifts the gate drive circuit 19 (main transistor 11) to normal control.

On the other hand, in FIG. 6A to FIG. 6C, the first temperature detecting signal ST1 which is generated by the first temperature-sensitive diode 17A and the second temperature detecting signal ST2 which is generated by the second temperature-sensitive diode 17B are input into the thermal shutdown circuit 22 (see FIG. 3). The overcurrent protection circuit 21 generates the difference signal ΔVf on the basis of the first temperature detecting signal ST1 and the second temperature detecting signal ST2. The overcurrent protection circuit 21 generates the overheat detecting signal SOH when the difference signal ΔVf exceeds the threshold VT and outputs the overheat detecting signal SOH to the gate drive circuit 19.

The gate drive circuit 19 restricts a part of or an entirety of the n-number of the gate signals G in response to the overheat detecting signal SOH and restricts a part of or an entirety of the n-number of the system currents IS which are generated by the n-number of the system transistors 12. Thereby, a part of or an entirety of the main transistor 11 is controlled so as to be in an off state, and at the same time, a part of or an entirety of the monitor transistor 14 is controlled so as to be in an off state. Thereby, an overheat state of the output region 7 is eliminated. The overcurrent protection circuit 21 stops generating the overheat detecting signal SOH when the difference signal ΔVf is lower than the threshold VT and shifts the gate drive circuit 19 to ordinary control.

As described above, in the semiconductor device 1A, the n-system main transistor 11 is configured so that an on-resistance (channel utilization rate) is changed by individually controlling the n-number of the system transistors 12. Specifically, the main transistor 11 is controlled so that an on-resistance during an active clamp operation is made different from an on-resistance during a normal operation by individually controlling the n-number of the system transistors 12. More specifically, the main transistor 11 is controlled so that an on-resistance during the active clamp operation exceeds an on-resistance during the normal operation by individually controlling the n-number of the system transistors 12.

On the other hand, the monitor transistor 14 is configured so as to be changed in on-resistance (channel utilization rate) by individually controlling the m-number (in this embodiment, m=n) of the system monitor transistors 15. Specifically, the monitor transistor 14 is configured so as to be changed in on-resistance in conjunction with the main transistor 11.

Specifically, the monitor transistor 14 is controlled so that an on-resistance during an active clamp operation is made different from an on-resistance during a normal operation in conjunction with the main transistor 11. More specifically, the monitor transistor 14 is controlled so that an on-resistance during the active clamp operation exceeds an on-resistance during the normal operation in conjunction with the main transistor 11.

On the other hand, the overcurrent protection circuit 21 performs on/off control of the main transistor 11 on the basis of output from the monitor transistor 14 and protects the main transistor 11 from an overcurrent. Further, the thermal shutdown circuit 22 performs on/off control of the main transistor 11 and on/off control of the monitor transistor 14 on the basis of output from the plurality of temperature-sensitive diodes 17, thereby protecting the main transistor 11 and the monitor transistor 14 from overheating. Then, the plurality of ESD diodes 43 protect the main transistor 11 and the control circuit 18 from static electricity.

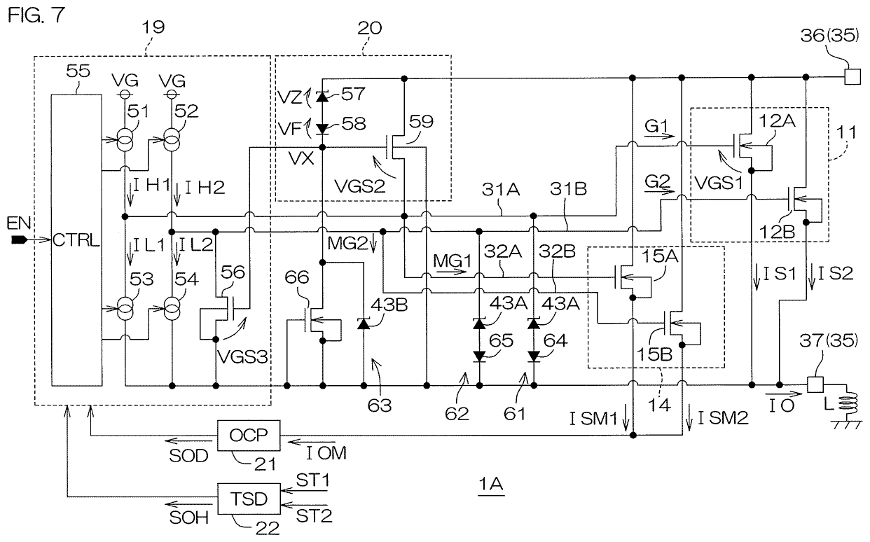

FIG. 7 is a block circuit diagram which shows an electric configuration example of the semiconductor device 1A in FIG. 1 (=configuration example to which 2-system main transistor 11 and 2-system monitor transistor 14 are applied to the semiconductor device 1A). FIG. 7 is also a circuit diagram which shows a main portion of the control circuit 18. FIG. 7 shows an example where the inductive load L is connected to the source terminal 37.

The semiconductor device 1A includes the 2-system (n=2) main transistor 11, the 2-system (m=n=2) monitor transistor 14, the two (n=2) main gate wirings 31, the two (m=n=2) monitor gate wirings 32, the gate drive circuit 19, the active clamp circuit 20 and the overcurrent protection circuit 21.

The 2-system main transistor 11 includes a first system transistor 12A and a second system transistor 12B. The two second gates SG configure the two first gates FG. The two second drains SD are each electrically connected to the drain terminal 36. The two second sources SS are each electrically connected to the source terminal 37.

The first system transistor 12A generates a first system current IS1 and the second system transistor 12B generates a second system current IS2. The 2-system main transistor 11 generates the output current IO including the first system current IS1 and the second system current IS2. As apparent from the description above, the second system current IS2 may be different from the first system current IS1 or may be the same as the first system current IS1. Hereinafter, the first system current IS1 is not distinguished from the second system current IS2 and they are simply represented as the system current IS.

The 2-system main transistor 11 is controlled in a first operation mode, a second operation mode and a third operation mode. In the first operation mode, the first and second system transistors 12A and 12B are controlled so as to be in an off state at the same time. In the second operation mode, the first and second system transistors 12A and 12B are controlled so as to be in an on state at the same time. In the third operation mode, only one of the first and second system transistors 12A and 12B is controlled so as to be in an on state. In this embodiment, in the third operation mode, the first system transistor 12A is controlled so as to be in an on state and the second system transistor 12B is controlled so as to be in an off state.

The 2-system monitor transistor 14 includes a first system monitor transistor 15A and a second system monitor transistor 15B. The two second monitor gates SMG configure the two first monitor gates FMG. The two second monitor drains SMD are each electrically connected to the drain terminal 36. The two second monitor sources SMS are electrically separated from the source terminal 37 (second sources SS of first and second system transistors 12A and 12B).

The first system monitor transistor 15A generates a first system monitor current ISM1 and the second system monitor transistor 15B generates a second system monitor current ISM2. The 2-system monitor transistor 14 generates the output monitor current IOM including the first system monitor current ISM1 and the second system monitor current ISM2. As apparent from the description above, the second system monitor current ISM2 may be different from the first system monitor current ISM1 or may be the same as the first system monitor current ISM1. Hereinafter, the first system monitor current ISM1 is not distinguished from the second system monitor current ISM2 and they are simply represented as the system monitor current ISM.

The 2-system monitor transistor 14 is controlled in a first operation mode, a second operation mode and a third operation mode. In the first operation mode, the first and second system monitor transistors 15A and 15B are controlled so as to be in an off state at the same time. In the second operation mode, the first and second system monitor transistors 15A and 15B are controlled so as to be in an on state at the same time. In the third operation mode, only one of the first and second system monitor transistors 15A and 15B is controlled so as to be in an on state.

In this embodiment, in the third operation mode, the first system monitor transistor 15A is controlled so as to be in an on state and the second system monitor transistor 15B is controlled so as to be in an off state. In this embodiment, the first to third operation modes of the monitor transistor 14 are executed in conjunction with the first to third operation modes of the main transistor 11.

The two main gate wirings 31 include a first main gate wiring 31A and a second main gate wiring 31B. The first main gate wiring 31A is electrically connected to the second gate SG of the first system transistor 12A. The second main gate wiring 31B is electrically connected to the second gate SG of the second system transistor 12B.

The two monitor gate wirings 32 include a first monitor gate wiring 32A and a second monitor gate wiring 32B. The first monitor gate wiring 32A is electrically connected to the first main gate wiring 31A and the second monitor gate SMG of the first system monitor transistor 15A. The second monitor gate wiring 32B is electrically connected to the second main gate wiring 31B and the second monitor gate SMG of the second system monitor transistor 15B.

In the following description, “a state that is electrically connected to the first main gate wiring 31A” includes “a state that is electrically connected to the second gate SG of the first system transistor 12A” and “a state that is electrically connected to the second monitor gate SMG of the first system monitor transistor 15A.” Also, “a state that is electrically connected to the second main gate wiring 31B” includes “a state that is electrically connected to the second gate SG of the second system transistor 12B” and “a state that is electrically connected to the second monitor gate SMG of the second system monitor transistor 15B.”

The gate drive circuit 19 is electrically connected to the first and second main gate wirings 31A and 31B. The gate drive circuit 19 generates a first gate signal G1 and a second gate signal G2 in response to an enable signal EN and individually outputs the first and second gate signals G1 and G2 to the first and second main gate wirings 31A and 31B. A first monitor gate signal MG1 and a second monitor gate signal MG2 which are input into the first and second system monitor transistors 15A and 15B are respectively constituted of the first and second gate signals G1 and G2.

Specifically, in an enabled state that the enable signal EN is at a high level (EN=H), the gate drive circuit 19 generates the first and second gate signals G1 and G2 which control both of the first and second system transistors 12A and 12B and both of the first and second system monitor transistors 15A and 15B so as to be in an on state. In a disabled state that the enable signal EN is at a low level (EN=L), the gate drive circuit 19 generates the first and second gate signals G1 and G2 which control both of the first and second system transistors 12A and 12B and both of the first and second system monitor transistors 15A and 15B so as to be in an off state.

In this embodiment, the gate drive circuit 19 includes a first current source 51, a second current source 52, a third current source 53, a fourth current source 54, a controller 55 and an n channel type drive MISFET 56. Although not shown specifically, the first current source 51, the second current source 52, the third current source 53, the fourth current source 54, the controller 55 and the drive MISFET 56 are each formed in the control region 10.

The first current source 51 generates a first source current IH1. The first current source 51 is electrically connected to an application end of a boosted voltage VG (=charge pump output) and the first main gate wiring 31A. The second current source 52 generates a second source current IH2. The second current source 52 is electrically connected to the application end of boosted voltage VG and the second main gate wiring 31B.

The third current source 53 generates a first sink current IL1. The third current source 53 is electrically connected to the first main gate wiring 31A and the source terminal 37. The fourth current source 54 generates a second sink current IL2. The fourth current source 54 is electrically connected to the second main gate wiring 31B and the source terminal 37.

The controller 55 is electrically connected to the first to fourth current sources 51 to 54. In an enabled state (EN=H), while controlling the first and second current sources 51 and 52 so as to be in an on state, the controller 55 controls the third and fourth current sources 53 and 54 so as to be in an off state. Thereby, the first source current IH1 is output to the first main gate wiring 31A, and the second source current IH2 is output to the second main gate wiring 31B.

In a disabled state (EN=L), while controlling the first and second current sources 51 and 52 so as to be in an off state, the controller 55 controls the third and fourth current sources 53 and 54 so as to be in an on state. Thereby, the first sink current IL1 is drawn from the first main gate wiring 31A, and the second sink current IL2 is drawn from the second main gate wiring 31B.

The drive MISFET 56 is electrically connected to the second main gate wiring 31B and the source terminal 37. The drive MISFET 56 includes a drain, a source, a gate and a back gate. The drain of the drive MISFET 56 is electrically connected to the second main gate wiring 31B. The source of the drive MISFET 56 is electrically connected to the source terminal 37. The back gate of the drive MISFET 56 is electrically connected to the source terminal 37.

The active clamp circuit 20 is connected between the drain and the gate of the first system transistor 12A. Also, the active clamp circuit 20 is connected between the drain and the gate of the first system monitor transistor 15A. The active clamp circuit 20 is configured so as to control both of the first system transistor 12A and the first system monitor transistor 15A in an on state and control both of the second system transistor 12B and the second system monitor transistor 15B in an off state in collaboration with the gate drive circuit 19, when the first source FS (source terminal 37) of the main transistor 11 is at a negative voltage.

Specifically, the active clamp circuit 20 has an internal node voltage Vx which is electrically connected to the gate drive circuit 19. The active clamp circuit 20 generates the first and second gate signals G1 and G2 which control the gate drive circuit 19 via the internal node voltage Vx and control both of the first system transistor 12A and the first system monitor transistor 15A so as to be in an on state and control both of the second system transistor 12B and the second system monitor transistor 15B so as to be in an off state.

More specifically, the active clamp circuit 20 generates the first and second gate signals G1 and G2 which control both of the first system transistor 12A and the first system monitor transistor 15A so as to be in an on state and control both of the second system transistor 12B and the second system monitor transistor 15B so as to be in an off state by controlling the gate drive circuit 19 via the internal node voltage Vx after being shifted from the enabled state (EN=H) to the disabled state (EN=L) and before the main transistor 11 is shifted to an active clamp operation.

Specifically, that before the main transistor 11 is shifted to an active clamp operation means that before the output voltage VO is clamped. Both of the second system transistor 12B and the second system monitor transistor 15B are controlled so as to be in an off state by the second gate signal G2 which is fixed at the output voltage VO. That is, a line between the gate and the source of the second system transistor 12B is short-circuited, and a line between the gate and the source the second system monitor transistor 15B is short-circuited.

The active clamp circuit 20 limits a drain-source voltage (=VBB−VOUT) of the main transistor 11 to a voltage not more than a clamp voltage Vclp. In this embodiment, the second system transistor 12B and the second system monitor transistor 15B are not involved in the active clamp operation. Therefore, the active clamp circuit 20 is not connected to the second system transistor 12B and the second system monitor transistor 15B.

In this embodiment, the active clamp circuit 20 includes a Zener diode array 57, a diode array 58 and an n channel type clamp MISFET 59. Although not shown specifically, the Zener diode array 57, the diode array 58 and the clamp MISFET 59 are each formed in the control region 10.

The Zener diode array 57 is constituted of a series circuit including a plurality (for example, eight) of Zener diodes connected in series in a forward direction. The number of the Zener diodes is arbitrary, and the number of the Zener diodes may be one. The Zener diode array 57 includes a cathode and an anode. The cathode of the Zener diode array 57 is electrically connected to the drain terminal 36 and the second drains SD of the first and second system transistors 12A and 12B.

The diode array 58 is constituted of a series circuit including a plurality (for example, three) of pn-junction diodes connected in series in a forward direction. The number of the pn-junction diodes is arbitrary, and the number of the pn-junction diodes may be one. The diode array 58 includes a cathode and an anode. The anode of the diode array 58 is connected to the anode of the Zener diode array 57 in a reverse biased manner.

The clamp MISFET 59 includes a drain, a source, a gate and a back gate. The drain of the clamp MISFET 59 is electrically connected to the drain terminal 36 and the second drains SD of the first and second system transistors 12A and 12B. The source of the clamp MISFET 59 is electrically connected to the first main gate wiring 31A. The gate of the clamp MISFET 59 is electrically connected to the cathode of the diode array 58. The back gate of the clamp MISFET 59 is electrically connected to the source terminal 37.

The internal node voltage Vx of the active clamp circuit 20 is electrically connected to the gate of the drive MISFET 56. The active clamp circuit 20 controls the drive MISFET 56 so as to be in an on state or in an off state according to the internal node voltage Vx. The internal node voltage Vx may be a voltage inside the active clamp circuit 20. The internal node voltage Vx may be a gate voltage of the clamp MISFET 59 or may be a cathode voltage of any one of the pn-junction diodes of the diode array 58.

In this embodiment, the semiconductor device 1A includes a first protection circuit 61, a second protection circuit 62 and a third protection circuit 63 as an example of an electrostatic breakdown protection circuit which protect various types of circuits from static electricity.

The first protection circuit 61 protects the first system transistor 12A from static electricity. The first protection circuit 61 is electrically connected to the first main gate wiring 31A and the source terminal 37. In this embodiment, the first protection circuit 61 is constituted of a first diode pair which includes the first ESD diode 43A connected in a reverse biased manner and a first pn-junction diode 64.

The cathode of the first ESD diode 43A is electrically connected to the first main gate wiring 31A. The first pn-junction diode 64 includes a cathode and an anode. The anode of the first pn-junction diode 64 is connected in a reverse biased manner to the anode of the first ESD diode 43A. The cathode of the first pn-junction diode 64 is electrically connected to the source terminal 37.

The second protection circuit 62 protects the second system transistor 12B from static electricity. The second protection circuit 62 is electrically connected to the second main gate wiring 31B and the source terminal 37. In this embodiment, the second protection circuit 62 is constituted of a second diode pair which includes the first ESD diode 43A connected in a reverse biased manner and a second pn-junction diode 65.

The cathode of the first ESD diode 43A is electrically connected to the second main gate wiring 31B. The second pn-junction diode 65 includes a cathode and an anode. The anode of the second pn-junction diode 65 is connected in a reverse biased manner to the anode of the first ESD diode 43A. The cathode of the second pn-junction diode 65 is electrically connected to the source terminal 37.

The third protection circuit 63 protects the active clamp circuit 20 from static electricity. The third protection circuit 63 is electrically connected to the active clamp circuit 20 and the source terminal 37. The third protection circuit 63 is constituted of a parallel circuit which includes a depression-type n-channel type protection MISFET 66 and the first ESD diode 43A. The protection MISFET 66 includes a drain, a source, a gate and a back gate.

The drain of the protection MISFET 66 is electrically connected to the gate of the clamp MISFET 59. The source, the gate and the back gate of the protection MISFET 66 are electrically connected to the source terminal 37. The cathode of the second ESD diode 43B is electrically connected to the drain of the protection MISFET 66 (gate of the clamp MISFET 59). The anode of the first ESD diode 43A is electrically connected to the source terminal 37.

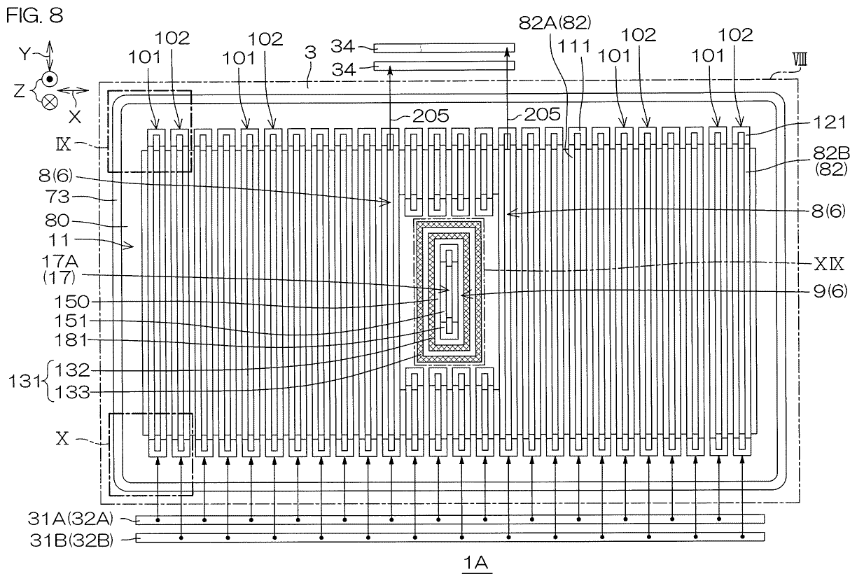

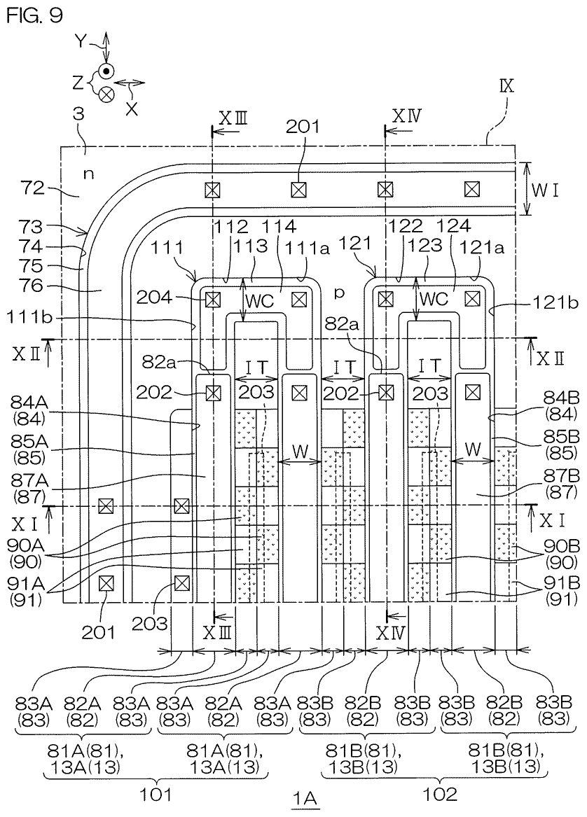

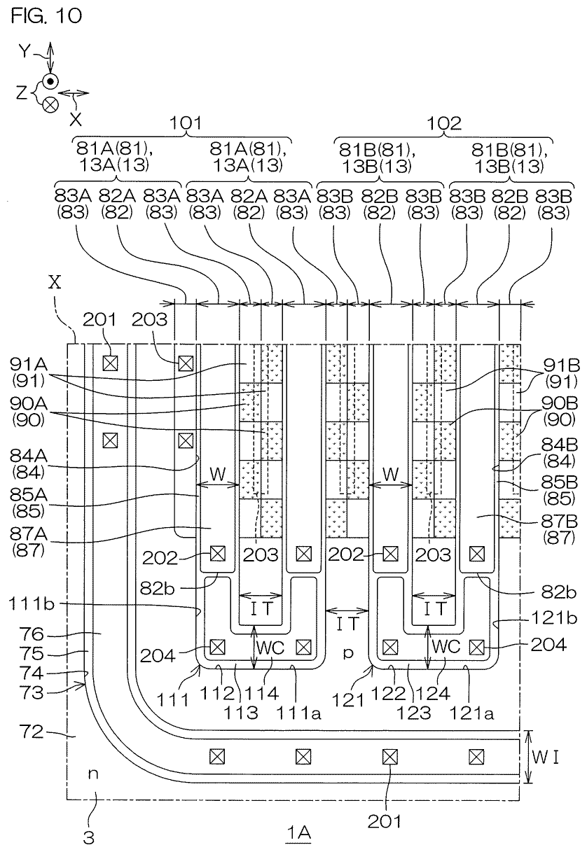

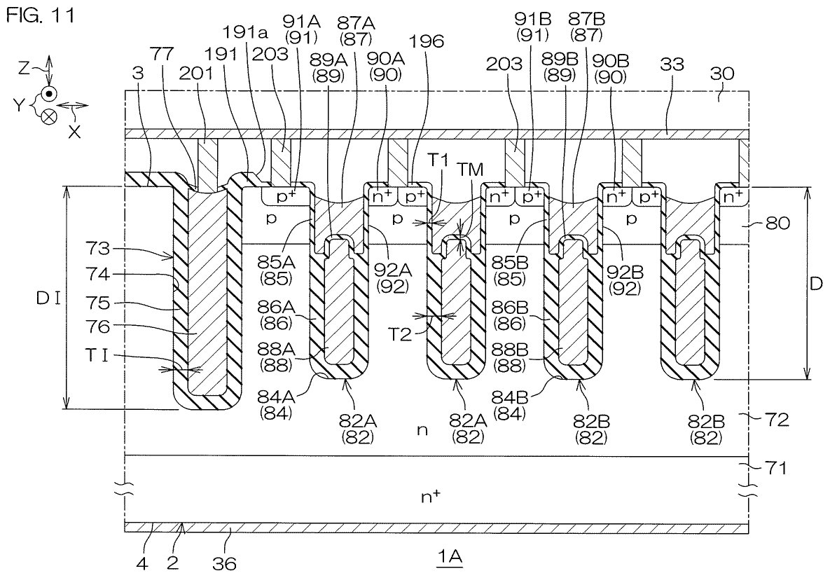

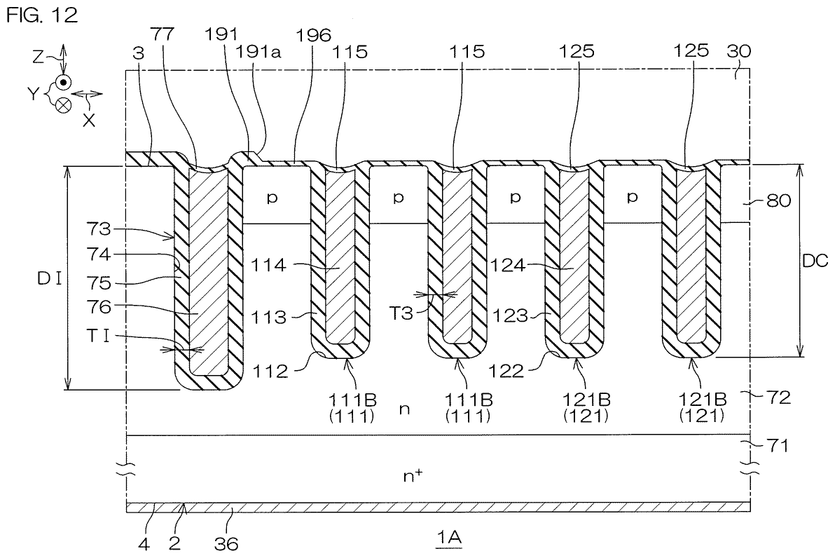

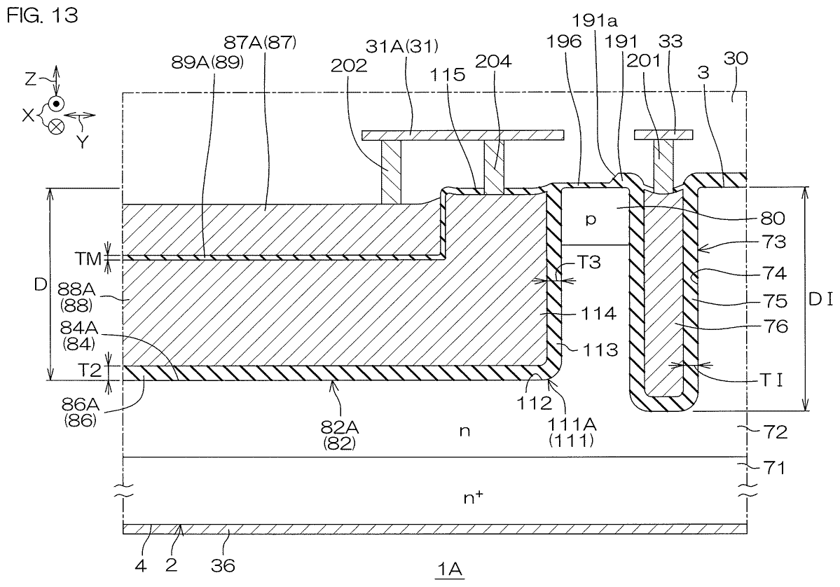

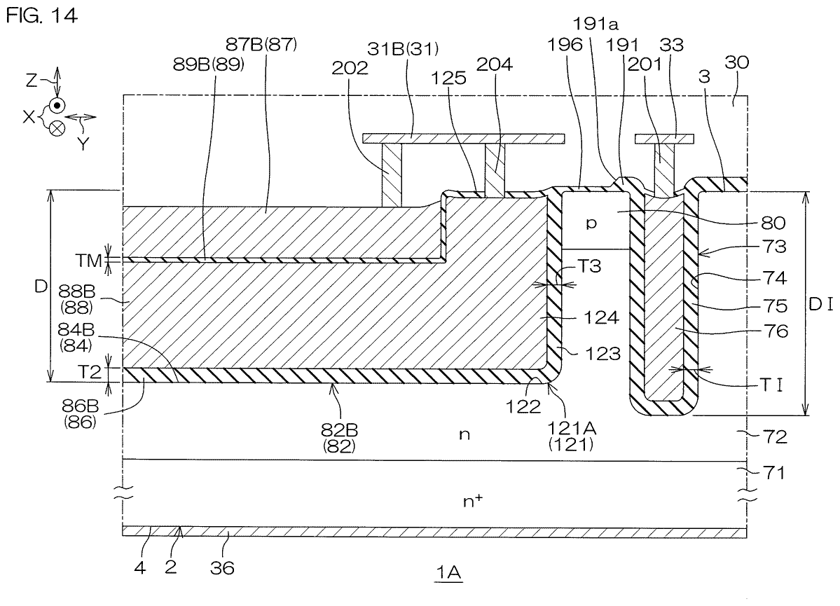

FIG. 8 is an enlarged view of a region VIII shown in FIG. 1 and a plan view which shows a layout example of the output region 7 shown in FIG. 7. FIG. 9 is an enlarged view of a region IX shown in FIG. 8. FIG. 10 is an enlarged view of a region X shown in FIG. 8. FIG. 11 is a cross-sectional view taken along line XI-XI shown in FIG. 9. FIG. 12 is a cross-sectional view taken along line XII-XII shown in FIG. 9. FIG. 13 is a cross-sectional view taken along line XIII-XIII shown in FIG. 9. FIG. 14 is a cross-sectional view taken along line XIV-XIV shown in FIG. 9.

With reference to FIG. 8 to FIG. 14, the semiconductor device 1A includes an n-type first semiconductor region 71 which is formed in a surface layer portion of the second main surface 4 of the chip 2. The first semiconductor region 71 forms the first drain FD of the main transistor 11 and the first monitor drain FMD of the monitor transistor 14. The first semiconductor region 71 may be referred to as a “drain region.” The first semiconductor region 71 is formed in an entire area of the surface layer portion of the second main surface 4 and exposed from the second main surface 4 and the first to fourth side surfaces 5A to 5D.

An n-type impurity concentration of the first semiconductor region 71 may be not less than 1×10¹⁸ cm⁻³ and not more than 1×10²¹ cm⁻³. A thickness of the first semiconductor region 71 may be not less than 10 μm and not more than 450 μm. The thickness of the first semiconductor region 71 is preferably not less than 50 μm and not more than 150 μm. In this embodiment, the first semiconductor region 71 is formed of an n-type semiconductor substrate (Si substrate).

The semiconductor device 1A includes an n-type second semiconductor region 72 which is formed in a surface layer portion of the first main surface 3 of the chip 2. The second semiconductor region 72 forms the first drain FD of the main transistor 11 and the first monitor drain FMD of the monitor transistor 14 together with the first semiconductor region 71. The second semiconductor region 72 may be referred to as a “drift region.” The second semiconductor region 72 is formed in an entire area of the surface layer portion of the first main surface 3 so as to be electrically connected to the first semiconductor region 71 and exposed from the first main surface 3 and the first to fourth side surfaces 5A to 5D.

The second semiconductor region 72 has an n-type impurity concentration less than the first semiconductor region 71. The n-type impurity concentration of the second semiconductor region 72 may be not less than 1×10¹⁵ cm⁻³ and not more than 1×10¹⁸ cm⁻³. The second semiconductor region 72 has a thickness less than the thickness of the first semiconductor region 71. The thickness of the second semiconductor region 72 may be not less than 1 μm and not more than 25 μm. The thickness of the second semiconductor region 72 is preferably not less than 5 μm and not more than 15 μm. In this embodiment, the second semiconductor region 72 is formed of an n-type epitaxial layer (Si epitaxial layer).

The semiconductor device 1A includes a first trench separation structure 73 as an example of a region separation structure which demarcates the output region 7 in the first main surface 3. The first trench separation structure 73 may be referred to as a “DTI (deep trench isolation) structure.” The first trench separation structure 73 is formed in an annular shape surrounding some regions of the first main surface 3 in a plan view and demarcates the output region 7 which is in a predetermined shape.

In this embodiment, the first trench separation structure 73 is formed in a quadrilateral annular shape having four sides parallel to the first to fourth side surfaces 5A to 5D in a plan view and demarcates the output region 7 in a quadrilateral shape. The planar shape of the first trench separation structure 73 is arbitrary and the first trench separation structure 73 may be formed in a polygonal annular shape. The output region 7 may be demarcated in a polygonal shape according to the planar shape of the first trench separation structure 73.

The first trench separation structure 73 has a separation width WI and a separation depth DI. The separation width WI is a width in a direction orthogonal to a direction in which the first trench separation structure 73 extends in a plan view. The separation width WI may be not less than 0.5 μm and not more than 2.5 μm. The separation width WI is preferably not less than 1.2 μm and not more than 2 μm. The separation depth DI may be not less than 1 μm and not more than 10 μm. The separation depth DI is preferably not less than 2 μm and not more than 6 μm.

An aspect ratio DI/WI of the first trench separation structure 73 may be more than 1 and not more than 5. The aspect ratio DI/WI is a ratio of the separation depth DI to the separation width WI. The aspect ratio DI/WI is preferably not less than 2. A bottom wall of the first trench separation structure 73 is preferably at an interval of not less than 1 μm and not more than 5 μm from a bottom portion of the second semiconductor region 72.

The first trench separation structure 73 has a corner portion which connects a portion extending in the first direction X with a portion extending in the second direction Y in a circular arc shape (curved shape). In this embodiment, four corners of the first trench separation structure 73 are formed in a circular arc shape. That is, the output region 7 is demarcated in a quadrilateral shape having four corners, each of which extends in a circular arc shape. The corner portion of the first trench separation structure 73 preferably has a constant separation width WI along a circular arc direction.

The first trench separation structure 73 has a single electrode structure including a first separation trench 74, a first separation insulating film 75 (first separation insulator), a first separation electrode 76 and a first separation cap insulating film 77. The first separation trench 74 is dug down from the first main surface 3 toward the second main surface 4. The first separation trench 74 is formed at an interval from the bottom portion of the second semiconductor region 72 to the first main surface 3 side. The first separation trench 74 may be formed in a tapered shape in which an opening width is narrowed from an opening to the bottom wall.

The first separation insulating film 75 is formed on a wall surface of the first separation trench 74. Specifically, the first separation insulating film 75 is formed as a film on the wall surface of the first separation trench 74 and demarcates a recess space inside the first separation trench 74. The first separation insulating film 75 may include a silicon oxide film. It is preferable that the first separation insulating film 75 includes a silicon oxide film constituted of an oxide of the chip 2.

The first separation insulating film 75 has a separation thickness TI. The separation thickness TI is a thickness along a normal direction of the wall surface of the first separation trench 74. The separation thickness TI may be not less than 0.1 μm and not more than 1 μm. The separation thickness TI is preferably not less than 0.15 μm and not more than 0.65 μm. In the first separation insulating film 75, a thickness of a portion which covers the bottom wall of the first separation trench 74 may be less than a thickness of a portion which covers the side wall of the first separation trench 74.

The first separation electrode 76 is embedded as an integrated member in the first separation trench 74 across the first separation insulating film 75. In this embodiment, the first separation electrode 76 may include conductive polysilicon. A source potential (reference potential which serves as a reference of circuit operation) is to be applied to the first separation electrode 76. The first separation electrode 76 has an electrode surface which is exposed from the first separation trench 74. The electrode surface of the first separation electrode 76 may be recessed toward the bottom wall of the first separation trench 74 in a curved shape.

The first separation cap insulating film 77 covers the electrode surface of the first separation electrode 76 as a film inside the first separation trench 74. The first separation cap insulating film 77 continues to the first separation insulating film 75. The first separation cap insulating film 77 may include a silicon oxide film. It is preferable that the first separation cap insulating film 77 includes a silicon oxide film constituted of an oxide of the first separation electrode 76. That is, it is preferable that the first separation cap insulating film 77 includes an oxide of polysilicon and the first separation insulating film 75 includes an oxide of silicon monocrystal.

The semiconductor device 1A includes a p-type first body region 80 which is formed in a surface layer portion of the first main surface 3 in the output region 7. A p-type impurity concentration of the first body region 80 may be not less than 1×10¹⁶ cm⁻³ and not more than 1×10¹⁸ cm⁻³. The first body region 80 is formed in an entire area of the surface layer portion of the first main surface 3 in the output region 7 and in contact with the side wall of the first trench separation structure 73. The first body region 80 is formed in a region on the first main surface 3 side with respect to the bottom wall of the first trench separation structure 73. The first body region 80 is preferably formed in a region on the first main surface 3 side with respect to an intermediate portion of the first trench separation structure 73.

The semiconductor device 1A includes the main transistor 11 which is formed in the first main surface 3 in the output region 7. The main transistor 11 is formed in the first main surface 3 at an interval from the first trench separation structure 73 in a plan view. The main transistor 11 includes the plurality of unit transistors 13 which are formed so as to concentrate in the first main surface 3 of the output region 7.

The number of the unit transistors 13 is arbitrary. FIG. 10 shows an example where the 60 unit transistors 13 are formed. The number of the unit transistors 13 is preferably an even number. The plurality of unit transistors 13 are aligned in a single row in the first direction X in a plan view and are each formed as a band shape extending in the second direction Y. The plurality of unit transistors 13 are formed as a stripe pattern extending in the second direction Y in a plan view.

Specifically, the plurality of unit transistors 13 are each constituted of a unit cell 81. Each unit cell 81 includes one trench structure 82 and a channel cell 83 which is controlled by the trench structure 82. The trench structure 82 may be referred to as a “gate structure” or a “trench gate structure.”

Each trench structure 82 configures the third gate TG of each unit transistor 13. The channel cell 83 is a region in which opening/closing of a current path is controlled by the trench structure 82. In this embodiment, the unit cell 81 includes a pair of the channel cells 83 which are formed on both sides of one trench structure 82.

The plurality of trench structures 82 are arrayed at an interval in the first direction X in a plan view and are each formed as a band shape extending in the second direction Y. That is, the plurality of trench structures 82 are formed as a stripe pattern extending in the second direction Y in a plan view. The plurality of trench structures 82 each have a first end portion 82a on one side and a second end portion 82b on the other side with respect to a longitudinal direction (second direction Y).

Each trench structure 82 has a trench width W and a trench depth D. The trench width W is a width in a direction orthogonal to a direction in which the trench structure 82 extends (first direction X). The trench width W is preferably less than the separation width WI of the first trench separation structure 73 (W<WI). The trench width W may be not less than 0.5 μm and not more than 2 μm. The trench width W is preferably not less than 0.5 μm and not more than 1.5 μm. As a matter of course, the trench width W may be substantially equal to the separation width WI (W≈WI).

The trench depth D is preferably less than the separation depth DI of the first trench separation structure 73 (D<DI). The trench depth D may be not less than 1 μm and not more than 10 μm. The trench depth D is preferably not less than 2 μm and not more than 6 μm. As a matter of course, the trench depth D may be substantially equal to the separation depth DI (D≈DI).

An aspect ratio D/W of the trench structure 82 may be more than 1 and not more than 5. The aspect ratio D/W is a ratio of the trench depth D to the trench width W. The aspect ratio D/W is in particular preferably not less than 2. A bottom wall of the trench structure 82 is preferably at an interval of not less than 1 μm and not more than 5 μm from the bottom portion of the second semiconductor region 72.

The plurality of trench structures 82 are arrayed with a trench interval IT kept in the first direction X. The trench interval IT is preferably set at a value at which a depletion layer expanding from the plurality of trench structures 82 is made integral further below the bottom wall of the plurality of trench structures 82. The trench interval IT may be not less than 0.25 times the trench width W and not more than 1.5 times the trench width W. The trench interval IT is preferably not more than the trench width W (IT≤W). The trench interval IT may be not less than 0.5 μm and not more than 2 μm.

Hereinafter, a description of a configuration of one trench structure 82 shall be given. The trench structure 82 has a multi-electrode structure including a trench 84, an upper insulating film 85, a lower insulating film 86, an upper electrode 87, a lower electrode 88 and an intermediate insulating film 89. The trench 84 may be referred to as a “gate trench.” The trench structure 82 includes an electrode (gate electrode) which is embedded in the trench 84 across an insulator (gate insulator). The insulator is constituted of the upper insulating film 85, the lower insulating film 86 and the intermediate insulating film 89. The electrode is constituted of the upper electrode 87 and the lower electrode 88.

The trench 84 is dug down from the first main surface 3 toward the second main surface 4. The trench 84 penetrates through the first body region 80 and is formed at an interval from the bottom portion of the second semiconductor region 72 to the first main surface 3 side. The trench 84 may be formed in a tapered shape in which an opening width is narrowed from an opening to the bottom wall. A corner portion of the bottom wall of the trench 84 is preferably formed in a curved shape. An entirety of the bottom wall of the trench 84 may be formed in a curved shape toward the second main surface 4.

The upper insulating film 85 covers an upper wall surface of the trench 84. Specifically, the upper insulating film 85 covers the upper wall surface of the trench 84 located in a region on the opening side thereof with respect to a bottom portion of the first body region 80. The upper insulating film 85 crosses a boundary between the second semiconductor region 72 and the first body region 80. The upper insulating film 85 has a portion which covers the first body region 80 and a portion which covers the second semiconductor region 72.

The area covered by the upper insulating film 85 with respect to the first body region 80 is larger than the area covered by upper insulating film 85 with respect to the second semiconductor region 72. The upper insulating film 85 preferably includes a silicon oxide film. It is preferable that the upper insulating film 85 includes a silicon oxide film constituted of an oxide of the chip 2. The upper insulating film 85 is formed as a gate insulating film.

The upper insulating film 85 has a first thickness T1. The first thickness T1 is a thickness along a normal direction of a wall surface of the trench 84. The first thickness T1 is less than the separation thickness TI of the first separation insulating film 75 (T1<TI). The first thickness T1 may be not less than 0.01 μm and not more than 0.05 μm. The first thickness T1 is preferably not less than 0.02 μm and not more than 0.04 μm.

The lower insulating film 86 covers a lower wall surface of the trench 84. Specifically, the lower insulating film 86 covers the lower wall surface of the trench 84 which is located in a region on the bottom wall side thereof with respect to the bottom portion of the first body region 80. The lower insulating film 86 demarcates a recess space in a region on the bottom wall side of the trench 84. The lower insulating film 86 is in contact with the second semiconductor region 72. The lower insulating film 86 may include a silicon oxide film. It is preferable that the lower insulating film 86 incudes a silicon oxide film constituted of an oxide of the chip 2.

The lower insulating film 86 has a second thickness T2. The second thickness T2 is a thickness along a normal direction of the wall surface of the trench 84. The second thickness T2 exceeds the first thickness T1 of the upper insulating film 85 (T1<T2). The second thickness T2 may be substantially equal to the separation thickness TI of the first separation insulating film 75 (T2≈TI). The second thickness T2 may be not less than 0.1 μm and not more than 1 μm. The second thickness T2 is preferably not less than 0.15 μm and not more than 0.65 μm. In the lower insulating film 86, a thickness of a portion which covers the bottom wall of the trench 84 may be less than a thickness of a portion which covers the side wall of the trench 84.

The upper electrode 87 is embedded on the upper side (opening side) inside the trench 84 across the upper insulating film 85. The upper electrode 87 is embedded as a band shape extending in the second direction Y in a plan view. The upper electrode 87 faces the first body region 80 and the second semiconductor region 72 across the upper insulating film 85. A facing area of the upper electrode 87 with respect to the first body region 80 is larger than a facing area of the upper electrode 87 with respect to the second semiconductor region 72. The upper electrode 87 may include conductive polysilicon. The upper electrode 87 is formed as a gate electrode. The gate signal G is input into the upper electrode 87.

The upper electrode 87 has an electrode surface which is exposed from the trench 84. The electrode surface of the upper electrode 87 may be recessed in a curved shape toward the bottom wall of the trench 84. The electrode surface of the upper electrode 87 is preferably positioned further on the bottom wall side of the trench 84 than a depth position of the electrode surface of the first separation electrode 76 with respect to a depth direction of the trench 84.

The lower electrode 88 is embedded on the lower side (bottom wall side) inside the trench 84 across the lower insulating film 86. The lower electrode 88 is embedded as a band shape extending in the second direction Y in a plan view. The lower electrode 88 may have a thickness (length) exceeding a thickness (length) of the upper electrode 87 with respect to the depth direction of the trench 84.

The lower electrode 88 faces the second semiconductor region 72 across the lower insulating film 86. The lower electrode 88 has an upper end portion protruding to the first main surface 3 side from the lower insulating film 86. The upper end portion of the lower electrode 88 engages with the bottom portion of the upper electrode 87 and faces the upper insulating film 85 across the bottom portion of the upper electrode 87 in a lateral direction along the first main surface 3.

The lower electrode 88 may include conductive polysilicon. In this embodiment, the lower electrode 88 is formed as a gate electrode. The lower electrode 88 is fixed at the same potential as the upper electrode 87. That is, the same gate signal G is to be applied to the lower electrode 88 at the same time with the upper electrode 87. Thereby, since it is possible to suppress a voltage drop between the upper electrode 87 and the lower electrode 88, it is possible to suppress an electric field concentration between the upper electrode 87 and the lower electrode 88. Also, the chip 2 (in particular, second semiconductor region 72) can be decreased in on-resistance due to an improvement in carrier density in the vicinity of the trench 84.

The intermediate insulating film 89 is interposed between the upper electrode 87 and the lower electrode 88 and electrically insulates the upper electrode 87 and the lower electrode 88. Specifically, the intermediate insulating film 89 covers the lower electrode 88 which is exposed from the lower insulating film 86 in a region between the upper electrode 87 and the lower electrode 88. The intermediate insulating film 89 continues to the upper insulating film 85 and the lower insulating film 86. The intermediate insulating film 89 may include a silicon oxide film. It is preferable that the intermediate insulating film 89 includes a silicon oxide film constituted of an oxide of the lower electrode 88.

The intermediate insulating film 89 has an intermediate thickness TM with respect to the normal direction Z. The intermediate thickness TM is less than the second thickness T2 of the lower insulating film 86 (TM<T2). The intermediate thickness TM may be not less than 0.01 μm and not more than 0.05 μm. The intermediate thickness TM is preferably not less than 0.02 μm and not more than 0.04 μm.

The pair of channel cells 83 are each formed as a band shape extending in the second direction Y on both sides of each trench structure 82. The pair of channel cells 83 have a length less than a length of the trench structure 82 with respect to the second direction Y. An entire area of the pair of channel cells 83 faces the upper electrode 87 across the upper insulating film 85. The pair of channel cells 83 each have a channel width equivalent to a value that is one-half the trench interval IT.

The pair of channel cells 83 include at least one n-type source region 90 which is formed in a surface layer portion of the first body region 80. The number of the source regions 90 included in the pair of channel cells 83 is arbitrary. In this embodiment, the pair of channel cells 83 each include the plurality of source regions 90. All of the source regions 90 included in each unit cell 81 forms the third source TS of each unit transistor 13.

An n-type impurity concentration of the source region 90 exceeds the n-type impurity concentration of the second semiconductor region 72. The n-type impurity concentration of the source region 90 may be not less than 1×10¹⁸ cm⁻³ and not more than 1×10²¹ cm⁻³. The plurality of source regions 90 are formed in a region on the first main surface 3 side at an interval from the bottom portion of the first body region 80 and face the upper electrode 87 across the upper insulating film 85. The plurality of source regions 90 are arrayed in each channel cell 83 at an interval in the second direction Y. That is, the plurality of source regions 90 are arrayed on both sides of the corresponding trench structure 82 at an interval along the trench structure 82.

The pair of channel cells 83 include at least one p-type contact region 91 which is formed in a region different from the source region 90 at the surface layer portion of the first body region 80. The number of the contact regions 91 included in the pair of channel cells 83 is arbitrary. In this embodiment, the pair of channel cells 83 each include the plurality of contact regions 91. A p-type impurity concentration of the contact region 91 exceeds the p-type impurity concentration of the first body region 80. The p-type impurity concentration of the contact region 91 may be not less than 1×10¹⁸ cm⁻³ and not more than 1×10²¹ cm⁻³.

The plurality of contact regions 91 are formed in a region on the first main surface 3 side at an interval from the bottom portion of the first body region 80 and face the upper electrode 87 across the upper insulating film 85. The plurality of contact regions 91 are formed alternately with the plurality of source regions 90 in the second direction Y in a manner that one source region 90 is sandwiched therebetween. That is, the plurality of contact regions 91 are arrayed on both sides of the corresponding trench structure 82 at an interval along the trench structure 82.

The pair of channel cells 83 include a plurality of channel regions 92 which are formed between the plurality of source regions 90 and the second semiconductor region 72 inside the first body region 80. On/off control of the plurality of channel regions 92 in the pair of channel cells 83 is performed by one trench structure 82. The plurality of channel regions 92 included in the pair of channel cells 83 form one channel of the unit transistor 13. Thereby, one unit cell 81 functions as one unit transistor 13.

The two unit cells 81 arranged on both sides in the first direction X inside the output region 7 preferably do not include the source region 90 in the channel cell 83 on the first trench separation structure 73 side. According to this structure, it is possible to suppress a leakage current between the trench structure 82 and the first trench separation structure 73. In this embodiment, the two unit cells 81 arranged on both sides which are in close proximity to first trench separation structure 73 include only the contact region 91 (hereinafter, referred to as the “outermost contact region 91”) in the channel cell 83 on the first trench separation structure 73 side.

The outermost contact region 91 is formed at an interval from the first trench separation structure 73 to the trench structure 82 side and is connected to a side wall of the corresponding trench structure 82. The outermost contact region 91 may be formed as a band shape extending along the side wall of the corresponding trench structure 82. The unit cell 81 which is in close proximity to the temperature detecting region 9 in the output region 7 preferably does not include the source region 90 in the channel cell 83 on the temperature detecting region 9 side. In this case, the unit cell 81 preferably only includes the contact region 91 in the channel cell 83 on the temperature detecting region 9 side.

The main transistor 11 includes two (in this embodiment, n=2) system transistors 12 which are formed so as to concentrate in the output region 7. The two system transistors 12 include the first system transistor 12A and the second system transistor 12B. The first system transistor 12A includes a plurality (in this embodiment, 30) of first unit transistors 13A which are selectively systematized as an individually controlled object from the plurality of unit transistors 13.

The second system transistor 12B includes a plurality (in this embodiment, 30) of second unit transistors 13B which are selectively systematized as an individually controlled object from the plurality of unit transistors 13 excluding the first unit transistors 13A. The number of the second unit transistors 13B may be different from the number of the first unit transistors 13A. The number of the second unit transistors 13B is preferably equal to the number of the first unit transistors 13A.

Hereinafter, the “unit cell 81,” the “trench structure 82,” the “channel cell 83,” the “trench 84,” the “upper insulating film 85,” the “lower insulating film 86,” the “upper electrode 87,” the “lower electrode 88,” the “intermediate insulating film 89,” the “source region 90,” the “contact region 91” and the “channel region 92” of the first unit transistor 13A are respectively referred to as a “first unit cell 81A,” a “first trench structure 82A,” a “first channel cell 83A,” a “first trench 84A,” a “first upper insulating film 85A,” a “first lower insulating film 86A,” a “first upper electrode 87A,” a “first lower electrode 88A,” a “first intermediate insulating film 89A,” a “first source region 90A,” a “first contact region 91A” and a “first channel region 92A.” The first gate signal G1 is input into the first upper electrode 87A and the first lower electrode 88A.

Hereinafter, the “unit cell 81,” the “trench structure 82,” the “channel cell 83,” the “trench 84,” the “upper insulating film 85,” the “lower insulating film 86,” the “upper electrode 87,” the “lower electrode 88,” and the “intermediate insulating film 89,” the “source region 90,” the “contact region 91” and the “channel region 92” of the second unit transistor 13B are respectively referred to as a “second unit cell 81B,” a “second trench structure 82B,” a “second channel cell 83B,” a “second trench 84B,” a “second upper insulating film 85B,” a “second lower insulating film 86B,” a “second upper electrode 87B,” a “second lower electrode 88B,” a “second intermediate insulating film 89B,” a “second source region 90B,” a “second contact region 91B” and a “second channel region 92B.” The second gate signal G2 which is electrically independent of the first gate signal G1 is input into the second upper electrode 87B and the second lower electrode 88B.

The first system transistor 12A includes at least one first composite cell 101. The number of the first composite cells 101 is arbitrary and is adjusted according to a size of the output region 7 (a total number of the unit transistors 13). In this embodiment, the first system transistor 12A includes the plurality (in this embodiment, 15) of first composite cells 101.

The plurality of first composite cells 101 are each constituted of an α-number (α≥2) of the first unit transistors 13A (first unit cell 81A) arrayed which are adjacent to the first main surface 3 in a plan view. The plurality of first composite cells 101 are arrayed at an interval in the first direction X in a plan view.

The second system transistor 12B includes at least one second composite cell 102. The number of the second composite cells 102 is arbitrary and is adjusted according to a size of the output region 7 (a total number of the unit transistors 13). The number of the second composite cells 102 may be different from the number of the first composite cells 101. The number of the second composite cells 102 is preferably equal to the number of the first composite cells 101.

In this embodiment, the second system transistor 12B includes the plurality (in this embodiment, 15) of second composite cells 102. The plurality of second composite cells 102 are each constituted of a β-number (β≥2) of the second unit transistors 13B (second unit cell 81B) which are arrayed adjacent to the first main surface 3 in a plan view.

The plurality of second composite cells 102 are each arranged adjacent to the plurality of first composite cells 101 in a plan view. Specifically, the plurality of second composite cells 102 are each arranged in a region between the plurality of first composite cells 101 which are in close proximity to each other in a plan view. More specifically, the plurality of second composite cells 102 are arrayed alternately with the plurality of first composite cells 101 along the first direction X in a manner that one first composite cell 101 is sandwiched therebetween in a plan view.

The number of the first unit transistors 13A included in one first composite cell 101 may be given as one (α=1) and the number of the second unit transistors 13B included in one second composite cell 102 may be given as one (β=1). That is, the plurality of second unit transistors 13B may be arrayed alternately with the plurality of first unit transistors 13A in a manner that one unit transistor 13 is sandwiched therebetween in a plan view.

However, in this case, the number of the plurality of first unit transistors 13A and the plurality of second unit transistors 13B which face each other increase. As a result, a risk of short circuit between the first unit transistor 13A and the second unit transistor 13B which are in close proximity to each other is increased due to a process error, etc. Here, “short circuit” refers to a short circuit between the first trench structure 82A (third gate TG) of the first unit transistor 13A and the second trench structure 82B (third gate TG) of the second unit transistor 13B (also see the circuit diagram of FIG. 7).

For example, where one first unit transistor 13A short-circuits with one second unit transistor 13B to which the first unit transistor 13A is in close proximity, all of the first unit transistors 13A are short-circuited by all of the second unit transistors 13B. That is, as a result of the first system transistor 12A and the second system transistor 12B functioning as one system transistor 12, the first system transistor 12A and the second system transistor 12B do not configure the 2-system main transistor 11 (also see the circuit diagram of FIG. 7).

Therefore, the number of the first unit transistors 13A included in one first composite cell 101 is preferably not less than 2 (α≥2), and the number of the second unit transistors 13B included in one second composite cell 102 is preferably not less than 2 (β≥2). In this structure, the number of the plurality of first unit transistors 13A and the plurality of second unit transistors 13B which face each other can be decreased. As a result, it is possible to decrease a risk of short circuit between the first unit transistor 13A and the second unit transistor 13B which are in close proximity to each other.

The first unit transistor 13A (specifically, first channel region 92A) serves as a heating source in the output region 7. Therefore, the number of the first unit transistors 13A regulates a heating amount of one first composite cell 101, and an arrangement of the plurality of first composite cells 101 regulates a heating site in the output region 7. That is, an increase in the number of the first unit transistors 13A which configure one first composite cell 101 results in an increase in heating amount inside one first composite cell 101. Also, where the plurality of first composite cells 101 are arranged so as to be mutually adjacent, the heating sites of the output region 7 are localized.

Therefore, the number of the first unit transistors 13A is preferably not more than four (α≤4). According to this structure, it is possible to suppress a local temperature rise in one first composite cell 101. In view of the risk of short circuit and the heating amount, the number of the first unit transistors 13A is in particular preferably two (α=2). The plurality of first composite cells 101 are preferably arrayed at an equal interval in the output region 7. According to this structure, it is possible to thin out the heating sites coming from the plurality of first composite cells 101 in the output region 7 and it is possible to suppress a local temperature rise in the output region 7.

In each first composite cell 101, the plurality of first channel regions 92A (first source regions 90A) arrayed on the side of one of the first trench structures 82A preferably face a region between the plurality of first channel regions 92A (first source regions 90A) arrayed on the side of the other of the first trench structures 82A in the first direction X. According to this structure, it is possible to thin out starting points of heating in each first composite cell 101. Thereby, it is possible to suppress a local temperature rise in each first composite cell 101.

In this case, in each first unit cell 81A, the plurality of first channel regions 92A formed in one of the first channel cells 83A preferably face the plurality of first channel regions 92A formed in the other of the first channel cells 83A across the corresponding first trench structure 82A.

In each first composite cell 101, the plurality of first channel regions 92A formed in a region between a pair of the first trench structures 82A are preferably arrayed so as to be shifted from each other in the second direction Y in a plan view. As a matter of course, in each first unit cell 81A, the plurality of first channel regions 92A formed in one of the first channel cells 83A may face a region between the plurality of first channel regions 92A formed in the other of the first channel cells 83A across the corresponding first trench structure 82A.

In each first unit cell 81A, the plurality of first contact regions 91A formed in one of the first channel cells 83A may face the plurality of first contact regions 91A formed in the other of the first channel cells 83A across the corresponding first trench structure 82A. In each first composite cell 101, the plurality of first contact regions 91A arrayed on the side of one of the first trench structures 82A may face a region between the plurality of first contact regions 91A arrayed on the side of the other of the first trench structures 82A in the first direction X.

In each first composite cell 101, the plurality of first contact regions 91A formed in a region between the pair of first trench structures 82A may be arrayed so as to be shifted from each other in the second direction Y in a plan view. Also, the plurality of first contact regions 91A may face the plurality of first source regions 90A in the first direction X in a plan view.

The second unit transistor 13B serves as a heating source in the output region 7. Therefore, the number of the second unit transistors 13B regulates a heating amount of one second composite cell 102, and an arrangement of the plurality of second composite cells 102 regulates the heating site in the output region 7. That is, an increase in the number of the second unit transistors 13B which configure one second composite cell 102 results in an increase in heating amount inside one second composite cell 102. Also, where the plurality of second composite cells 102 are arranged so as to be mutually adjacent, the heating sites of the output region 7 are localized.

Therefore, the number of the second unit transistors 13B is preferably not more than four (β≤4). According to this structure, it is possible to suppress a local temperature rise in one second composite cell 102. In this case, the number of the second unit transistors 13B is preferably equal to the number of the first unit transistors 13A. According to this structure, it is possible to suppress a variation in heating range due to the first composite cell 101 and a variation in heating range due to the second composite cell 102. In view of the risk of short circuit and the heating amount, the number of the second unit transistors 13B is in particular preferably two (β=2).

The plurality of second composite cells 102 are preferably arrayed at an equal interval in the output region 7. According to this structure, it is possible to thin out the heating sites coming from the plurality of second composite cells 102 in the output region 7 and it is possible to suppress a local temperature rise in the output region 7. In this case, it is preferable that at least one second composite cell 102 is arranged so as to be in close proximity to at least one first composite cell 101.

According to this structure, it is possible to create such a situation that, in the first composite cell 101 and the second composite cell 102 which are in close proximity to each other, one of the cells is in an on state and the other of the cells is in an off state. It is therefore possible to suppress a local temperature rise due to the first composite cell 101 and the second composite cell 102.

In this case, at least one second composite cell 102 is preferably arranged in a region between the two mutually adjacent first composite cells 101. Further, in this case, it is in particular preferable that the plurality of second composite cells 102 are alternately arrayed with the plurality of first composite cells 101 in a manner that one first composite cell 101 is sandwiched therebetween.

According to the structures above, the two first composite cells 101 which are in close proximity to each other can be isolated at an interval corresponding to the second composite cell 102. Thereby, it is possible to appropriately thin out the heating sites coming from the plurality of first composite cells 101 and the plurality of second composite cells 102 and it is possible to appropriately suppress a local temperature rise in the output region 7.

In each second composite cell 102, the plurality of second channel regions 92B (second source regions 90B) arrayed on the side of one of the second trench structures 82B preferably face a region between the plurality of second channel regions 92B (second source regions 90B) arrayed on the side of the other of the second trench structures 82B in the first direction X. According to this structure, it is possible to thin out starting points of heating in each second composite cell 102. Thereby, it is possible to suppress a local temperature rise in each second composite cell 102.

In this case, in each second unit cell 81B, the plurality of second channel regions 92B formed in one of the second channel cells 83B preferably face the plurality of second channel regions 92B formed in the other of the second channel cells 83B across the corresponding second trench structure 82B. In each second composite cell 102, the plurality of second channel regions 92B formed in a region between a pair of the second trench structures 82B are preferably arrayed so as to be shifted from each other in the second direction Y in a plan view.

The plurality of second channel regions 92B are preferably arrayed so as to be shifted in the second direction Y with respect to the plurality of first channel regions 92A in an inter-trench region between each first trench structure 82A and each second trench structure 82B. That is, the plurality of second channel regions 92B preferably face a region between the plurality of first contact regions 91A in the first direction X in the inter-trench region. According to the structures above, it is possible to thin out starting points of heating in the inter-trench region. It is therefore possible to suppress a local temperature rise in the inter-trench region.

In each second unit cell 81B, the plurality of second contact regions 91B formed in one of the second channel cells 83B may face the plurality of second contact regions 91B formed in the other of the second channel cells 83B across the corresponding second trench structure 82B. In each second composite cell 102, the plurality of second contact regions 91B arrayed on the side of one of the second trench structures 82B may face a region between the plurality of second contact regions 91B arrayed on the side of the other of the second trench structures 82B in the first direction X.

As a matter of course, in each second unit cell 81B, the plurality of second channel regions 92B formed in one of the second channel cells 83B may face a region between the plurality of second channel regions 92B formed in the other of the second channel cells 83B across the corresponding second trench structure 82B.

In each second composite cell 102, the plurality of second contact regions 91B formed in a region between the pair of second trench structures 82B may be arrayed so as to be shifted from each other in the second direction Y in a plan view. The plurality of second contact regions 91B may face the plurality of second source regions 90B in the first direction X in a plan view.

The n-system main transistor 11 has a total channel ratio RT. The total channel ratio RT is a ratio of a total planar area of all of the channel regions 92 which occupies a planar area of all of the channel cells 83. A planar area of each channel region 92 is defined by a planar area of each source region 90. The total channel ratio RT is adjusted in a range of more than 0% and less than 100%. The total channel ratio RT is preferably adjusted in a range of not less than 25% and not more than 75%.

The total channel ratio RT is divided into an n-number of system channel ratios RS by the n-number of the system transistors 12. The total channel ratio RT of the 2-system main transistor 11 is constituted of an added value (RT=RSA+RSB) of a first system channel ratio RSA of the first system transistor 12A and a second system channel ratio RSB of the second system transistor 12B.

The first system channel ratio RSA is a ratio of a total planar area of all of the first channel regions 92A which occupies a total planar area of all of the channel cells 83. The second system channel ratio RSB is a ratio of a total planar area of all of the second channel regions 92B which occupies a total planar area of all of the channel cells 83.

A planar area of each first channel region 92A is defined by a planar area of each first source region 90A, and a planar area of each second channel region 92B is defined by a planar area of each second source region 90B. The first system channel ratio RSA is adjusted by an arrayed pattern of the first source region 90A and the first contact region 91A. The second system channel ratio RSB is adjusted by an arrayed pattern of the second source region 90B and the second contact region 91B.

The first system channel ratio RSA is divided into a plurality of first channel ratios RCA by the plurality of first composite cells 101. The first channel ratio RCA is a ratio of a total planar area of the plurality of first channel regions 92A which occupies a total planar area of all of the channel cells 83 in each first composite cell 101.

The first system channel ratio RSA is constituted of an added value of the plurality of first channel ratios RCA. The plurality of first composite cells 101 preferably have the first channel ratios RCA which are equal to each other. In each first unit transistor 13A, the plurality of first channel regions 92A may be formed in a first area which is different from each other or equal to each other for each unit area.

The second system channel ratio RSB is divided into a plurality of second channel ratios RCB by the plurality of second composite cells 102. The second channel ratio RCB is a ratio of a total planar area of the plurality of second channel regions 92B which occupies a total planar area of all of the channel cells 83 in each second composite cell 102. The plurality of second composite cells 102 are constituted of an added value of the plurality of second channel ratios RCB.

The plurality of second composite cells 102 preferably have the second channel ratios RCB which are equal to each other. In each second unit transistor 13B, the plurality of second channel regions 92B may be formed in a second area which is different from each other or equal to each other for each unit area. The second area may be equal to or different from the first area of the plurality of first channel regions 92A for each unit area.

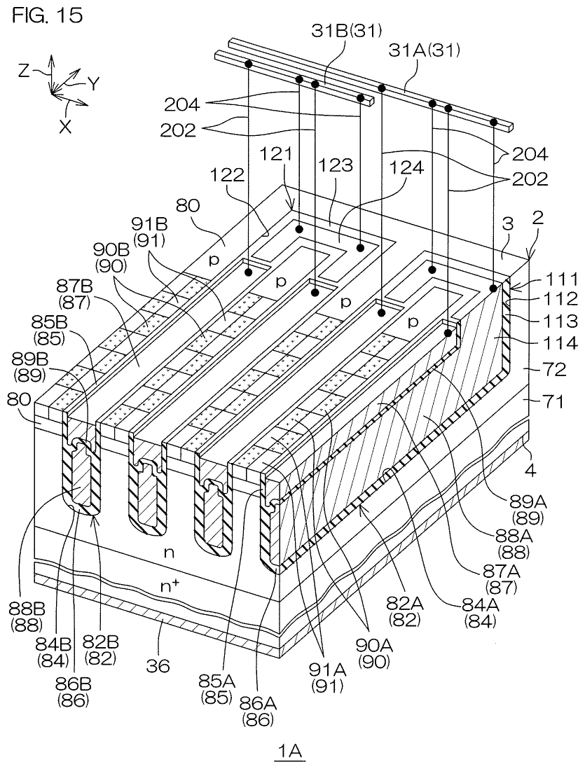

The second system channel ratio RSB may be substantially equal to the first system channel ratio RSA (RSA≈RSB). The second system channel ratio RSB may exceed the first system channel ratio RSA (RSA<RSB). The second system channel ratio RSB may be less than the first system channel ratio RSA (RSB<RSA). Hereinafter, in FIG. 15 to FIG. 18, a configuration example of the first channel is shown.

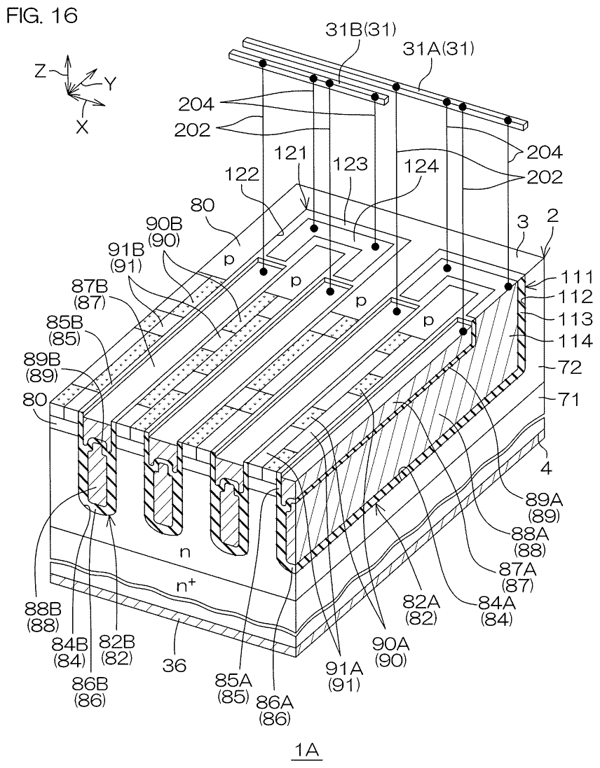

FIG. 15 to FIG. 18 are cross-sectional perspective views which show first to fourth channel configuration examples. In the example of FIG. 15, the total channel ratio RT is 50%, the first system channel ratio RSA is 25% and the second system channel ratio RSB is 25%. In the example of FIG. 16, the total channel ratio RT is 50%, the first system channel ratio RSA is 12.5% and the second system channel ratio RSB is 37.5%.

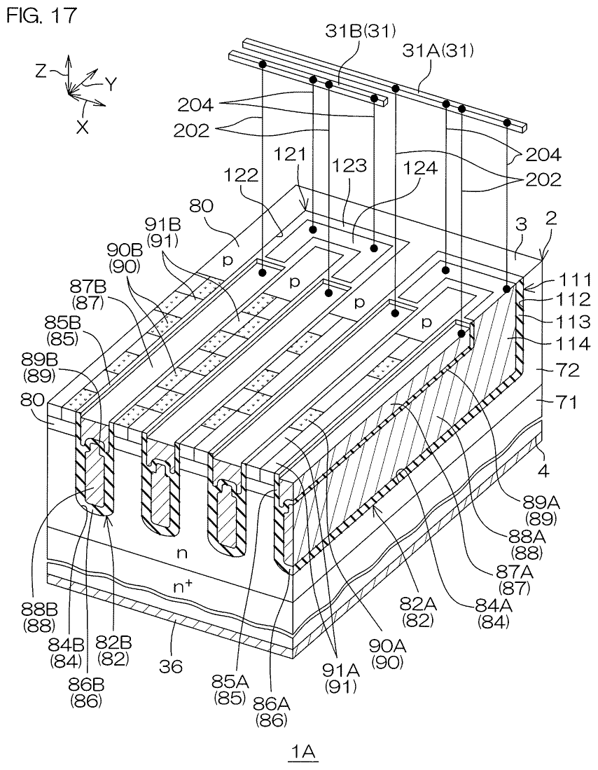

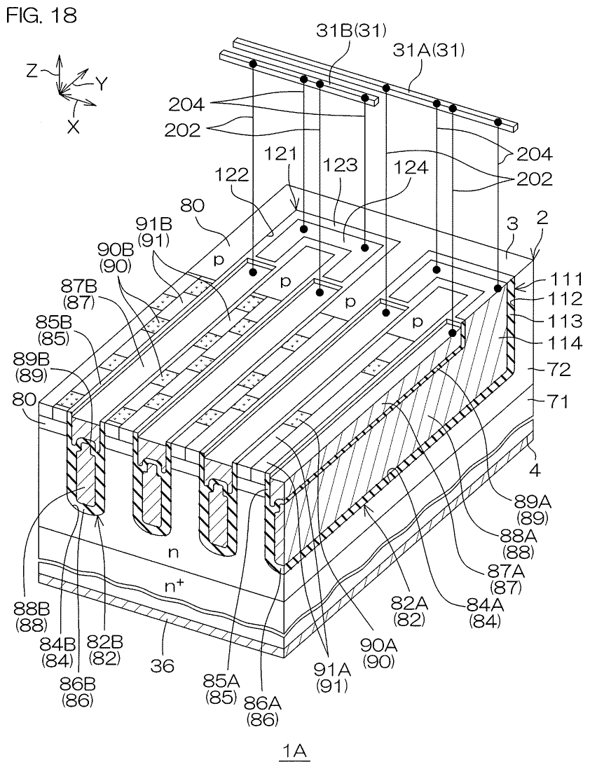

In the example of FIG. 17, the total channel ratio RT is 33%, the first system channel ratio RSA is 8.3% and the second system channel ratio RSB is 24.7%. In the example of FIG. 18, the total channel ratio RT is 25%, the first system channel ratio RSA is 6.3% and the second system channel ratio RSB is 18.7%.

With again reference to FIG. 8 to FIG. 14, the main transistor 11 includes multiple pairs (in this embodiment, 15 pairs, total of 30) of first trench connection structures 111 which are formed in the first main surface 3 in the output region 7. The multiple pairs of first trench connection structures 111 each include the first trench connection structure 111 on one side (first side surface 5A side) and the first trench connection structure 111 on the other side (second side surface 5B side) which face each other across one corresponding first composite cell 101 with respect to the second direction Y.

The first trench connection structure 111 on one side connects the first end portions 82a of the plurality (in this embodiment, one pair) of first trench structures 82A each other in an arch shape in a plan view. The first trench connection structure 111 on the other side connects the second end portions 82b of the plurality (in this embodiment, one pair) of first trench structures 82A each other in an arch shape in a plan view. With the plurality (in this embodiment, one pair) of first trench structures 82A which configure one first composite cell 101, the pair of first trench connection structures 111 configure one annular-shaped trench structure.

The first trench connection structure 111 on the other side has the same structure as the first trench connection structure 111 on one side except that it is connected to the second end portion 82b of the first trench structure 82A. Hereinafter, a description of a configuration of one first trench connection structure 111 on one side shall be given, and a description of a configuration of the first trench connection structure 111 on the other side shall be omitted.

The first trench connection structure 111 on one side has a first portion 111a extending in the first direction X and a plurality (in this embodiment, one pair) of second portions 111b extending in the second direction Y. The first portion 111a faces the plurality of first end portions 82a in a plan view. The plurality of second portions 111b extend from the first portion 111a to the plurality of first end portions 82a and are connected to the plurality of first end portions 82a.

The first trench connection structure 111 on one side has a connection width WC and a connection depth DC. The connection width WC is a width in a direction orthogonal to a direction in which the first trench connection structure 111 extends. The connection width WC is preferably substantially equal to the trench width W of the trench structure 82 (WC≈W). The connection depth DC is preferably substantially equal to the trench depth D of the trench structure 82 (DC≈D).

It is preferable that an aspect ratio DC/WC of the first trench connection structure 111 is substantially equal to the aspect ratio D/W of the trench structure 82 (DC/WC≈D/W). A bottom wall of the first trench connection structure 111 is preferably at an interval of not less than 1 μm and not more than 5 μm from the bottom portion of the second semiconductor region 72.

The first trench connection structure 111 on one side has a single electrode structure including a first connection trench 112, a first connection insulating film 113, a first connection electrode 114 and a first cap insulating film 115. The first connection trench 112 extends in an arch shape so as to be communicatively connected to the first end portions 82a of the plurality of first trenches 84A in a plan view and is dug down from the first main surface 3 to the second main surface 4. The first connection trench 112 demarcates the first portion 111a and the second portion 111b of the first trench connection structure 111. The first connection trench 112 is formed at an interval from the bottom portion of the second semiconductor region 72 to the first main surface 3 side.

The first connection trench 112 may be formed in a tapered shape in which an opening width is narrowed from an opening to the bottom wall. A corner portion of the bottom wall of the first connection trench 112 is preferably formed in a curved shape. An entirety of the bottom wall of the first connection trench 112 may be formed in a curved shape toward the second main surface 4. The side wall and the bottom wall of the first connection trench 112 are smoothly connected to the side wall and the bottom wall of the first trench 84A.

The first connection insulating film 113 is formed on a wall surface of the first connection trench 112. Specifically, the first connection insulating film 113 is formed as a film on the wall surface of the first connection trench 112 and demarcates a recess space inside the first connection trench 112. The first connection insulating film 113 extends in the first direction X at the first portion 111a of the first connection trench 112. The first connection insulating film 113 extends in the second direction Y at the second portion 111b of the first connection trench 112.

The first connection insulating film 113 is connected to the first upper insulating film 85A and the first lower insulating film 86A at a communicatively connected portion of the first connection trench 112 and the first trench 84A. The first connection insulating film 113 may include a silicon oxide film. It is preferable that the first connection insulating film 113 includes a silicon oxide film constituted of an oxide of the chip 2.

The first connection insulating film 113 has a third thickness T3. The third thickness T3 is a thickness along a normal direction of the wall surface of the first connection trench 112. The third thickness T3 exceeds the first thickness T1 of the first upper insulating film 85A (T1<T3). The third thickness T3 may be substantially equal to the second thickness T2 of the lower insulating film 86 (T2≈T3). The third thickness T3 may be substantially equal to the separation thickness TI of the first separation insulating film 75 (T3≈TI).

The third thickness T3 may be not less than 0.1 μm and not more than 1 μm. The third thickness T3 is preferably not less than 0.15 μm and not more than 0.65 μm. A thickness of a portion which covers the bottom wall of the first connection trench 112 in the first connection insulating film 113 may be less than a thickness of a portion which covers the side wall of the first connection trench 112.

The first connection electrode 114 is embedded in the first connection trench 112 as an integrated member across the first connection insulating film 113. In this embodiment, the first connection electrode 114 may include conductive polysilicon. The first connection electrode 114 extends in the first direction X at the first portion 111a of the first connection trench 112. The first connection electrode 114 extends in the second direction Y at the second portion 111b of the first connection trench 112. The first connection electrode 114 is connected to the first lower electrode 88A at the communicatively connected portion of the first connection trench 112 and the first trench 84A.

The first connection electrode 114 is electrically insulated from the first upper electrode 87A across the first intermediate insulating film 89A. That is, the first connection electrode 114 is constituted of a lead-out portion which is led out to the first connection trench 112 from the first trench 84A across the first connection insulating film 113 and the first intermediate insulating film 89A in the first lower electrode 88A. The first gate signal G1 is transmitted to the first lower electrode 88A via the first connection electrode 114. That is, the same first gate signal G1 is to be applied to the first connection electrode 114 at the same time with the first upper electrode 87A.

The first connection electrode 114 has an electrode surface which is exposed from the first connection trench 112. The electrode surface of the first connection electrode 114 may be recessed in a curved shape toward the bottom wall of the first connection trench 112. The electrode surface of the first connection electrode 114 is preferably located (protrudes) further on the first main surface 3 side than a depth position of the electrode surface of the upper electrode 87 of the trench structure 82 with respect to a depth direction of the first connection trench 112.

The first cap insulating film 115 covers the electrode surface of the first connection electrode 114 as a film inside the first connection trench 112. The first cap insulating film 115 prevents a short circuit of the first connection electrode 114 with another electrode. The first cap insulating film 115 continues to the first connection insulating film 113.

The first cap insulating film 115 may include a silicon oxide film. It is preferable that the first cap insulating film 115 includes a silicon oxide film constituted of an oxide of the first connection electrode 114. That is, it is preferable that the first cap insulating film 115 includes an oxide of polysilicon and the first connection insulating film 113 includes an oxide of silicon monocrystal.

The main transistor 11 includes multiple pairs (in this embodiment, 15 pairs, a total of 30) of second trench connection structures 121 which are formed in the first main surface 3 in the output region 7. The multiple pairs of second trench connection structures 121 each include the second trench connection structure 121 on one side (first side surface 5A side) and the second trench connection structure 121 on the other side (second side surface 5B side) which face each other across one corresponding second composite cell 102 with respect to the second direction Y.

The second trench connection structure 121 on one side connects the first end portions 82a of the plurality (in this embodiment, one pair) of second trench structures 82B each other in an arch shape in a plan view. The second trench connection structure 121 on the other side connects the second end portions 82b of the plurality (in this embodiment, one pair) of second trench structures 82B each other in an arch shape in a plan view. With the plurality (in this embodiment, one pair) of second trench structures 82B which configure one second composite cell 102, the pair of second trench connection structures 121 configure one annular-shaped trench structure.

The second trench connection structure 121 on the other side has the same structure as the second trench connection structure 121 on one side except that it is connected to the second end portion 82b of the second trench structure 82B. Hereinafter, a description of a configuration of one second trench connection structure 121 on one side shall be given, and a description of a configuration of the second trench connection structure 121 on the other side shall be omitted.

The second trench connection structure 121 on one side has a first portion 121a which extends in the first direction X and a plurality (in this embodiment, one pair) of second portions 121b which extend in the second direction Y. The first portion 121a faces the plurality of first end portions 82a in a plan view. The plurality of second portions 121b extend from the first portion 121a to the plurality of first end portions 82a and are connected to the plurality of first end portions 82a. As with each of the first trench connection structures 111, the second trench connection structure 121 on one side has the connection width WC and the connection depth DC.

The second trench connection structure 121 on one side has a single electrode structure including a second connection trench 122, a second connection insulating film 123, a second connection electrode 124 and a second cap insulating film 125. The second connection trench 122 extends in an arch shape so as to be communicatively connected to the first end portions 82a of the pair of second trenches 84B in a plan view and is dug down from the first main surface 3 toward the second main surface 4. The second connection trench 122 demarcates the first portion 121a and the second portion 121b of the second trench connection structure 121. The second connection trench 122 is formed at an interval from the bottom portion of the second semiconductor region 72 to the first main surface 3 side.

The second connection trench 122 includes a side wall and a bottom wall. The second connection trench 122 may be formed in a tapered shape in which an opening width is narrowed from an opening to the bottom wall. A corner portion of the bottom wall of the second connection trench 122 is preferably formed in a curved shape. An entirety of the bottom wall of the second connection trench 122 may be formed in a curved shape toward the second main surface 4. The side wall and the bottom wall of the second connection trench 122 are smoothly connected to the side wall and the bottom wall of the second trench 84B.

The second connection insulating film 123 is formed on a wall surface of the second connection trench 122. Specifically, the second connection insulating film 123 is formed as a film on the second connection trench 122 and demarcates a recess space inside the second connection trench 122. The second connection insulating film 123 extends in the first direction X at the first portion 121a of the second connection trench 122.

The second connection insulating film 123 extends in the second direction Y at the second portion 121b of the second connection trench 122. The second connection insulating film 123 may include a silicon oxide film. It is preferable that the second connection insulating film 123 includes a silicon oxide film constituted of an oxide of the chip 2. As with the first connection insulating film 113, the second connection insulating film 123 has the third thickness T3.

The second connection electrode 124 is embedded as an integrated member in the second connection trench 122 across the second connection insulating film 123. In this embodiment, the second connection electrode 124 may include conductive polysilicon. The second connection electrode 124 extends in the first direction X at the first portion 121a of the second connection trench 122. The second connection electrode 124 extends in the second direction Y at the second portion 121b of the second connection trench 122. The second connection electrode 124 is connected to the second lower electrode 88B at a communicatively connected portion of the second connection trench 122 and the second trench 84B.

The second connection electrode 124 is electrically insulated from the second upper electrode 87B across the second intermediate insulating film 89B. That is, the second connection electrode 124 is constituted of a lead-out portion which is led out to the second connection trench 122 from the second trench 84B across the second connection insulating film 123 and the second intermediate insulating film 89B in the second lower electrode 88B. The second gate signal G2 is transmitted to the second lower electrode 88B via the second connection electrode 124. That is, the same second gate signal G2 is to be applied to the second connection electrode 124 at the same time with the second upper electrode 87B.

The second connection electrode 124 has an electrode surface which is exposed from the second connection trench 122. The electrode surface of the second connection electrode 124 may be recessed in a curved shape toward the bottom wall of the second connection trench 122. The electrode surface of the second connection electrode 124 is preferably located (protrudes) further on the first main surface 3 side than the depth position of the electrode surface of the upper electrode 87 of the trench structure 82 with respect to a depth direction of the second connection trench 122.

The second cap insulating film 125 covers the electrode surface of the second connection electrode 124 as a film inside the second connection trench 122. The second cap insulating film 125 prevents a short circuit of the second connection electrode 124 with another electrode. The second cap insulating film 125 continues to the second connection insulating film 123.

The second cap insulating film 125 may include a silicon oxide film. It is preferable that the second cap insulating film 125 includes a silicon oxide film constituted of an oxide of the second connection electrode 124. That is, it is preferable that the second cap insulating film 125 includes an oxide of polysilicon and the second connection insulating film 123 includes an oxide of silicon monocrystal.

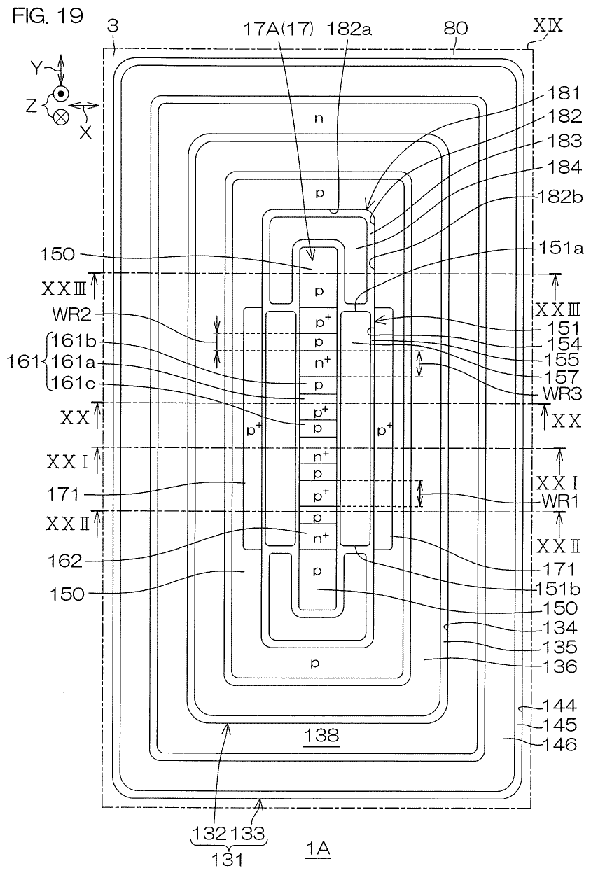

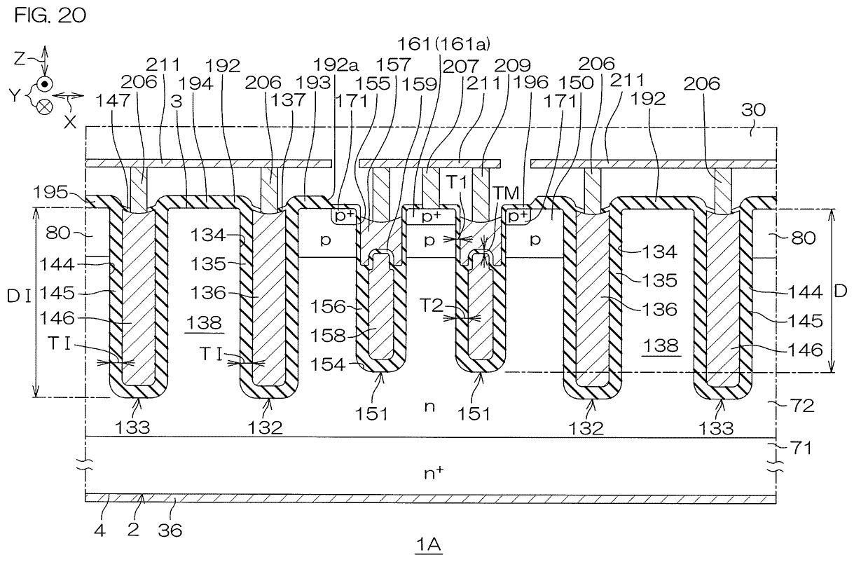

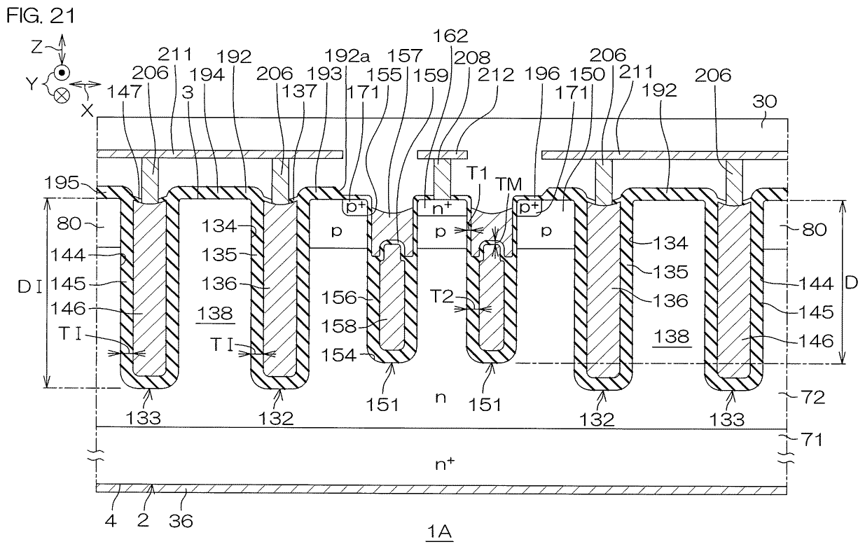

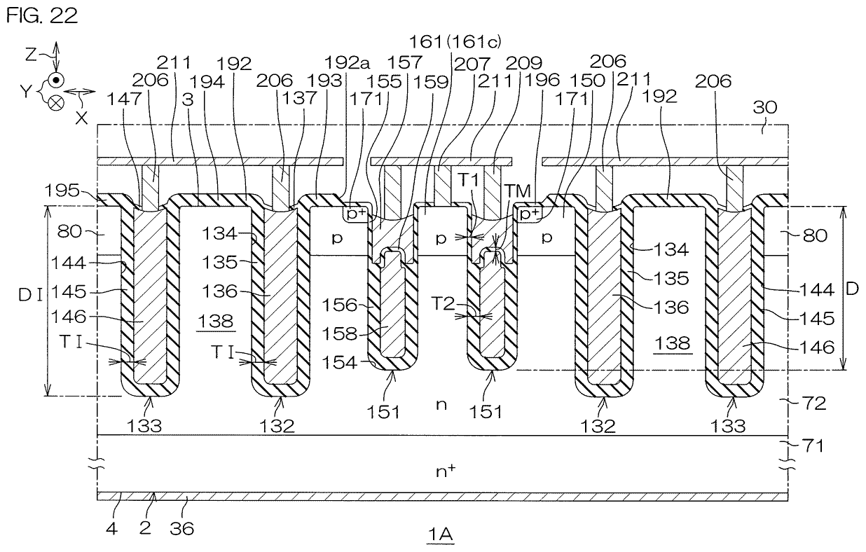

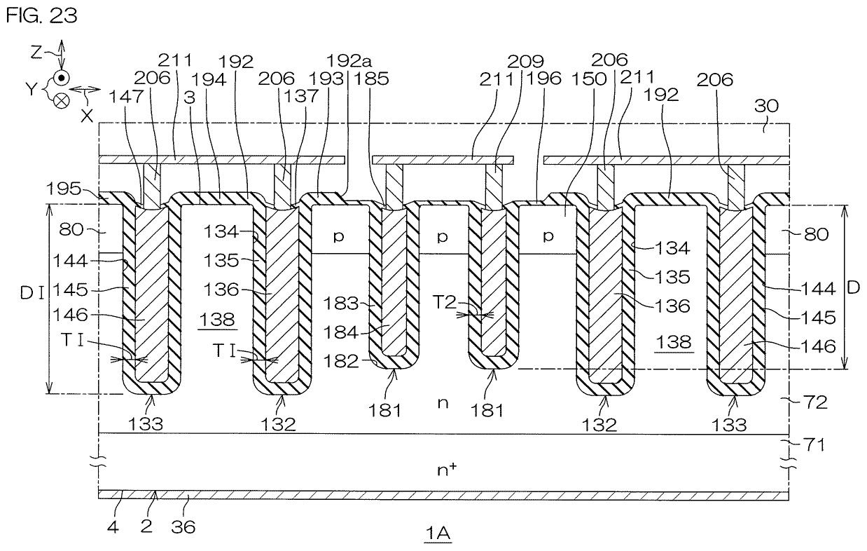

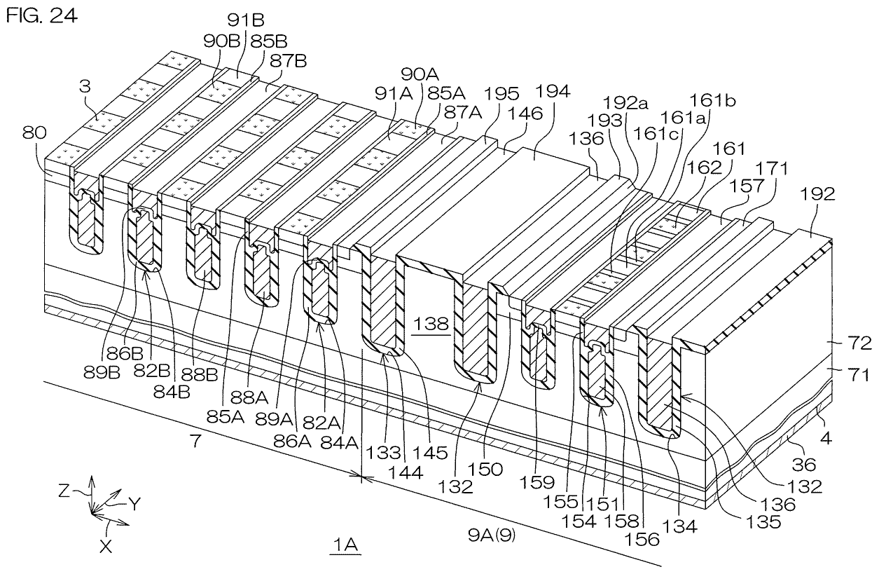

With reference to FIG. 8, the semiconductor device 1A further includes the above-described first temperature detecting region 9A which is demarcated at an inner portion of the output region 7. Hereinafter, a description of a specific structure of the first temperature detecting region 9A shall be given. FIG. 19 is an enlarged view of a region XIX shown in FIG. 8. FIG. 20 is a cross-sectional view taken along line XX-XX shown in FIG. 19. FIG. 21 is a cross-sectional view taken along line XXI-XXI shown in FIG. 19. FIG. 22 is a cross-sectional view taken along line XXII-XXII shown in FIG. 19. FIG. 23 is a cross-sectional view taken along line XXIII-XXIII shown in FIG. 19. FIG. 24 is a cross-sectional perspective view which shows the output region 7 and the first temperature detecting region 9A.

With reference to FIG. 19 to FIG. 24, the semiconductor device 1A includes a diode separation structure 131 as an example of the region separation structure which demarcates the first temperature detecting region 9A in the first main surface 3. The diode separation structure 131 may be referred to as a “DTI structure.” In this embodiment, the diode separation structure 131 has a double trench separation structure which includes a second trench separation structure 132 and a third trench separation structure 133. As a matter of course, the diode separation structure 131 may have a single trench separation structure which is constituted of only the second trench separation structure 132 or may have a multi-trench separation structure which includes three or more trench separation structures.

The second trench separation structure 132 is formed in an annular shape which surrounds a part of the inner portion of the first main surface 3 in the output region 7 in a plan view and demarcates the first temperature detecting region 9A formed in a predetermined shape. In this embodiment, the second trench separation structure 132 is formed in a quadrilateral annular shape having four sides in parallel to the first to fourth side surfaces 5A to 5D in a plan view and demarcates the first temperature detecting region 9A in a quadrilateral shape. The planar shape of the second trench separation structure 132 is arbitrary and the second trench separation structure 132 may be formed in a polygonal annular shape. The first temperature detecting region 9A may be demarcated in a polygonal shape according to the planar shape of the second trench separation structure 132.

As with the first trench separation structure 73, the second trench separation structure 132 has the separation width WI and the separation depth DI (aspect ratio DI/WI). A bottom wall of the second trench separation structure 132 is preferably kept at an interval of not less than 1 μm and not more than 5 μm from the bottom portion of the second semiconductor region 72.

The second trench separation structure 132 has a corner portion which connects a portion extending in the first direction X with a portion extending in the second direction Y in a circular arc shape (curved shape). In this embodiment, four corners of the second trench separation structure 132 are formed in a circular arc shape. That is, the first temperature detecting region 9A is demarcated in a quadrilateral shape having four corners, each of which extends in a circular arc shape. The corner portion of the second trench separation structure 132 preferably has a constant separation width WI along a circular arc direction.

The second trench separation structure 132 has a single electrode structure including a second separation trench 134, a second separation insulating film 135 (second separation insulator), a second separation electrode 136 and a second separation cap insulating film 137. The second separation trench 134 is dug down from the first main surface 3 toward the second main surface 4. The second separation trench 134 is formed at an interval from the bottom portion of the second semiconductor region 72 to the first main surface 3 side. The second separation trench 134 may be formed in a tapered shape in which an opening width is narrowed from an opening to the bottom wall.

The second separation insulating film 135 is formed on a wall surface of the second separation trench 134. Specifically, the second separation insulating film 135 is formed as a film in an entire area of the wall surface of the second separation trench 134 and demarcates a recess space inside the second separation trench 134. The second separation insulating film 135 may include a silicon oxide film. It is preferable that the second separation insulating film 135 includes a silicon oxide film constituted of an oxide of the chip 2. As with the first separation insulating film 75, the second separation insulating film 135 has the separation thickness TI.

The second separation electrode 136 is embedded as an integrated member in the second separation trench 134 across the second separation insulating film 135. In this embodiment, the second separation electrode 136 may include conductive polysilicon. An anode potential is to be applied to the second separation electrode 136. As a matter of course, a source potential may be applied to the second separation electrode 136, as with the first separation electrode 76. The second separation electrode 136 has an electrode surface which is exposed from the second separation trench 134. The electrode surface of the second separation electrode 136 may be recessed toward the bottom wall of the second separation trench 134 in a curved shape.

The second separation cap insulating film 137 covers the electrode surface of the second separation electrode 136 as a film inside the second separation trench 134. The second separation cap insulating film 137 continues to the second separation insulating film 135. The second separation cap insulating film 137 may include a silicon oxide film. It is preferable that the second separation cap insulating film 137 includes a silicon oxide film constituted of an oxide of the second separation electrode 136.

The third trench separation structure 133 is formed in an annular shape which surrounds the second trench separation structure 132 at an interval from the second trench separation structure 132 in a plan view. That is, the third trench separation structure 133 demarcates a mesa portion 138 which extends in an annular shape in a plan view between the third trench separation structure 133 and the second trench separation structure 132. The third trench separation structure 133 is formed in a quadrilateral annular shape which has four sides in parallel to the second trench separation structure 132 in a plan view. The planar shape of the third trench separation structure 133 is arbitrary and the third trench separation structure 133 may be formed in a polygonal annular shape.

The third trench separation structure 133 is formed at an interval of a first separation trench interval IST from the second trench separation structure 132. The first separation trench interval IST preferably exceeds the trench interval IT of the plurality of trench structures 82. The first separation trench interval IST may be not less than 0.5 μm and not more than 4 μm. The third trench separation structure 133 has the separation width WI and the separation depth DI (aspect ratio DI/WI), as with the first trench separation structure 73.

The bottom wall of the third trench separation structure 133 is preferably kept at an interval of not less than 1 μm and not more than 5 μm from the bottom portion of the third region. The third trench separation structure 133 has a corner portion which connects a portion extending in the first direction X with a portion extending in the second direction Y in a circular arc shape (curved shape). In this embodiment, four corners of the third trench separation structure 133 are formed in a circular arc shape. The corner portion of the third trench separation structure 133 preferably has a constant separation width WI along a circular arc direction.

The third trench separation structure 133 has a single electrode structure which includes a third separation trench 144, a third separation insulating film 145 (third separation insulator), a third separation electrode 146 and a third separation cap insulating film 147. The third separation trench 144, the third separation insulating film 145, the third separation electrode 146 and the third separation cap insulating film 147 are formed substantially in the same manner as the second separation trench 134, the second separation insulating film 135, the second separation electrode 136 and the second separation cap insulating film 137. The third separation trench 144, the third separation insulating film 145, the third separation electrode 146 and the third separation cap insulating film 147 shall be specifically described by referring to the description of the second trench separation structure 132, and the description of the third separation trench 144, the third separation insulating film 145, the third separation electrode 146 and the third separation cap insulating film 147 shall be omitted.

The semiconductor device 1A includes a second body region 150 (body region) which is formed in the surface layer portion of the first main surface 3 in the first temperature detecting region 9A. A p-type impurity concentration of the second body region 150 may be not less than 1×10¹⁶ cm⁻³ and not more than 1×10¹⁸ cm⁻³. The p-type impurity concentration of the second body region 150 is preferably substantially equal to the p-type impurity concentration of the first body region 80. The second body region 150 preferably has a thickness (depth) which is substantially equal to that of the first body region 80. According to this structure, the second body region 150 can be formed at the same time with the first body region 80.

The second body region 150 is formed in an entire area of the surface layer portion of the first main surface 3 in the first temperature detecting region 9A. The second body region 150 is not formed in the mesa portion 138. The second body region 150 is in contact with an inner peripheral wall of the second trench separation structure 132 and not in contact with an outer peripheral wall of the second trench separation structure 132 or an inner peripheral wall of the third trench separation structure 133. Further, the first body region 80 is also not formed in the mesa portion 138 in the surface layer portion of the first main surface 3.

The first body region 80 is in contact with an outer peripheral wall of the third trench separation structure 133 and not in contact with the outer peripheral wall of the second trench separation structure 132 or the inner peripheral wall of the third trench separation structure 133. As a matter of course, the second body region 150 (first body region 80) may be formed in the surface layer portion of the first main surface 3 in the mesa portion 138.

The semiconductor device 1A includes a plurality of diode trench structures 151 (trench structures) formed in the first main surface 3 in the first temperature detecting region 9A. The diode trench structure 151 is electrically independent of the trench structure 82 of the main transistor 11. As the number of the plurality of diode trench structures 151, two or more suffices, and the number thereof is adjusted according to the size of the first temperature detecting region 9A. In this embodiment, the semiconductor device 1A includes the two diode trench structures 151.

The plurality of diode trench structures 151 are arrayed at an interval in the first direction X in a plan view and are each formed as a band shape extending in the second direction Y. That is, the plurality of diode trench structures 151 are formed as a stripe pattern extending in the second direction Y in a plan view. The plurality of diode trench structures 151 are each have a first end portion 151a on one side and a second end portion 151b on the other side with respect to the longitudinal direction (second direction Y).

As with the trench structure 82, each diode trench structure 151 has the trench width W and the trench depth D. Also, a bottom wall of each diode trench structure 151 is preferably at an interval of not less than 1 μm and not more than 5 μm from the bottom portion of the second semiconductor region 72. Also, as with the plurality of trench structures 82, the plurality of diode trench structures 151 are arrayed with the trench interval IT kept in the first direction X.

Hereinafter, a description of a configuration of one diode trench structure 151 shall be given. The diode trench structure 151 has a multi-electrode structure including a third trench 154, a third upper insulating film 155, a third lower insulating film 156, a third upper electrode 157, a third lower electrode 158 and a third intermediate insulating film 159. The third trench 154 may be referred to as a “diode trench.”

The diode trench structure 151 includes an embedded electrode which is embedded in the third trench 154 across an embedded insulator. The embedded insulator is constituted of the third upper insulating film 155, the third lower insulating film 156 and the third intermediate insulating film 159. The embedded electrode is constituted of the third upper electrode 157 and the third lower electrode 158.

The third trench 154 is dug down from the first main surface 3 toward the second main surface 4. The third trench 154 penetrates through the second body region 150 and is formed at an interval from the bottom portion of the second semiconductor region 72 to the first main surface 3 side. The third trench 154 may be formed in a tapered shape in which an opening width is narrowed from an opening to the bottom wall. A corner portion of the bottom wall of the third trench 154 is preferably formed in a curved shape. An entirety of the bottom wall of the third trench 154 may be formed in a curved shape toward the second main surface 4.

The third upper insulating film 155 covers an upper wall surface of the third trench 154. Specifically, the third upper insulating film 155 covers the upper wall surface of the third trench 154 located in a region on the opening side thereof with respect to the bottom portion of the second body region 150. The third upper insulating film 155 crosses a boundary between the second semiconductor region 72 and the second body region 150. The third upper insulating film 155 has a portion which covers the second body region 150 and a portion which covers the second semiconductor region 72.

The area covered by the third upper insulating film 155 with respect to the second body region 150 is larger than the area covered by the third upper insulating film 155 with respect to the second semiconductor region 72. The third upper insulating film 155 may include a silicon oxide film. It is preferable that the third upper insulating film 155 includes a silicon oxide film constituted of an oxide of the chip 2. As with the first upper insulating film 85A, the third upper insulating film 155 has the first thickness T1.

The third lower insulating film 156 covers a lower wall surface of the third trench 154. Specifically, the third lower insulating film 156 covers the lower wall surface of the third trench 154 which is located in a region on the bottom wall side thereof with respect to the bottom portion of the second body region 150. The third lower insulating film 156 demarcates a recess space in a region on the bottom wall side of the third trench 154.

The third lower insulating film 156 is in contact with the second semiconductor region 72. The third lower insulating film 156 may include a silicon oxide film. The third lower insulating film 156 preferably includes the silicon oxide film constituted of the oxide of the chip 2. As with the first lower insulating film 86A, the third lower insulating film 156 has the second thickness T2.

The third upper electrode 157 is embedded on the upper side (opening side) inside the third trench 154 across the third upper insulating film 155. The third upper electrode 157 is embedded as a band shape extending in the second direction Y in a plan view. The third upper electrode 157 faces the second body region 150 and the second semiconductor region 72 across the third upper insulating film 155.

A facing area of the third upper electrode 157 facing with respect to the second body region 150 is larger than a facing area of the third upper electrode 157 with respect to the second semiconductor region 72. The third upper electrode 157 may include conductive polysilicon. The third upper electrode 157 is formed as a low potential electrode. Preferably, potential other than the gate potential (gate signal G) is input into the third upper electrode 157. An anode potential may be input into the third upper electrode 157.

The third upper electrode 157 has an electrode surface which is exposed from the third trench 154. The electrode surface of the third upper electrode 157 may be recessed in a curved shape toward the bottom wall of the third trench 154. The electrode surface of the third upper electrode 157 is preferably positioned further on the bottom wall side of the third trench 154 than a depth position of the electrode surface of the second separation electrode 136 (first separation electrode 76) with respect to a depth direction of the third trench 154.

The third lower electrode 158 is embedded on the lower side (bottom wall side) inside the third trench 154 across the third lower insulating film 156. The third lower electrode 158 is embedded as a band shape extending in the second direction Y in a plan view. The third lower electrode 158 may have a thickness (length) exceeding the thickness (length) of the third upper electrode 157 with respect to the depth direction of the third trench 154.

The third lower electrode 158 faces the second semiconductor region 72 across the third lower insulating film 156. The third lower electrode 158 has an upper end portion protruding to the first main surface 3 side from the third lower insulating film 156. The upper end portion of the third lower electrode 158 engages with the bottom portion of the third upper electrode 157 and faces the third upper insulating film 155 across the bottom portion of the third upper electrode 157 in a lateral direction along the first main surface 3.

The third lower electrode 158 may include conductive polysilicon. A potential other than the gate potential (gate signal G) may by preferably applied to the third lower electrode 158. The third lower electrode 158 is preferably fixed to the same potential as the third upper electrode 157. That is, an anode potential may be applied to the third lower electrode 158. Thereby, since it is possible to suppress a voltage drop between the third upper electrode 157 and the third lower electrode 158, it is possible to suppress an electric field concentration between the third upper electrode 157 and the third lower electrode 158.

The third intermediate insulating film 159 is interposed between the third upper electrode 157 and the third lower electrode 158 and electrically insulates the third upper electrode 157 and the third lower electrode 158. Specifically, the third intermediate insulating film 159 covers the third lower electrode 158 which is exposed from the third lower insulating film 156 in a region between the third upper electrode 157 and the third lower electrode 158.

The third intermediate insulating film 159 continues to the third upper insulating film 155 and the third lower insulating film 156. The third intermediate insulating film 159 may include a silicon oxide film. It is preferable that the third intermediate insulating film 159 includes a silicon oxide film constituted of an oxide of the third lower electrode 158. The third intermediate insulating film 159 has the intermediate thickness TM with respect to the normal direction Z as with the first intermediate insulating film 89A.

The semiconductor device 1A includes the first temperature-sensitive diode 17A which is formed in the first temperature detecting region 9A. The first temperature-sensitive diode 17A has a pn-junction portion which is formed in the surface layer portion of the first main surface 3 in a region between the plurality of diode trench structures 151. Specifically, the pn-junction portion is formed in a surface layer portion of the second body region 150. In this embodiment, the pn-junction portion is not formed in a region between the diode separation structure 131 and the diode trench structure 151.

Specifically, the first temperature-sensitive diode 17A includes a p-type anode region 161 (first polarity region) and an n-type cathode region 162 (second polarity region), each of which is formed in the surface layer portion of the second body region 150. The cathode region 162 is formed in the surface layer portion of the second body region 150 so as to form the pn-junction portion with the anode region 161.

More specifically, the first temperature-sensitive diode 17A includes a plurality of the anode regions 161 and a plurality of the cathode regions 162. The plurality of cathode regions 162 are arrayed alternately with the plurality of anode regions 161 along the second direction Y so as to sandwich one anode region 161.

The plurality of anode regions 161 and the plurality of cathode regions 162 are in contact with the plurality of diode trench structures 151. The plurality of anode regions 161 and the plurality of cathode regions 162 face the third upper electrode 157 across the third upper insulating film 155 with respect to the plurality of diode trench structures 151.

An anode potential is to be applied to the plurality of anode regions 161, and a cathode potential is to be applied to the plurality of cathode regions 162. That is, the plurality of anode regions 161 are fixed at the same potential as one of or both of the third upper electrode 157 and the third lower electrode 158 (in this embodiment, both of them).

Each of the anode regions 161 has a concentration gradient in which a p-type impurity concentration is increased or decreased along the second direction Y. Specifically, each of the anode regions 161 includes a high concentration region 161a, a first low concentration region 161b and a second low concentration region 161c which are formed along the second direction Y. The high concentration region 161a is a region which has the p-type impurity concentration higher than that of the second body region 150. Both of the first low concentration region 161b and the second low concentration region 161c are a region which has the p-type impurity concentration lower than that of the high concentration region 161a.

The high concentration region 161a is formed at an interval from the bottom portion of the second body region 150 to the first main surface 3 side and faces the second semiconductor region 72 across a part of the second body region 150. The high concentration region 161a preferably has the p-type impurity concentration substantially equal to that of the contact region 91 of the output region 7.

The high concentration region 161a preferably has a thickness (depth) substantially equal to that of the contact region 91. According to this structure, the high concentration region 161a can be formed at the same time with the contact region 91. The high concentration region 161a has a first region width WR1 with respect to the second direction Y. The first region width WR1 is preferably substantially equal to a length of the contact region 91.

The first low concentration region 161b is positioned on one side in the second direction Y with respect to the high concentration region 161a. The second low concentration region 161c is positioned on the other side in the second direction Y with respect to the high concentration region 161a. In this embodiment, the first low concentration region 161b and the second low concentration region 161c are each formed by utilizing a part of the second body region 150.

Therefore, both of the first low concentration region 161b and the second low concentration region 161c have the p-type impurity concentration of the second body region 150. Both of the first low concentration region 161b and the second low concentration region 161c have a second region width WR2 (WR1≠WR2) which is different from the first region width WR1 with respect to the second direction Y. The second region width WR2 is preferably less than the first region width WR1 (WR1>WR2).

Each of the cathode regions 162 is formed at an interval from the bottom portion of the second body region 150 to the first main surface 3 side and faces the second semiconductor region 72 across a part of the second body region 150. Each of the cathode regions 162 preferably has an n-type impurity concentration substantially equal to that of the source region 90 of the output region 7. Each of the cathode regions 162 preferably has a thickness (depth) substantially equal to that of the source region 90. According to this structure, the cathode region 162 can be formed at the same time with the source region 90.

Each of the cathode regions 162 has a third region width WR3 which is different from the second region width WR2 (WR2≠WR3) with respect to the second direction Y. The second region width WR2 preferably has a length less than a length of the source region 90. The third region width WR3 preferably exceeds the second region width WR2 (WR2<WR3). The third region width WR3 may be not less than the first region width WR1 (WR1≤WR3) or may be less than the first region width WR1 (WR1>WR3).

The semiconductor device 1A includes a p-type diode contact region 171 which is formed in a region between the diode separation structure 131 (second trench separation structure 132) and the diode trench structure 151 at the surface layer portion of the second body region 150. The diode contact region 171 has a p-type impurity concentration higher than that of the second body region 150. The diode contact region 171 preferably has the p-type impurity concentration substantially equal to that of the high concentration region 161a (contact region 91 of output region 7).

The diode contact region 171 is formed at an interval from the second trench separation structure 132 and in contact with the diode trench structure 151. The diode contact region 171 faces the third upper electrode 157 across the third upper insulating film 155. The diode contact region 171 is formed at an interval from the bottom portion of the second body region 150 to the first main surface 3 side and faces the second semiconductor region 72 across a part of the second body region 150. The diode contact region 171 is formed as a band shape extending along a side wall of a corresponding diode trench structure 151 in a plan view.

The semiconductor device 1A includes a pair of diode trench connection structures 181 which are formed in the first main surface 3 in the first temperature detecting region 9A. The pair of diode trench connection structures 181 each include the diode trench connection structure 181 on one side (first side surface 5A side) and the diode trench connection structure 181 on the other side (second side surface 5B side) which face each other across the plurality of diode trench structures 151 with respect to the second direction Y.

The diode trench connection structure 181 on one side connects both of the first end portions 151a of the pair of diode trench structures 151 in an arch shape in a plan view. The diode trench connection structure 181 on the other side connect both of the second end portions 151b of the pair of diode trench structures 151 in an arch shape in a plan view. With the plurality of diode trench structures 151, the pair of diode trench connection structures 181 constitute one annular-shaped trench structure.

The diode trench connection structure 181 on the other side has the same structure as the diode trench connection structure 181 on one side except that it is connected to the second end portion 151b of the diode trench structure 151. Hereinafter, a description shall be given of a configuration of one diode trench connection structure 181 on one side, and a description of a configuration of the diode trench connection structure 181 on the other side shall be omitted.

The diode trench connection structure 181 on one side has a first portion 182a extending in the first direction X and a plurality of second portions 182b extending in the second direction Y. The first portion 182a faces the plurality of first end portions 151a in a plan view. The plurality of second portions 182b extend from the first portion 182a toward the plurality of first end portions 151a and are connected to the plurality of first end portions 151a.

As with the first trench connection structure 111 (second trench connection structure 121), the diode trench connection structure 181 on one side has the connection width WC and the connection depth DC. A bottom wall of the diode trench connection structure 181 is preferably kept at an interval of not less than 1 μm and not more than 5 μm from the bottom portion of the second semiconductor region 72.

The first diode connection structure 181 on one side has a single electrode structure including a third connection trench 182, a third connection insulating film 183, a third connection electrode 184 and a third cap insulating film 185. The third connection trench 182 extends in an arch shape so as to be communicatively connected to the first end portions 151a of the plurality of third trenches 154 in a plan view and is dug down from the first main surface 3 to the second main surface 4. The third connection trench 182 demarcates the first portion 182a and the second portion 182b of the third trench connection structure 181. The third connection trench 182 is formed at an interval from the bottom portion of the second semiconductor region 72 to the first main surface 3 side.

The third connection trench 182 may be formed in a tapered shape in which an opening width is narrowed from an opening to the bottom wall. A corner portion of the bottom wall of the third connection trench 182 is preferably formed in a curved shape. An entirety of the bottom wall of the third connection trench 182 may be formed in a curved shape toward the second main surface 4. The side wall and the bottom wall of the third connection trench 182 are smoothly connected to the side wall and the bottom wall of the third trench 154.

The third connection insulating film 183 is formed on a wall surface of the third connection trench 182. Specifically, the third connection insulating film 183 is formed as a film on the wall surface of the third connection trench 182 and demarcates a recess space inside the third connection trench 182. The third connection insulating film 183 extends in the first direction X at the first portion 182a of the third connection trench 182. The third connection insulating film 183 extends in the second direction Y at the second portion 182b of the third connection trench 182.

The third connection insulating film 183 is connected to the third upper insulating film 155 and the third lower insulating film 156 at a communicatively connected portion of the third connection trench 182 and the third trench 154. The third connection insulating film 183 may include a silicon oxide film. It is preferable that the third connection insulating film 183 includes a silicon oxide film constituted of an oxide of the chip 2. As with the first connection insulating film 113, the third connection insulating film 183 has the third thickness T3.

The third connection electrode 184 is embedded in the third connection trench 182 as an integrated member across the third connection insulating film 183. In this embodiment, the third connection electrode 184 may include conductive polysilicon. The third connection electrode 184 extends in the first direction X at the first portion 182a of the third connection trench 182. The third connection electrode 184 extends in the second direction Y at the second portion 182b of the third connection trench 182. The third connection electrode 184 is connected to the third lower electrode 158 at the communicatively connected portion of the third connection trench 182 and the third trench 154.

The third connection electrode 184 is electrically insulated from the third upper electrode 157 across the third intermediate insulating film 159. That is, the third connection electrode 184 is constituted of a lead-out portion which is led out to the third connection trench 182 from the third trench 154 across the third connection insulating film 183 and the third intermediate insulating film 159 in the third lower electrode 158.

The third connection electrode 184 has an electrode surface which is exposed from the third connection trench 182. The electrode surface of the third connection electrode 184 may be recessed in a curved shape toward the bottom wall of the third connection trench 182. The electrode surface of the third connection electrode 184 is preferably located (protrudes) further on the first main surface 3 side than a depth position of the electrode surface of the third upper electrode 157 with respect to a depth direction of the third connection trench 182.

The third cap insulating film 185 covers the electrode surface of the third connection electrode 184 as a film inside the third connection trench 182. The third cap insulating film 185 prevents a short circuit of the third connection electrode 184 with another electrode. The third cap insulating film 185 continues to the third connection insulating film 183.

The third cap insulating film 185 may include a silicon oxide film. It is preferable that the third cap insulating film 185 includes a silicon oxide film constituted of an oxide of the third connection electrode 184. That is, it is preferable that the third cap insulating film 185 includes an oxide of polysilicon and the third connection insulating film 183 includes an oxide of silicon monocrystal.

As described above, the semiconductor device 1A includes the diode separation structure 131, the plurality of diode trench structures 151, the second body region 150, the second temperature-sensitive diode 17B, the diode contact region 171 and the diode trench connection structure 181 in the first temperature detecting region 9A.

The first temperature-sensitive diode 17A has negative temperature characteristics in which the first forward direction voltage Vf1 linearly decreases with an increase in the first temperature TE1 of the output region 7. Thereby, the first temperature-sensitive diode 17A generates the first temperature detecting signal ST1 which changes in response to the first temperature TE1 of the output region 7 and indirectly monitors the first temperature TE1 of the output region 7.

With again reference to FIG. 1, the semiconductor conductor device 1A further includes the above-described second temperature detecting region 9B which is demarcated at an inner portion of the control region 10. The structure thereof on the second temperature detecting region 9B side is the same as the structure on the first temperature detecting region 9A side. That is, the semiconductor device 1A includes the diode separation structure 131, the plurality of diode trench structures 151, the second body region 150, the second temperature-sensitive diode 17B, the diode contact region 171 and the diode trench connection structure 181 in the second temperature detecting region 9B. The diode separation structure 131 may have a single trench separation structure which is constituted of only the second trench separation structure 132 or may have a multi-trench separation structure which includes the plurality of trench separation structures.

That is, the second temperature-sensitive diode 17B has substantially the same configuration as the first temperature-sensitive diode 17A and has substantially the same electrical characteristics as the first temperature-sensitive diode 17A. The second temperature-sensitive diode 17B has negative temperature characteristics in which the second forward direction voltage Vf2 linearly decreases with an increase in the second temperature TE2 of the control region 10. Thereby, the second temperature-sensitive diode 17B generates the second temperature detecting signal ST2 which changes according to the second temperature TE2 of the control region 10 and indirectly monitors the second temperature TE2 of the control region 10.

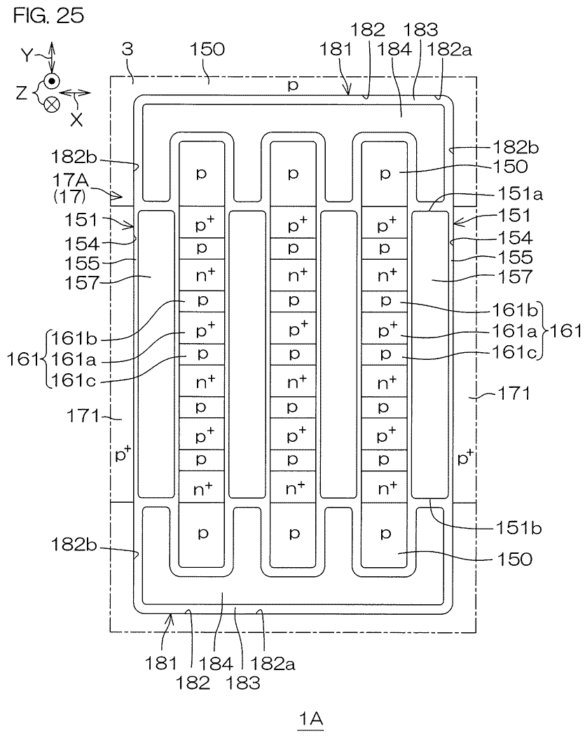

FIG. 25 is an enlarged plan view which partially shows another embodiment example of the first temperature detecting region 9A. In the above-described FIG. 19, a structure example where the first temperature detecting region 9A which includes two diode trench structures 151 was shown. However, as shown in FIG. 25, there may be adopted the first temperature detecting region 9A which includes three or more diode trench structures 151. In FIG. 25, an example where four diode trench structures 151 are formed is shown, however, the number of the diode trench structures 151 is arbitrary and may be five or more.

The first temperature-sensitive diode 17A has a plurality of pn-junction portions, each of which is formed in the surface layer portion of the first main surface 3 in a region between plural pairs of diode trench structures 151 which are in close proximity to each other. That is, the first temperature-sensitive diode 17A includes the plurality of anode regions 161 and the plurality of cathode regions 162, each of which is formed in a region between the plural pairs of diode trench structures 151 which are in close proximity to each other. The layout of the first temperature detecting region 9A (first temperature-sensitive diode 17A) is adjusted by the above-described structure. As a matter of course, the layout of the second temperature detecting region 9B (second temperature-sensitive diode 17B) is also adjusted by the above-described structure.

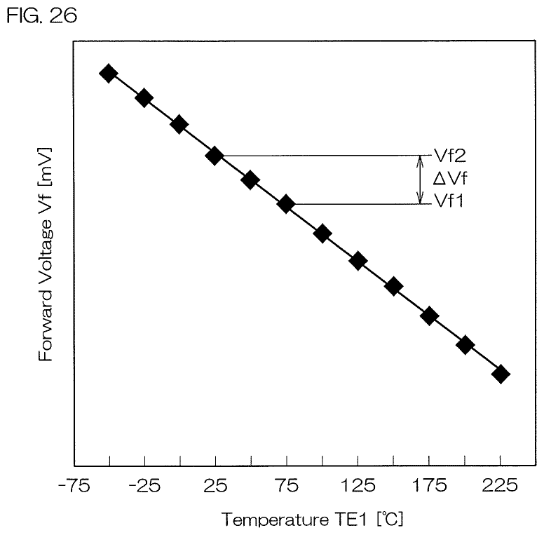

FIG. 26 is a graph which shows the temperature characteristics of the first temperature-sensitive diode 17A shown in FIG. 19. In FIG. 26, the vertical axis indicates the first forward direction voltage Vf1 [mV] of the first temperature-sensitive diode 17A, and the horizontal axis indicates the first temperature TE1 [ ° C.] of the output region 7. In FIG. 26, the temperature characteristics of the first forward direction voltage Vf1 are indicated by a plurality of plotting points.

With reference to FIG. 26, the first temperature-sensitive diode 17A has the negative temperature characteristics in which the first forward direction voltage Vf1 linearly decreases with an increase in the first temperature TE1 of the output region 7. Thereby, the first temperature-sensitive diode 17A generates the first temperature detecting signal ST1 which changes in response to the first temperature TE1 of the output region 7 and indirectly monitors the first temperature TE1 of the output region 7.

When the main transistor 11 generates the output current IO, the second temperature TE2 is less than the first temperature TE1 (T1>T2). Therefore, during generation of the output current IO, the forward direction voltage Vf2 of the second temperature-sensitive diode 17B exceeds the forward direction voltage Vf1 of the first temperature-sensitive diode 17A (Vf1<Vf2).

The difference signal ΔVf which is generated by the difference circuit 26 indicates a difference value (ΔVf=Vf2−Vf1) between the first temperature detecting signal ST1 (first forward direction voltage Vf1) and the second temperature detecting signal ST2 (second forward direction voltage Vf2). In FIG. 26, an example of the difference signal ΔVf in which the first temperature TE1 is 75° C. and the second temperature TE2 is 25° C. is shown. Descriptions besides the structure on the second temperature detecting region 9B side shall be made by referring to a description of the structure on the first temperature detecting region 9A side, and other descriptions of the structure on the second temperature detecting region 9B side shall be omitted.

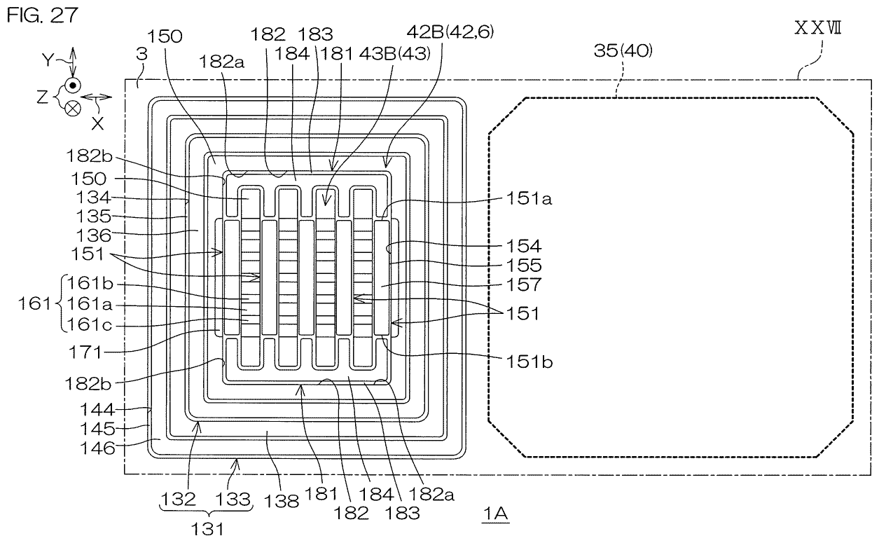

With again reference to FIG. 1, the semiconductor device 1A further includes above-described plurality of protection regions 42 (the plurality of first protection regions 42A and the plurality of second protection regions 42B) which are demarcated in an arbitrary region at the inner portion of the first main surface 3. The arrangement of the plurality of first protection regions 42A is arbitrary. The plurality of second protection regions 42B are each arranged at a position which is in close proximity to the plurality of terminal electrodes 35. Hereinafter, a description of a structure of the protection region 42 shall be given. FIG. 27 is an enlarged view of a region XXVII shown in FIG. 1. FIG. 27 is also an enlarged plan view which shows the structure thereof on the second protection region 42B side.

Each of the structures on the plurality of protection regions 42 side is similar to the structure on the first temperature detecting region 9A side. That is, the semiconductor device 1A includes the diode separation structure 131, the plurality of diode trench structures 151, the second body region 150, the second temperature-sensitive diode 17B, the diode contact region 171 and the diode trench connection structure 181 in each protection region 42. The diode separation structure 131 may have a single trench separation structure which is constituted of only the second trench separation structure 132 or may have a multi-trench separation structure which includes the plurality of trench separation structures.

A planar area of each of the protection regions 42 is preferably less than a planar area of the terminal electrode 35 (terminal electrodes 38 to 41) other than the source terminal 37. The planar area of each of the protection regions 42 preferably exceeds a planar area of each of the temperature detecting regions 9. The number of the plurality of diode trench structures 151 in each of the protection regions 42 preferably exceeds the number of the plurality of diode trench structures 151 in each temperature detecting region 9.

A total planar area of the anode region 161 in each of the protection regions 42 preferably exceeds a total planar area of the anode region 161 in each of the temperature detecting regions 9. A total planar area of the cathode region 162 in each of the protection regions 42 preferably exceeds a total planar area of the cathode region 162 in each of the temperature detecting regions 9.

An increase in the planar area of each of the protection regions 42 makes it possible to improve a current processing capacity during application of the relatively large reverse-bias voltage VR in each of the ESD diodes 43. Descriptions besides the structure of each of the protection regions 42 shall be made by referring to a description of the structure of the first temperature detecting region 9A, and other descriptions of the structure of each of the protection regions 42 shall be omitted.

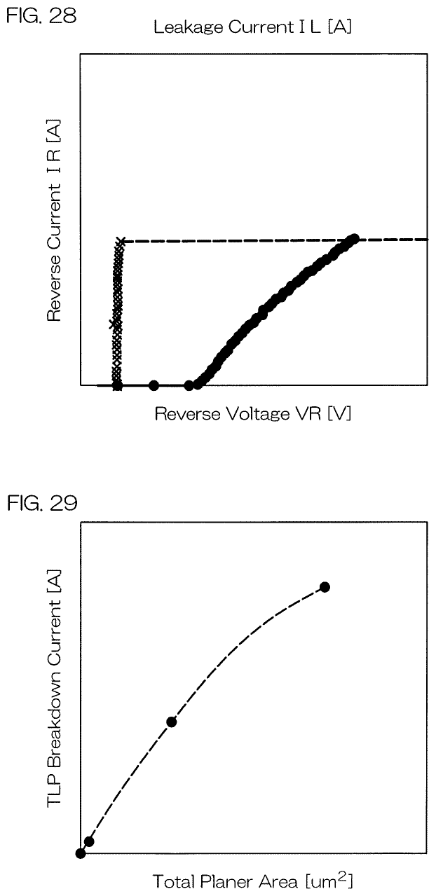

FIG. 28 is a graph which shows breakdown characteristics of the ESD diode 43 shown in FIG. 27. In FIG. 28, the vertical axis indicates a reverse direction current IR [A], the lower horizontal axis indicates a reverse-bias voltage VR [V], and the upper horizontal axis indicates a leakage current IL [A]. In FIG. 28, the breakdown characteristics of the ESD diode 43 are indicated by plotting a plurality of filled circles, and leakage current characteristics of the ESD diode 43 are indicated by plotting a plurality of cross marks. With reference to FIG. 28, it was confirmed that the ESD diode 43 is a diode which has favorable breakdown characteristics and properly operates against static electricity.

FIG. 29 is a graph which shows a relationship between a breakdown current IB of the ESD diode 43 and a planar area of the ESD diode 43 shown in FIG. 27. In FIG. 29, the vertical axis indicates the breakdown current IB [A] of the ESD diode 43, and the horizontal axis indicates the total planar area [μcm²] of the cathode region 162. The breakdown current IB is a reverse direction current IR when the ESD diode 43 results in destruction.

FIG. 29 is a graph which is obtained by a known TLP (Transmission Line Pulse) determination method. In the TLP determination method, such a reverse-bias voltage VR that will result in destruction of the ESD diode 43 is to be applied to the ESD diode 43 in a pulse shape and the breakdown current IB is obtained. The total planar area of the cathode region 162 is adjusted by adjusting a planar area of the protection region 42 or the number, etc., of the plurality of diode trench structures 151.

In the protection region 42, the total planar area of the anode region 161 is also increased according to an increase in the total planar area of the cathode region 162. With reference to FIG. 29, the breakdown current IB of the ESD diode 43 is increased with an increase in the planar area of the protection region 42 (total planar area of cathode region 162).

From evaluation results of FIG. 28 and FIG. 29, it was found that the ESD diode 43 has the same structure as the temperature-sensitive diode 17 and also different in structure from a Zener diode but has the same breakdown characteristics as a Zener diode and functions as an ESD protection device. In other words, it was found that although the temperature-sensitive diode 17 has the same structure as the ESD diode 43, it has forward direction voltage characteristics in which a linear change occurs in response to a change in temperature and functions as a temperature-sensitive device.

As an example, each of the protection regions 42 preferably has a planar area exceeding a planar area of each of the temperature detecting regions 9 in a plan view. That is, the ESD diode 43 preferably has a planar area exceeding a planar area of the temperature-sensitive diode 17. Thereby, although the ESD diode 43 has a basic mode which is common to that of the temperature-sensitive diode 17, it appropriately functions as an ESD protection device.

In this case, a total planar area of the cathode region 162 according to the ESD diode 43 preferably exceeds a total planar area of the cathode region 162 according to the temperature-sensitive diode 17. Further, a total planar area of the anode region 161 according to the ESD diode 43 preferably exceeds a total planar area of the anode region 161 according to the temperature-sensitive diode 17.

With again reference to FIG. 11 to FIG. 14 and also FIG. 21 to FIG. 25, etc., the semiconductor device 1A includes a first field insulating film 191 which partially covers the first main surface 3 in the output region 7. The first field insulating film 191 may include a silicon oxide film. The first field insulating film 191 preferably includes a silicon oxide film which is constituted of an oxide of the chip 2.

The first field insulating film 191 is formed on the first trench separation structure 73 side at an interval from the main transistor 11 in a plan view and covers a periphery of the first trench separation structure 73. The first field insulating film 191 directly covers the first body region 80 at a peripheral edge portion of the output region 7 and exposes the outermost contact region 91.

The first field insulating film 191 is formed as a band shape extending along an inner periphery (inner peripheral wall) of the first trench separation structure 73 in a plan view. In this embodiment, the first field insulating film 191 is formed in an annular shape extending along an inner peripheral wall of the first trench separation structure 73 in a plan view and surrounds an entire periphery of the inner portion of the output region 7.

The first field insulating film 191 has a side extending in one direction (first direction X) and a side extending in an intersecting direction (second direction Y) which intersects the one direction in a plan view. The first field insulating film 191 continues to the first separation insulating film 75 on the inner periphery (inner peripheral wall) side of the first trench separation structure 73. The output region 7 is demarcated by the first trench separation structure 73 inside the chip 2 and demarcated by the first field insulating film 191 on the chip 2.

The first field insulating film 191 has a first insulating side wall 191a which demarcates the output region 7 on the chip 2. The first insulating side wall 191a is formed along an entire periphery of the first field insulating film 191. The first insulating side wall 191a has a side extending in one direction (first direction X) and a side extending in an intersecting direction (second direction Y) which intersects the one direction. The first insulating side wall 191a is positioned on the first body region 80). The first insulating side wall 191a is inclined obliquely downward so as to form an acute angle with the first main surface 3.

Specifically, the first insulating side wall 191a has an upper end portion which is positioned on the main surface side of the first field insulating film 191 and a lower end portion which is positioned on the first main surface 3 side and is inclined obliquely downward from the upper end portion toward the lower end portion. The first insulating side wall 191a forms an inclination angle which is not less than 20° and not more than 40° (20°≤θ≤40°) between the first insulating side wall 191a and the first main surface 3. Where there is drawn a straight line that connects the upper end portion and the lower end portion of the first insulating side wall 191a in a cross-sectional view, the inclination angle is an angle (absolute angle) formed between the straight line and the first main surface 3 inside the first field insulating film 191. The inclination angle is preferably less than 40° (θ<40°).

It is in particular preferable that the inclination angle falls within a range of 30°±6° (24°≤θ≤36°). The inclination angle typically falls within a range of not less than 28° and not more than 36° (28°≤θ≤36°). The first insulating side wall 191a may be inclined in a curved shape which is recessed toward the first main surface 3 in a region between the upper end portion and the lower end portion. In this case as well, where there is drawn a straight line which connects the upper end portion and the lower end portion of the first insulating side wall 191a in a cross-sectional view, the inclination angle is an angle (absolute angle) formed between the straight line and the first main surface 3.

According to the first insulating side wall 191a having a relatively gentle inclination angle, it is possible to prevent electrode residue which is produced upon formation of the trench structure 82, etc., from remaining in a state that it adheres on the first insulating side wall 191a. Thereby, it is possible to decrease a risk of short circuit between the plurality of unit transistors 13 due to the electrode residue. In reducing a risk of short circuit of the first upper electrode 87A and the second upper electrode 87B, it is effective to dig down the electrode surface of the first upper electrode 87A and the electrode surface of the second upper electrode 87B deeper than the electrode surface of the first separation electrode 76, etc.

The first field insulating film 191 has a thickness exceeding the first thickness T1 of the upper insulating film 85. The thickness of the first field insulating film 191 is a thickness along the normal direction Z of a portion other than the insulating side wall 191a. The thickness of the first field insulating film 191 preferably exceeds the intermediate thickness TM of the intermediate insulating film 89.

The thickness of the first field insulating film 191 may be substantially equal to the second thickness T2 of the lower insulating film 86. The thickness of the first field insulating film 191 may be substantially equal to the separation thickness TI of the separation insulating film 75. The thickness of the first field insulating film 191 may be not less than 0.1 μm and not more than 1 μm. The thickness of the first field insulating film 191 is preferably not less than 0.15 μm and not more than 0.65 μm.

With again reference to FIG. 21 to FIG. 25, etc., the semiconductor device 1A includes a second field insulating film 192 which partially covers the first main surface 3 in the temperature detecting region 9. The second field insulating film 192 may include a silicon oxide film. The second field insulating film 192 preferably includes a silicon oxide film which is constituted of an oxide of the chip 2. The second field insulating film 192 is formed on the diode separation structure 131 side at an interval from the main transistor 11 and the temperature-sensitive diode 17 in a plan view and covers a periphery of the diode separation structure 131.

Specifically, the second field insulating film 192 includes a first covering portion 193, a second covering portion 194 and a third covering portion 195. The first covering portion 193 is formed along an inner edge (inner peripheral wall) of the second trench separation structure 132 at a peripheral edge portion of the temperature detecting region 9. The second covering portion 194 covers the mesa portion 138 between the second trench separation structure 132 and the third trench separation structure 133 on the first main surface 3. The third covering portion 195 is formed along an outer edge (outer peripheral wall) of the third trench separation structure 133 at the inner portion of the output region 7.

The first covering portion 193 directly covers the second body region 150 at a peripheral edge portion of the temperature detecting region 9 and exposes the diode contact region 171. The first covering portion 193 is formed as a band shape extending along the inner edge (inner peripheral wall) of the second trench separation structure 132 in a plan view.

In this embodiment, the first covering portion 193 is formed in an annular shape extending along the inner edge (inner peripheral wall) of the second trench separation structure 132 in a plan view and surrounds an entire periphery of the inner portion of the temperature detecting region 9. The first covering portion 193 continues to the second separation insulating film 135 on the inner edge (inner peripheral wall) side of the second trench separation structure 132. The first covering portion 193 has a side which extends in one direction (first direction X) and a side which extends in an intersecting direction (second direction Y) which intersects the one direction in a plan view.

The second covering portion 194 directly covers the second semiconductor region 72 at the mesa portion 138. The second field insulating film 192 is formed as a band shape extending along an outer edge (outer peripheral wall) of the second trench separation structure 132 and an inner edge (inner peripheral wall) of the third trench separation structure 133 in a plan view.

In this embodiment, the second covering portion 194 is formed in an annular shape extending along the mesa portion 138 in a plan view and surrounds an entire periphery of the second trench separation structure 132. The second covering portion 194 continues to the second separation insulating film 135 on the outer edge (outer peripheral wall) side of the second trench separation structure 132 and continues to the third separation insulating film 145 on the inner edge (inner peripheral wall) side of the third trench separation structure 133.

The third covering portion 195 directly covers the first body region 80 at the inner portion of the output region 7 and exposes the contact region 91. The third covering portion 195 is formed as a band shape extending along an outer edge (outer peripheral wall) of the third trench separation structure 133 in a plan view.

In this embodiment, the third covering portion 195 is formed in an annular shape extending along the outer edge (outer peripheral wall) of the third trench separation structure 133 in a plan view and surrounds an entire periphery of the third trench separation structure 133. The third covering portion 195 continues to the third separation insulating film 145 on the outer edge (outer peripheral wall) side of the third trench separation structure 133. The third covering portion 195 has a side extending in one direction (first direction X) and a side extending in an intersecting direction (second direction Y) which intersects the one direction in a plan view.

The temperature detecting region 9 is demarcated inside the chip 2 by the diode separation structure 131 and demarcated on the chip 2 by the second field insulating film 192. Further, the output region 7 is demarcated on the chip 2 at the inner portion by the first field insulating film 191 and the second field insulating film 192.

The second field insulating film 192 has a second insulating side wall 192a which demarcates on the chip 2 the temperature detecting region 9 and the output region 7. The second insulating side wall 192a is formed in an entire periphery of the second field insulating film 192. The second insulating side wall 192a has a side extending in one direction (first direction X) and a side extending in an intersecting direction (second direction Y) which intersects the one direction.

The second insulating side wall 192a on the temperature detecting region 9 side is positioned on the second body region 150, and the second insulating side wall 192a on the output region 7 side is positioned on the first body region 80. The second insulating side wall 192a is inclined obliquely downward so as to form an acute angle with the first main surface 3. Specifically, the second insulating side wall 192a has an upper end portion which is positioned on the main surface side of the second field insulating film 192 and a lower end portion which is positioned on the first main surface 3 side and is inclined obliquely downward from the upper end portion toward the lower end portion.

As with the first insulating side wall 191a, the second insulating side wall 192a forms an inclination angle of not less than 20° and not more than 40° (20°≤θ≤40°) between the second insulating side wall 192a and the first main surface 3. It is in particular preferable that the inclination angle falls within a range of 30°±6° (24°≤θ≤36°). Typically, the inclination angle falls within a range of not less than 28° and not more than 36° (28°≤θ≤36°).

The second insulating side wall 192a may be inclined in a curved shape which is recessed to the first main surface 3 in a region between the upper end portion and the lower end portion. In this case as well, where there is drawn a straight line that connects the upper end portion and the lower end portion of the second insulating side wall 192a in a cross-sectional view, the inclination angle is an angle (absolute value) formed between the straight line and the first main surface 3.

According to the second insulating side wall 192a having a relatively gentle inclination angle, it is possible to prevent electrode residue which is produced upon formation of the trench structure 82, the diode trench structure 151, etc., from remaining in a state that it adheres on the second insulating side wall 192a. Thereby, it is possible to decrease a risk of short circuit between the temperature-sensitive diodes 17 and the unit transistors 13 due to the electrode residue. In reducing a risk of short circuit between the first upper electrode 87A, the second upper electrode 87B and the third upper electrode 157 due to the electrode residue, it is effective to dig down the electrode surface of the third upper electrode 157 deeper than the electrode surfaces of the first separation electrode 76, the second separation electrode 136, etc.

The second field insulating film 192 preferably has a thickness which is substantially equal to that of the first field insulating film 191. Although not shown specifically, the second field insulating film 192 may cover a region on the second temperature detecting region 9B side and a region on the protection region 42 side in the same manner as the first temperature detecting region 9A.

The semiconductor device 1A includes a main surface insulating film 196 which selectively covers the first main surface 3 in the output region 7. The main surface insulating film 196 may include a silicon oxide film. It is preferable that the main surface insulating film 196 includes a silicon oxide film constituted of an oxide of the chip 2. The main surface insulating film 196 covers a region of the output region 7 outside the first field insulating film 191 and the second field insulating film 192. The main surface insulating film 196 continues to the upper insulating film 85, the first connection insulating film 113, the second connection insulating film 123, the third upper insulating film 155 and the first field insulating film 191 (first insulating side wall 191a) and the second field insulating film 192 (second insulating side wall 192a).

The main surface insulating film 196 has a thickness which is less than the thickness of the first field insulating film 191 (second field insulating film 192). The thickness of the main surface insulating film 196 is preferably not more than one-fifth the thickness of the first field insulating film 191 (second field insulating film 192). The thickness of the main surface insulating film 196 may be substantially equal to the first thickness T1 of the upper insulating film 85. The thickness of the main surface insulating film 196 may be not less than 0.01 μm and not more than 0.05 μm. The thickness of the main surface insulating film 196 is preferably not less than 0.02 μm and not more than 0.04 μm.

The semiconductor device 1A includes the aforementioned interlayer insulating layer 30 which covers the first main surface 3. The semiconductor device 1A includes a plurality of via electrodes 201 to 209 which are embedded in the interlayer insulating layer 30. The plurality of via electrodes 201 to 209 may be constituted of a plurality of first via electrodes 201, a plurality of second via electrodes 202, a plurality of third via electrodes 203, a plurality of fourth via electrodes 204, a plurality of fifth via electrodes 205, a plurality of sixth via electrode 206, a plurality of seventh via electrodes 207, a plurality of eighth via electrodes 208 and a plurality of ninth via electrodes 209. The plurality of via electrodes 201 to 209 may be constituted of a tungsten via electrode. In some of the attached drawings, the plurality of via electrodes 201 to 209 are indicated, for simplification, by a cross mark or by a line.

The plurality of first via electrodes 201 are each constituted of a source via electrode for the first separation electrode 76. The plurality of first via electrodes 201 are each embedded at a portion which covers the first trench separation structure 73 in the interlayer insulating layer 30. The plurality of first via electrodes 201 are embedded at an interval along the first separation electrode 76 and are each electrically connected to the first separation electrode 76. The arrangement and shape of the plurality of first via electrodes 201 are arbitrary. One or the plurality of first via electrodes 201 extending as a band shape or in an annular shape in a plan view may be formed on the first separation electrode 76.

The plurality of second via electrodes 202 are each constituted of a gate via electrode for the plurality of upper electrodes 87. The plurality of second via electrodes 202 are each embedded at a portion which covers the plurality of trench structures 82 in the interlayer insulating layer 30. In this embodiment, the plurality of second via electrodes 202 are each electrically connected to both end portions of the plurality of upper electrodes 87. The arrangement and shape of the plurality of second via electrodes 202 are arbitrary. One or the plurality of second via electrodes 202 extending as a band shape along the upper electrode 87 in a plan view may be formed on each of the upper electrodes 87.

The plurality of third via electrodes 203 are each constituted of a source via electrode for the plurality of channel cells 83. The plurality of third via electrodes 203 are each embedded at a portion which covers the plurality of channel cells 83 in the interlayer insulating layer 30. The plurality of third via electrodes 203 are each electrically connected to the plurality of source regions 90 and the plurality of contact regions 91 (outermost contact regions 91). The arrangement and shape of the plurality of third via electrodes 203 are arbitrary. One or the plurality of third via electrodes 203 extending as a band shape in a plan view may be formed on each of the channel cell 83.

The plurality of fourth via electrodes 204 are each constituted of a gate via electrode for the plurality of first and second connection electrodes 114 and 124. The plurality of fourth via electrodes 204 are each embedded at a portion which covers the plurality of first and second connection electrodes 114 and 124 in the interlayer insulating layer 30. The plurality of fourth via electrodes 204 are electrically connected to the plurality of first and second connection electrodes 114 and 124, respectively. The arrangement and shape of the plurality of fourth via electrodes 204 are arbitrary. One or the plurality of fourth via electrodes 204 extending along each of the first and second connection electrodes 114 and 124 as a band shape may be formed on each of the first and second connection electrodes 114 and 124.

The plurality of fifth via electrodes 205 are each constituted of a source via electrode for the monitor transistor 14. The fifth via electrode 205 is embedded in a portion which covers the first channel cell 83A to be utilized as the first system monitor transistor 15A among the plurality of first channel cells 83A in the interlayer insulating layer 30.

The number of the first channel cells 83A for the first system monitor transistor 15A is set so as to be less than the number of the first channel cells 83A for the first system transistor 12A. In this embodiment, the first channel cell 83A which is positioned inside one first composite cell 101 is utilized as the first channel cell 83A of the first system monitor transistor 15A.

Further, the fifth via electrode 205 is embedded in a portion which covers the second channel cell 83B to be utilized as the second system monitor transistor 15B, among the second channel cells 83B. The number of the second channel cells 83B for the second system monitor transistor 15B is set to be less than the number of the second channel cells 83B for the second system transistor 12B. The fifth via electrode 205 is electrically connected to the plurality of source regions 90 and the plurality of contact regions 91. The arrangement and shape of the fifth via electrode 205 are arbitrary. The plurality of fifth via electrodes 205 may be arrayed at an interval along the channel cell 83 in a plan view.

The plurality of sixth via electrodes 206 are each constituted of an anode via electrode for the diode separation structure 131 (second trench separation structure 132 and third trench separation structure 133). The plurality of sixth via electrodes 206 are each embedded in a portion which covers the diode separation structure 131 in the interlayer insulating layer 30. The plurality of sixth via electrodes 206 are embedded at an interval along the diode separation structure 131 and each electrically connected to the second separation electrode 136 and the third separation electrode 146.

The arrangement and shape of the plurality of sixth via electrodes 206 are arbitrary. One or the plurality of sixth via electrodes 206 extending as a band shape or in an annular shape in a plan view may be formed on the second separation electrode 136. Further, one or the plurality of sixth via electrodes 206 extending in a circular shape, a polygonal shape, a band shape or an annular shape in a plan view may be formed on the third separation electrode 146.

The plurality of seventh via electrodes 207 are each constituted of an anode via electrode for the plurality of anode regions 161. The plurality of seventh via electrodes 207 are each embedded in a portion which covers the plurality of anode regions 161 in the interlayer insulating layer 30. The plurality of seventh via electrodes 207 are embedded at an interval along the plurality of anode regions 161 and each electrically connected to the plurality of anode regions 161. The arrangement and shape of the plurality of seventh via electrodes 207 are arbitrary. They may be formed in a band shape, a circular shape or a polygonal shape in a plan view.

The plurality of eighth via electrodes 208 are each constituted of a cathode via electrode for the plurality of cathode regions 162. The plurality of eighth via electrodes 208 are each embedded in a portion which covers the plurality of cathode regions 162 in the interlayer insulating layer 30. The plurality of eighth via electrodes 208 are embedded at an interval along the plurality of cathode regions 162 and each electrically connected to the plurality of cathode regions 162. The arrangement and shape of the plurality of eighth via electrodes 208 are arbitrary. They may be formed in a band shape, a circular shape or a polygonal shape in a plan view.

The plurality of ninth via electrodes 209 are each constituted of an anode via electrode for the diode trench structure 151 and the diode trench connection structure 181. The plurality of ninth via electrodes 209 are each embedded in a portion which covers the diode trench structure 151 and the diode trench connection structure 181 in the interlayer insulating layer 30. The plurality of ninth via electrodes 209 are each electrically connected to the plurality of third upper electrodes 157 and the plurality of third connection electrodes 184. The arrangement and shape of the plurality of ninth via electrodes 209 are arbitrary. They may be formed in a band shape, a circular shape or a polygonal shape in a plan view.

The semiconductor device 1A includes aforementioned one or the plurality of main source wirings 33 which are arranged inside the interlayer insulating layer 30. One or the plurality of main source wirings 33 are selectively routed inside the interlayer insulating layer 30, electrically connected to the first separation electrode 76 via the plurality of first via electrodes 201 and electrically connected to the source region 90 and the plurality of contact region 91 via the plurality of third via electrodes 203.

Also, one or the plurality of main source wirings 33 are electrically connected to the second separation electrode 136 and the third separation electrode 146 of the diode separation structure 131 via the plurality of sixth via electrodes 206. One or the plurality of main source wirings 33 are electrically connected to the aforementioned source terminal 37.

The semiconductor device 1A includes the aforementioned one or the plurality of monitor source wirings 34 which are arranged inside the interlayer insulating layer 30. One or the plurality of monitor source wirings 34 are constituted of a wiring layer which is formed inside the interlayer insulating layer 30. One or the plurality of monitor source wirings 34 are selectively routed inside the interlayer insulating layer 30, electrically connected to the first channel cell 83A of the first system monitor transistor 15A via the fifth via electrode 205 and electrically connected to the second channel cell 83B of the second system monitor transistor 15B via the fifth via electrode 205. One or the plurality of monitor source wirings 34 are electrically connected to the aforementioned overcurrent protection circuit 21.

The semiconductor device 1A includes the aforementioned n-number of the main gate wirings 31 which are formed inside the interlayer insulating layer 30. The n-number of the main gate wirings 31 are selectively routed inside the interlayer insulating layer 30. The n-number of the main gate wirings 31 are each electrically connected to one or the plurality of trench structures 82 (unit transistor 13) which are to be systematized as an individually controlled object in the output region 7 and electrically connected to the aforementioned control circuit 18 (gate drive circuit 19) in the control region 10.

In this embodiment, the n-number of the main gate wirings 31 include the first main gate wiring 31A and the second main gate wiring 31B. The first main gate wiring 31A is electrically connected to the first upper electrode 87A, the first lower electrode 88A and the first connection electrode 114 via the corresponding second via electrode 202 and the corresponding fourth via electrode 204 and imparts the first gate signal G1. The second main gate wiring 31B is electrically connected to the second upper electrode 87B, the second lower electrode 88B and the second connection electrode 124 via the corresponding second via electrode 202 and the corresponding fourth via electrode 204 and imparts the second gate signal G2.

The semiconductor device 1A includes the aforementioned n-number of the monitor gate wirings 32 which are formed inside the interlayer insulating layer 30. The n-number of the monitor gate wirings 32 are selectively routed inside the interlayer insulating layer 30. In this embodiment, the n-number of the monitor gate wirings 32 include the first monitor gate wiring 32A and the second monitor gate wiring 32B.

The first monitor gate wiring 32A is electrically connected to the first upper electrode 87A, the first lower electrode 88A and the first connection electrode 114 via the corresponding second via electrode 202 and the corresponding fifth via electrode 205. In this embodiment, the first monitor gate wiring 32A is integrally formed with the first main gate wiring 31A. The second monitor gate wiring 32B is electrically connected to the second upper electrode 87B and the second lower electrode 88B via the corresponding second via electrode 202 and the corresponding fifth via electrode 205. In this embodiment, the second monitor gate wiring 32B is integrally formed with the second main gate wiring 31B.

The semiconductor device 1A includes a plurality of anode wirings 211 described above which is formed inside the interlayer insulating layer 30. The plurality of anode wirings 211 are constituted of the plurality of wiring layers selectively routed inside the interlayer insulating layer 30. The plurality of anode wirings 211 are electrically connected to the plurality of second separation electrodes 136, the third separation electrode 146 and the plurality of anode region 161 via the plurality of via sixth electrode 206, the plurality of seventh via electrodes 207 and the plurality of ninth via electrodes 209.

The anode wiring 211 according to the plurality of temperature detecting regions 9 is electrically connected to an arbitrary application end of high potential (for example, the power potential VB). The anode wiring 211 according to the plurality of protection regions 42 is electrically connected to an application end of the source potential or an application end of the ground potential according to ESD protection objects. As a matter of course, where the source potential is to be applied to the anode region 161, the anode wiring 211 may be connected to the main source wiring 33 in an outer periphery.

The semiconductor device 1A includes a plurality of cathode wirings 212 described above which are formed inside the interlayer insulating layer 30. The plurality of cathode wirings 212 are constituted of a plurality of wiring layers which are selectively routed inside the interlayer insulating layer 30. The plurality of cathode wirings 212 are electrically connected to the plurality of cathode regions 162 via the plurality of eighth via electrodes 208. The cathode wiring 212 according to the plurality of temperature detecting regions 9 is electrically connected to an arbitrary application end of low potential (for example, a potential which is lower by about 5 V than the power potential VB). The cathode wiring 212 according to the plurality of protection regions 42 is electrically connected to the active clamp circuit 20 or an arbitrary terminal electrode 35.

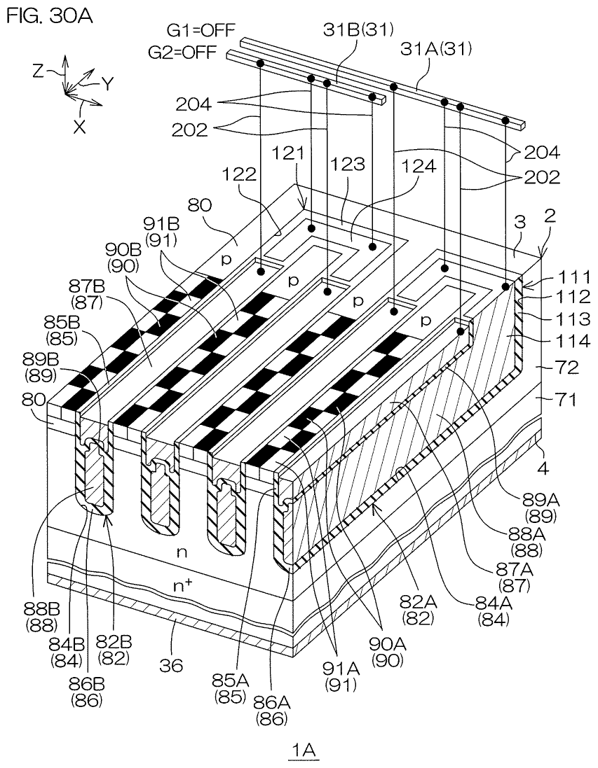

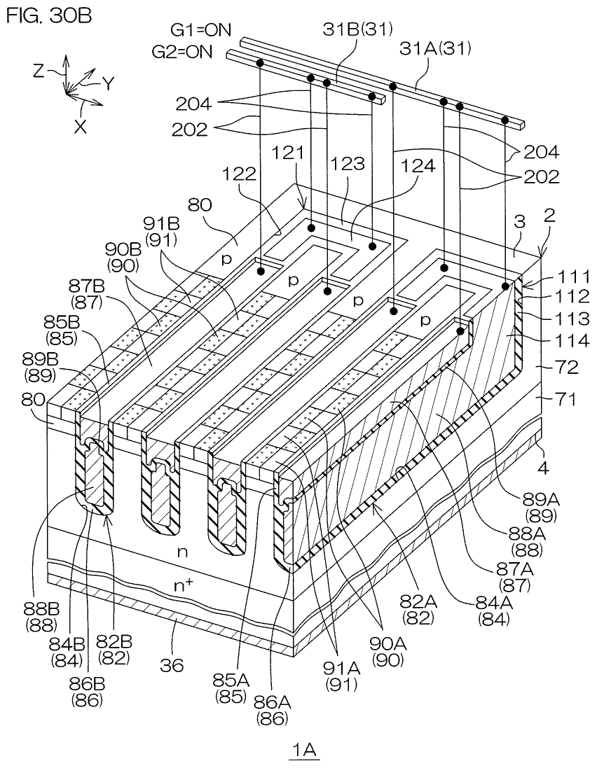

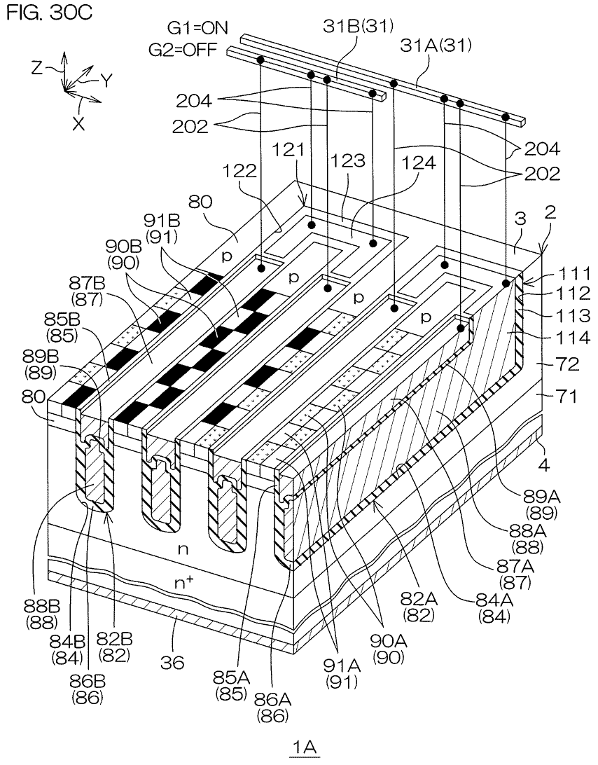

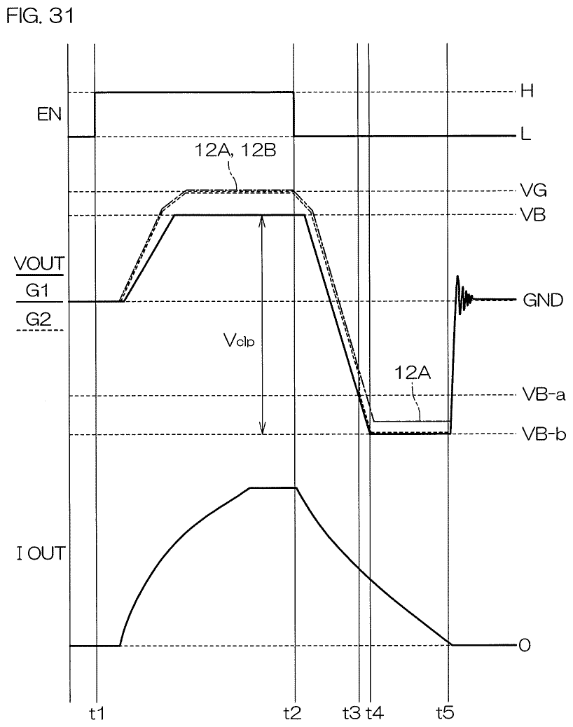

Hereinafter, with reference to FIG. 30A to FIG. 30C and FIG. 31, a description of a control example of the 2-system main transistor 11 shall be given. FIG. 30A to FIG. 30C are each a cross-sectional perspective view which shows an operation example of the main transistor 11. FIG. 31 is a timing char which shows a control example of the main transistor 11. In FIG. 30A to FIG. 30C, there is shown a configuration example where the total channel ratio RT is 50%, the first system channel ratio RSA is 25% and the second system channel ratio RSB is 25%. In FIG. 30A to FIG. 30C, a channel (source region 90) in an off state is indicated by a filled-in hatching.

There are sequentially shown, from the upper side of the sheet surface of FIG. 31, the enable signal EN, the output voltage VO (solid line), the first gate signal G1 (alternate long and short dashed line), the second gate signal G2 (broken line) and the output current IO. Hereinafter, a gate-source voltage of the first system transistor 12A is given as “Vgs1,” a gate-source voltage of the clamp MISFET 59 is given as “Vgs2,” a gate-source voltage of the drive MISFET 56 is given as “Vgs3,” a breakdown voltage of the Zener diode array 57 is given as “VZ” and a forward direction drop voltage of the diode array 58 is given as “VF.”

With reference to FIG. 31, the enable signal EN is kept at a low level up to a time t1. In the enable signal EN, the low level is a logical level when the main transistor 11 is turned off, and the high level is a logical level when the main transistor 11 is turned on.

At this time, since the first and second gate signals G1 and G2 are kept at the low level (≈VOUT), and the first and second system transistors 12A and 12B are controlled so as to be in an off state (see FIG. 27A). This state corresponds to a first operation mode of the main transistor 11. On the other hand, since the first and second gate signals G1 and G2 are kept in the low level, the first and second system monitor transistors 15A and 15B are controlled so as to be in an off state together with the first and second system transistors 12A and 12B.

At the time t1, the enable signal EN is controlled from a low level to a high level. When the enable signal EN is turned into the high level, the first and second gate signals G1 and G2 are raised from the low level (≈VOUT) to the high level (≈VG) and the first and second system transistors 12A and 12B are both controlled so as to be in an on state at the same time (see FIG. 30B).

Thereby, the main transistor 11 is turned into a normal operation (first operation) state. This state corresponds to a second operation mode of the main transistor 11. When the first and second system transistors 12A and 12B are turned into an on state, the output current IO starts to flow. The output voltage VO rises to the vicinity of the power voltage VB. When in the normal operation, the main transistor 11 is driven at the total channel ratio RT (=50%).

On the other hand, when the first and second gate signals G1 and G2 are raised from a low level to a high level, the first and second system monitor transistors 15A and 15B are both controlled so as to be in an on state in conjunction with the first and second system transistors 12A and 12B. Thereby, the monitor transistor 14 is turned into a normal operation state. When the first and second system monitor transistors 15A and 15B are turned into an on state, the output monitor current IOM which monitors the output current IO is generated and output to the overcurrent protection circuit 21.

At a time t2, the enable signal EN is controlled from a high level to a low level. When the enable signal EN is turned into the low level, the first and second gate signals G1 and G2 are raised from the high level to the low level. At this time, the main transistor 11 continues to flow the output current IO until all of the energy which was accumulated in the inductive load L during an on state is released. As a result, the output voltage VO abruptly drops down to a negative voltage lower than the ground voltage GND.

Thereby, the main transistor 11 is shifted to an active clamp operation (second operation). Also, when the first and second gate signals G1 and G2 are lowered from a high level to a low level, the monitor transistor 14 is shifted to the active clamp operation in conjunction with the main transistor 11.

At a time t3, when the output voltage VO falls down to a channel switching voltage VB-a that is lower than the power voltage VB by a predetermined value a (=VZ+VF+Vgs3), the internal node voltage Vx becomes higher than the gate-source voltage Vgs3. Thereby, the drive MISFET 56 is turned into an on state, and a short circuit a gate-to-source portion of the second system transistor 12B is short-circuited (G2=VOUT). As a result, the second system transistor 12B is controlled so as to be in an off state. At this time, the second system monitor transistor 15B is controlled so as to be in an off state in conjunction with the second system transistor 12B.

On the other hand, at a time t4, when the output voltage VO drops down to a lower limit voltage VB-b which is lower than the power voltage VB by a predetermined value b (=VZ+VF+Vgs1+Vgs2), the first system transistor 12A is controlled so as to be in an on state by the active clamp circuit 20. The lower limit voltage VB-b is less than the channel switching voltage VB-a (VB-b<VB-a). At this time, the first system monitor transistor 15A is controlled so as to be in an on state in conjunction with the first system transistor 12A.

Therefore, the second system transistor 12B is completely stopped by the drive MISFET 56 before the active clamp circuit 20 is operated. Thereby, during the active clamp operation, the main transistor 11 is driven by the first system transistor 12A in a state that the second system transistor 12B is stopped (see FIG. 30C). This state corresponds to a third operation mode of the main transistor 11.

During the active clamp operation, the main transistor 11 is driven at the first system channel ratio RSA (=25%). That is, the main transistor 11 is controlled so that a channel utilization rate during the active clamp operation is more than zero and less than a channel utilization rate during a normal operation. In other words, the main transistor 11 is controlled so that an on-resistance during the active clamp operation is higher than an on-resistance during the normal operation.

Similarly, the second system monitor transistor 15B is completely stopped in conjunction with the second system transistor 12B before the active clamp circuit 20 is operated. Thereby, during the active clamp operation, the monitor transistor 14 is driven by the first system monitor transistor 15A in a state that the second system monitor transistor 15B is stopped.

That is, the monitor transistor 14 is controlled so that a channel utilization rate during the active clamp operation is more than zero and less than a channel utilization rate during the normal operation. In other words, the monitor transistor 14 is controlled so that an on-resistance during the active clamp operation is higher than an on-resistance during the normal operation.

The output current IO is discharged via the first system transistor 12A. Thereby, the output voltage VO is limited to a voltage not less than the lower limit voltage VB-b. That is, the active clamp circuit 20 limits the output voltage VO on the basis of the power voltage VB and limits a drain-source voltage Vds (=VB−VOUT) of the main transistor 11 to a voltage not more than the clamp voltage Vclp (=b). The active clamp operation continues up to a time t5 when an energy which was accumulated at the inductive load L is completely released out and the output current IO no longer flows.

As described above, according to this control example, it is possible to provide the semiconductor device 1A having the on-resistance changeable main transistor 11 in which an on-resistance can be changed depending on an operation state. That is, according to the semiconductor device 1A, during the normal operation (during a first operation), a current is allowed to flow by utilizing the first and second system transistors 12A and 12B.

Thereby, an on-resistance can be decreased. On the other hand, during the active clamp operation (during a second operation), in a state that the second system transistor 12B is stopped, a current is allowed to flow by utilizing the first system transistor 12A. Thereby, it is possible to consume (absorb) the back electromotive force by the first system transistor 12A while suppressing an abrupt temperature rise due to a back electromotive force of the inductive load L.

In other words, according to the semiconductor device 1A, the main transistor 11 is relatively increased in channel utilization rate during the normal operation, and the main transistor 11 is relatively decreased in channel utilization rate during the active clamp operation. Thereby, an on-resistance can be decreased. Also, since it is possible to suppress an abrupt temperature rise due to the back electromotive force of the inductive load L during the active clamp operation, it is possible to improve an active clamp tolerance Eac. As described above, according to the semiconductor device 1A, it is possible to realize both an excellent on-resistance and an excellent active clamp tolerance Eac.

In FIG. 30A to FIG. 30C, some of or all (in this embodiment, all) of the output monitor currents IOM generated by the monitor transistor 14 are input into the overcurrent protection circuit 21 (also see FIG. 7). When the output monitor current IOM exceeds a predetermined threshold, the overcurrent protection circuit 21 generates the overcurrent detecting signal SOD and outputs the overcurrent detecting signal SOD to the gate drive circuit 19.

The gate drive circuit 19 limits some of or all of the n-number of the gate signals G in response to the overcurrent detecting signal SOD and limits one or both of the first and second system currents IS1 and IS2 generated by the first and second system transistors 12A and 12B. Thereby, an overcurrent state of the main transistor 11 is eliminated. When the output monitor current IOM is at a value not more than a predetermined threshold, the overcurrent protection circuit 21 stops generation of the overcurrent detecting signal SOD and shifts the gate drive circuit 19 (main transistor 11) to normal control.

In FIG. 30A to FIG. 30C, the first temperature detecting signal ST1 generated by the first temperature-sensitive diode 17A and the second temperature detecting signal ST2 generated by the second temperature-sensitive diode 17B are input into the thermal shutdown circuit 22 (also see FIG. 7). The overcurrent protection circuit 21 generates the difference signal ΔVf on the basis of the first temperature detecting signal ST1 and the second temperature detecting signal ST2. When the difference signal ΔVf exceeds the threshold VT, the overcurrent protection circuit 21 generates the overheat detecting signal SOH and outputs the overheat detecting signal SOH to the gate drive circuit 19.

The gate drive circuit 19 limits a part of or an entirety of the n-number of the gate signals G in response to the overheat detecting signal SOH and limits one of or both of the first and second system currents IS1 and IS2 which are generated in the first and second system transistors 12A and 12B. Thereby, a part of or an entirety of the main transistor 11 is controlled so as to be in an off state, and at the same time, a part of or an entirety of the monitor transistor 14 is controlled so as to be in an off state. Thereby, an overheat state of the output region 7 is eliminated. When the difference signal ΔVf is not more than the threshold VT, the overcurrent protection circuit 21 stops generating the overheat detecting signal SOH and shifts the gate drive circuit 19 to ordinary control.

As described above, according to the embodiment, it is possible to provide the novel semiconductor device 1A having a diode high in versatility. Specifically, the semiconductor device 1A according to a first mode of the embodiment includes the chip 2, the diode region (temperature detecting region 9 and/or protection region 42), the plurality of diode trench structures 151 (trench structures) and the diode (temperature-sensitive diode 17 and/or ESD diode 43). The chip 2 has the first main surface 3. The diode region is arranged in the first main surface 3.

The plurality of diode trench structures 151 are formed in the first main surface 3 at an interval in the diode region. The plurality of diode trench structures 151 each have an electrode structure which includes the third upper electrode 157 (upper electrode) and the third lower electrode 158 (lower electrode) which are embedded in the trench 84 across an insulator in an up/down direction. The diode has a pn-junction portion which is formed in a surface layer portion of the first main surface 3 at a region between the plurality of diode trench structures 151.

This diode can have forward direction voltage characteristics in which a linear change occurs in response to a change in temperature. Further, although this diode is different in structure from a Zener diode, this diode can have the same breakdown voltage characteristics as a Zener diode. Thereby, this diode can be utilized as the temperature-sensitive diode 17 or the ESD diode 43. Thus, it is possible to provide the novel semiconductor device 1A having a diode high in versatility.

The semiconductor device 1A according to a second mode of the embodiment includes the chip 2, the circuit region 6, the protection region 42, an electric circuit, the plurality of diode trench structures 151 (trench structures) and the ESD diode 43 (electrostatic breakdown protection diode). The chip 2 has the first main surface 3. The circuit region 6 is arranged in the first main surface 3. The protection region 42 is arranged in the first main surface 3. The electric circuit is formed in the circuit region 6. The plurality of diode trench structures 151 are formed in the first main surface 3 at an interval in the protection region 42.

The plurality of diode trench structures 151 each have an electrode structure which includes the third upper electrode 157 (upper electrode) and the third lower electrode 158 (lower electrode) which are embedded in the trench 84 across an insulator in an up/down direction. The ESD diode 43 has a pn-junction portion which is formed in a surface layer portion of the first main surface 3 at a region between the plurality of diode trench structures 151. The ESD diode 43 is electrically connected to an electric circuit so as to protect the electric circuit from static electricity. According to this structure, the diode which is formed in the protection region 42 is utilized as the ESD diode 43.

The semiconductor device 1A according to a third mode of the embodiment includes the chip 2, the plurality of temperature detecting regions 9, the plurality of diode trench structures 151 (trench structures) and the plurality of temperature-sensitive diodes 17. The chip 2 has the first main surface 3. The plurality of temperature detecting regions 9 are arranged in the first main surface 3 at an interval. The plurality of diode trench structures 151 are formed in the first main surface 3 at an interval in each of the temperature detecting regions 9.

The plurality of diode trench structures 151 each have an electrode structure that includes the third upper electrode 157 (upper electrode) and the third lower electrode 158 (lower electrode) which are embedded in the trench 84 across an insulator in an up/down direction. Each of the temperature-sensitive diodes 17 has a pn-junction portion which is formed in a surface layer portion of the first main surface 3 at a region between the plurality of diode trench structures 151 in each of the temperature detecting regions 9. Each of the temperature-sensitive diodes 17 detects a temperature of each of the temperature detecting regions 9. According to this structure, the plurality of diodes which are formed in the plurality of temperature detecting regions 9 are utilized as the plurality of temperature-sensitive diodes 17.

The semiconductor device 1A according to a fourth mode of the embodiment includes the chip 2, the temperature detecting region 9, the control region 10, the plurality of diode trench structures 151 (trench structures), the temperature-sensitive diode 17 and the control circuit 18. The chip 2 has the first main surface 3. The temperature detecting region 9 is arranged in the first main surface 3. The control region 10 is arranged in the first main surface 3. The plurality of diode trench structures 151 are formed in the first main surface 3 at an interval in the temperature detecting region 9.

The plurality of diode trench structures 151 each have an electrode structure which includes the third upper electrode 157 (upper electrode) and the third lower electrode 158 (lower electrode) embedded in the trench 84 across an insulator in an up/down direction. The temperature-sensitive diode 17 has a pn-junction portion which is formed in a surface layer portion of the first main surface 3 at a region between the plurality of diode trench structures 151 and generates a temperature detecting signal which detects a temperature of the temperature detecting region 9. The control circuit 18 is formed in the control region 10 and configured so as to generate an electric signal on the basis of a temperature detecting signal from the temperature-sensitive diode 17. According to this structure, the diode which is formed in the temperature detecting region 9 is utilized as the temperature-sensitive diode 17.

The semiconductor device 1A according to a fifth mode of the embodiment includes the chip 2, the temperature detecting region 9, the protection region 42, the plurality of diode trench structures 151 (first trench structure) on the temperature detecting region 9 side, the plurality of diode trench structures 151 (second trench structure) on the protection region 42 side, the temperature-sensitive diode 17 and the ESD diode 43 (electrostatic breakdown protection diode). The chip 2 has the first main surface 3. The temperature detecting region 9 is arranged in the first main surface 3. The protection region 42 is arranged in a region different from the temperature detecting region 9 in the first main surface 3.

The plurality of diode trench structures 151 on the temperature detecting region 9 side are formed in the first main surface 3 at an interval in the temperature detecting region 9. The plurality of diode trench structures 151 on the temperature detecting region 9 side each have an electrode structure that includes the third upper electrode 157 (upper electrode) and the third lower electrode 158 (lower electrode) which are embedded in the trench 84 across an insulator in an up/down direction.

The plurality of diode trench structures 151 on the protection region 42 side are formed in the first main surface 3 at an interval in the protection region 42. The plurality of diode trench structures 151 on the protection region 42 side each have an electrode structure that includes the third upper electrode 157 (upper electrode) and the third lower electrode 158 (lower electrode) which are embedded in the trench 84 across an insulator in an up/down direction.

The temperature-sensitive diode 17 has a pn-junction portion (first pn-junction portion) which is formed in a surface layer portion of the first main surface 3 at a region between the plurality of diode trench structures 151 on the temperature detecting region 9 side. The ESD diode 43 has a pn-junction portion (second pn-junction portion) which is formed in the surface layer portion of the first main surface 3 at a region between the plurality of diode trench structures 151 on the protection region 42 side. According to this structure, the diode which is formed in the temperature detecting region 9 is utilized as the temperature-sensitive diode 17, and the diode formed in the protection region 42 is utilized as the ESD diode 43.

The semiconductor device 1A according to a sixth mode of the embodiment further includes the output region 7 (device region) and the main transistor 11 (functional device) which is formed in the output region 7 in any one of the first to fifth modes. In this case, a diode region (temperature detecting region 9 and/or protection region 42) may be arranged so as to be adjacent to the output region 7.

Where the diode region is constituted of the temperature detecting region 9, the temperature-sensitive diode 17 is formed in the temperature detecting region 9. The temperature-sensitive diode 17 is preferably configured so as to detect a temperature of the output region 7. Where the diode region is constituted of the protection region 42, a protection diode is formed in the protection region 42. The protection diode is preferably configured so as to protect the main transistor 11 from static electricity.

In these cases, the main transistor 11 preferably includes the trench structure 82 (trench gate structure). The trench structure 82 preferably has an electrode structure which includes the upper electrode 87 (upper gate electrode) and the lower electrode 88 (lower gate electrode) which are embedded in the trench 84 (gate trench) across a gate insulator (upper insulating film 85 and lower insulating film 86) in an up/down direction. In this case, a part of or an entirety of the manufacturing processes of the diode can be incorporated into manufacturing processes of the main transistor 11.

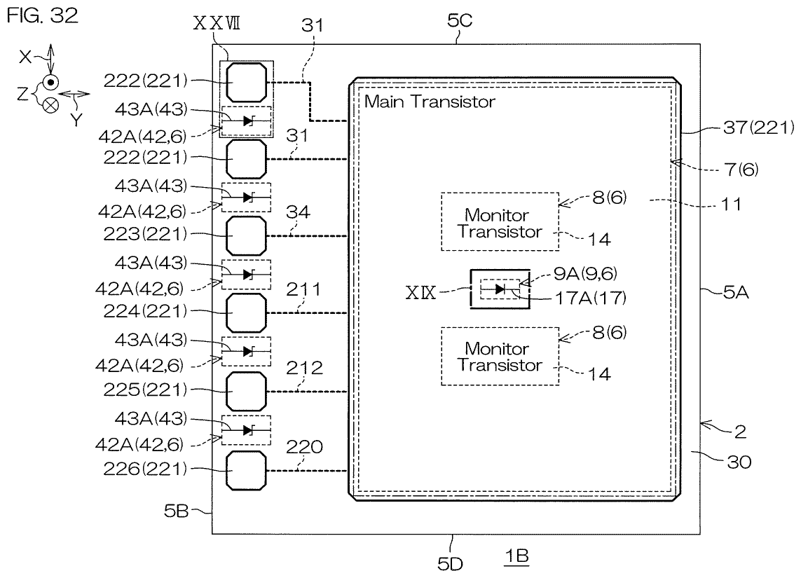

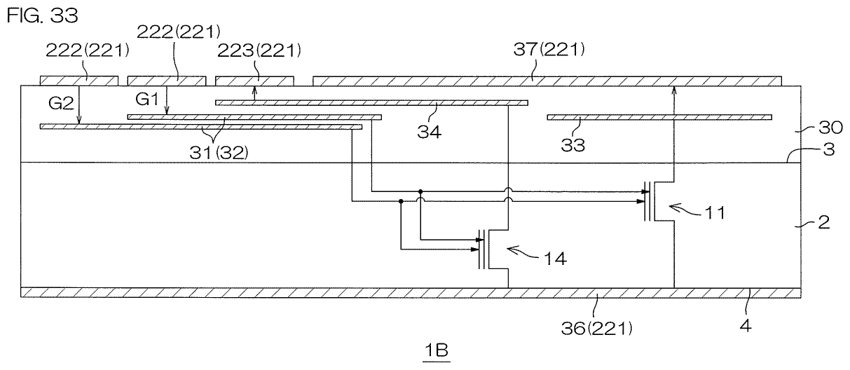

FIG. 32 is a schematic plan view which shows a semiconductor device 1B according to a second embodiment. FIG. 33 is a schematic cross-sectional view of the semiconductor device 1B shown in FIG. 32. In FIG. 32 and FIG. 33, there is shown a mode in which a two-system main transistor 11 is adopted as an example of an n-system main transistor 11, however, the mode is not limited thereto.

In the semiconductor device 1A according to the above-described first embodiment, the output region 7 (main transistor 11), the current detecting region 8 (monitor transistor 14), the temperature detecting region 9 (temperature-sensitive diode 17), the control region 10 (control circuit 18) and the protection region 42 (ESD diode 43) are arranged in the one chip 2. In contrast thereto, the semiconductor device 1B according to the second embodiment does not include the control region 10 (control circuit 18) but includes the output region 7 (main transistor 11), the current detecting region 8 (monitor transistor 14), the temperature detecting region 9 (temperature-sensitive diode 17), the control region 10 (control circuit 18) and the protection region 42 (ESD diode 43).

The semiconductor device 1B includes the chip 2, the output region 7 (main transistor 11), the current detecting region 8 (monitor transistor 14), at least one first temperature detecting region 9A (first temperature-sensitive diode 17A), at least one first protection region 42A (first ESD diode 43A), the first trench separation structure 73, the diode separation structure 131, the first field insulating film 191, the second field insulating film 192, the main surface insulating film 196, the interlayer insulating layer 30, the plurality of via electrodes 201 to 209, the n-number (in this embodiment, two) main gate wirings 31, at least one main source wiring 33, at least one monitor source wiring 34, at least one anode wiring 211, at least one cathode wiring 212 and a ground wiring 220. The ground wiring 220 is constituted of a wiring layer which is selectively routed inside the interlayer insulating layer 30.

In this embodiment, the semiconductor device 1B includes one first temperature detecting region 9A (first temperature-sensitive diode 17A) and the plurality of first protection regions 42A (first ESD diodes 43A). The output region 7 (main transistor 11), the current detecting region 8 (monitor transistor 14), the first temperature detecting region 9A (first temperature-sensitive diode 17A), the first protection region 42A (first ESD diode 43A), etc., are each formed in the same manner as in the case of the first embodiment.

The semiconductor device 1B includes a plurality of first terminal electrodes 221. In this embodiment, the plurality of first terminal electrodes 221 include the drain terminal 36, the source terminal 37, an n-number (in this embodiment, two) of first gate terminals 222, a first monitor source terminal 223 for the monitor transistor 14, a first anode terminal 224 for the temperature-sensitive diode 17, a first cathode terminal 225 for the temperature-sensitive diode 17 and a first ground terminal 226.

As in the case of the first embodiment, the drain terminal 36 covers the second main surface 4 of the chip 2. The source terminal 37, the first gate terminal 222, the first monitor source terminal 223, the first anode terminal 224, the first cathode terminal 225 and the first ground terminal 226 are configured so as to be externally connected by a conductive connection member such as a conducting wire (for example, bonding wire), etc. As in the case of the first embodiment, the source terminal 37 covers the output region 7 on the first main surface 3.

The n-number of the first gate terminals 222 are arranged in a region outside the source terminal 37 in a plan view. In this embodiment, the n-number of the first gate terminals 222 are arranged in a region outside the output region 7 in a plan view. The n-number of the first gate terminals 222 are electrically connected individually to the n-number of the main gate wirings 31 so as to individually transmit the n-number of the gate signals G from the outside to the n-number of the main gate wirings 31.

The first monitor source terminal 223 is arranged in a region outside the source terminal 37 in a plan view. In this embodiment, the first monitor source terminal 223 is arranged in a region outside the output region 7 in a plan view. The first monitor source terminal 223 is electrically connected to a first monitor source FMS of the monitor transistor 14 via the monitor source wiring 34.

The first anode terminal 224 is arranged in a region outside the source terminal 37 in a plan view. In this embodiment, the first anode terminal 224 is arranged in a region outside the output region 7 in a plan view. The first anode terminal 224 is electrically connected to the anode region 161 of the temperature-sensitive diode 17 via the anode wiring 211. The first cathode terminal 225 is arranged in a region outside the source terminal 37 on the first main surface 3 (specifically, on the interlayer insulating layer 30).

In this embodiment, the first cathode terminal 225 is arranged in a region outside the output region 7 in a plan view. The first cathode terminal 225 is electrically connected to the cathode region 162 of the temperature-sensitive diode 17 via the cathode wiring 212. The first ground terminal 226 is arranged in a region outside the source terminal 37 in a plan view. In this embodiment, the first ground terminal 226 is arranged in a region outside the output region 7 in a plan view. The first anode terminal 224 is electrically connected to the ground wiring 220. The first ground terminal 226 and the ground wiring 220 may be provided or may not be provided or they may be removed.

For example, the plurality of first protection regions 42A may be arranged at an interval from the first terminal electrode 221 other than the drain terminal 36 in the first direction X or in the second direction Y in a plan view and face at least one first terminal electrode 221 in the first direction X or in the second direction Y. The plurality of first protection regions 42A may overlap with at least one first terminal electrode 221 in a plan view.

The plurality of first ESD diodes 43A protect the main transistor 11, the monitor transistor 14, the temperature-sensitive diode 17, etc., from static electricity that can be produced, upon connection of a conducting wire (for example, bonding wire) to the plurality of first terminal electrodes 221. The first ESD diode 43A may be connected to an arbitrary first terminal electrode 221, and the plurality of first ESD diodes 43A may not be necessarily required to be electrically connected to all of the first terminal electrodes 221 other than the drain terminal 36. That is, the first ESD diode 43A may be electrically connected to the first terminal electrode 221 which needs protection from static electricity among the plurality of first terminal electrodes 221.

In this embodiment, the plurality of first ESD diodes 43A are interposed between the plurality of first terminal electrodes 221 and an arbitrary application end of a low potential so that a forward direction current flows to the side of the plurality of first terminal electrodes 221 other than the drain terminal 36 and the source terminal 37. Anodes of the plurality of first ESD diodes 43A may be electrically connected to the source terminal 37 or may be electrically connected to the first ground terminal 226.

As described above, according to the embodiment, it is possible to provide the novel semiconductor device 1B having a diode high in versatility. That is, the semiconductor device 1B includes the chip 2, the diode region (temperature detecting region 9 and/or protection region 42), the plurality of diode trench structures 151 (trench structures) and the diode (temperature-sensitive diode 17 and/or ESD diode 43). The chip 2 has the first main surface 3. The diode region is arranged in the first main surface 3.

The plurality of diode trench structures 151 are formed in the first main surface 3 at an interval in the diode region. The plurality of diode trench structures 151 each have an electrode structure that includes the third upper electrode 157 (upper electrode) and the third lower electrode 158 (lower electrode) which are embedded in the trench 84 across an insulator in an up/down direction. The diode has a pn-junction portion which is formed in a surface layer portion of the first main surface 3 at a region between the plurality of diode trench structures 151.

This diode can have forward direction voltage characteristics in which a linear change occurs in response to a change in temperature. Further, although this diode is different in structure from a Zener diode, it can have the same breakdown voltage characteristics as a Zener diode. Thereby, this diode can be utilized as the temperature-sensitive diode 17 or the ESD diode 43. Thus, it is possible to provide the novel semiconductor device 1B having a diode high in versatility. The above-described semiconductor device 1B eliminates a necessity for providing the control region 10 (control circuit 18), thus making it possible to simplify a wiring pattern and at the same time reduce the number of manufacturing manhours.

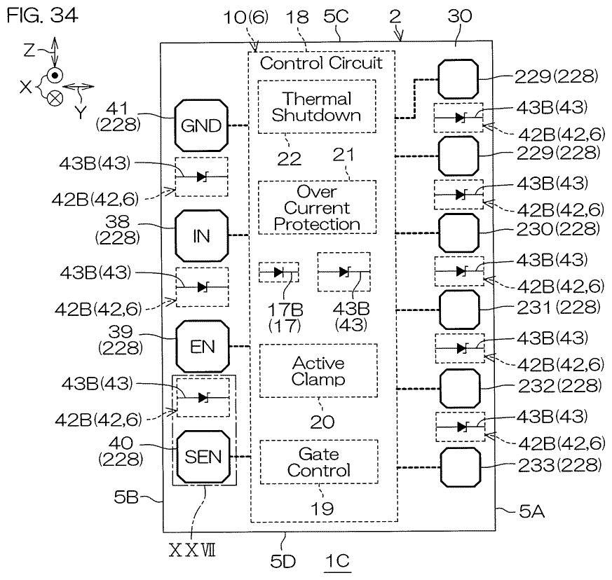

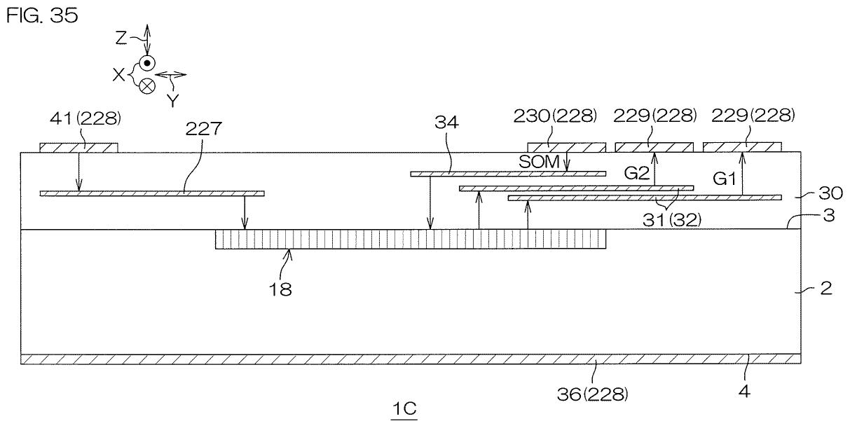

FIG. 34 is a schematic plan view which shows a semiconductor device 1C according to a third embodiment. FIG. 35 is a schematic cross-sectional view of the semiconductor device 1C shown in FIG. 34. In FIG. 34 and FIG. 35, there is shown a mode in which two-system gate signals G1 and G2 are generated, however, the mode is not limited thereto.

In the semiconductor device 1A according to the above-described first embodiment, the output region 7 (main transistor 11), the current detecting region 8 (monitor transistor 14), the temperature detecting region 9 (temperature-sensitive diode 17), the control region 10 (control circuit 18) and the protection region 42 (ESD diode 43) are arranged in the one chip 2.

In contrast thereto, the semiconductor device 1C according to the third embodiment does not include the output region 7 (main transistor 11) and the current detecting region 8 (monitor transistor 14) but includes the temperature detecting region 9 (temperature-sensitive diode 17), the control region 10 (control circuit 18) and the protection region 42 (ESD diode 43). For example, the semiconductor device 1C is a semiconductor control device which is externally connected to the semiconductor device 1B according to the second embodiment and controls the semiconductor device 1B from the outside.

The semiconductor device 1C includes the chip 2, the control region 10 (control circuit 18), at least one second temperature detecting region 9B (second temperature-sensitive diode 17B), at least one second protection region 42B (second ESD diode 43B), the first trench separation structure 73, the diode separation structure 131, the first field insulating film 191, the second field insulating film 192, the main surface insulating film 196, the interlayer insulating layer 30, the plurality of via electrodes 206 to 208, the n-number of (in this embodiment, two) main gate wirings 31, at least one monitor source wiring 34, at least one anode wiring 211, at least one cathode wiring 212 and a ground wiring 227. The ground wiring 227 is constituted of a wiring layer which is selectively routed inside the interlayer insulating layer 30.

In this embodiment, the semiconductor device 1C includes the one second temperature detecting region 9B (second temperature-sensitive diode 17B) and the plurality of second protection regions 42B (second ESD diodes 43B). The output region 7 (main transistor 11), the current detecting region 8 (monitor transistor 14), the second temperature detecting region 9B (second temperature-sensitive diode 17B), the second protection region 42B (second ESD diode 43B), etc., are each formed in the same manner as in the case of the first embodiment.

The semiconductor device 1C includes a plurality of second terminal electrodes 228 which are arranged on the first main surface 3 (specifically, on the interlayer insulating layer 30). The plurality of second terminal electrodes 228 further include the drain terminal 36, the input terminal 38, the enable terminal 39, the sense terminal 40, the ground terminal 41, an n-number of (in this embodiment, two) second gate terminals 229, a second monitor source terminal 230, a second anode terminal 231, a second cathode terminal 232 and a second ground terminal 233.

As in the case of the first embodiment, the drain terminal 36 covers the second main surface 4 of the chip 2. The input terminal 38, the enable terminal 39, the sense terminal 40, the ground terminal 41, the second gate terminal 229, the second monitor source terminal 230, the second anode terminal 231, the second cathode terminal 232 and the second ground terminal 233 are configured so as to be externally connected by a conductive connection member such as a conducting wire (for example, a bonding wire), etc.

The input terminal 38, the enable terminal 39, the sense terminal 40 and the ground terminal 41 are arrayed in a single row on one end portion side of the chip 2 with respect to the control region 10 (control circuit 18) in a plan view. That is, in the semiconductor device 1C, the plurality of second terminal electrodes 228 for the control circuit 18 are arrayed in a single row on one end portion side of the chip 2 in a plan view.

The second gate terminal 229, the second monitor source terminal 230, the second anode terminal 231, the second cathode terminal 232 and the second ground terminal 233 (hereinafter, simply referred to as “terminal electrodes 228 to 232”) are arrayed on the other end portion side of the chip 2 in a single row with respect to the control region 10 (control circuit 18) in a plan view.

The terminal electrodes 228 to 232 are each arranged so as to be electrically connected respectively to the terminal electrodes 222 to 226 of the semiconductor device 1B in correspondence to the terminal electrodes 222 to 226. That is, in the semiconductor device 1C, the plurality of second terminal electrodes 228 for the semiconductor device 1B face the plurality of second terminal electrodes 228 for the control circuit 18 across the control circuit 18 in a plan view and are arrayed in a single row on the other end portion side of the chip 2.

The n-number of the second gate terminals 229 are each electrically connected to the n-number of the main gate wirings 31 and individually transmit the n-number of the gate signals G generated by the control circuit 18 to the n-number of the main gate wirings 31. The second monitor source terminal 230 is electrically connected to the control circuit 18 (overcurrent protection circuit 21) via the monitor source wiring 34.

The second anode terminal 231 is electrically connected to an arbitrary application end of high potential (for example, the power potential VB) via the anode wiring 211. The second cathode terminal 232 is electrically connected to the thermal shutdown circuit 22 via the cathode wiring 212. The second ground terminal 233 is electrically connected to the ground wiring 227 (ground terminal 41). The second ground terminal 233 and the ground wiring 227 may be provided or may not be provided, or they may be removed.

For example, the plurality of second protection regions 42B may be arranged at an interval from the plurality of second terminal electrodes 228 other than the drain terminal 36 in the first direction X or in the second direction Y in a plan view and face at least the second terminal electrode 228 in the first direction X or in the second direction Y. The plurality of second protection regions 42B may overlap with at least one second terminal electrode 228 other than the drain terminal 36 in a plan view.

The plurality of second ESD diodes 43B protect the control circuit 18, the second temperature-sensitive diode 17B, etc., from static electricity which can be produced upon connection of a conducting wire (for example, bonding wire) to the plurality of second terminal electrodes 228. The second ESD diode 43B can be connected to an arbitrary second terminal electrode 228, and the plurality of second ESD diodes 43B are not necessarily required to be electrically connected to all of the second terminal electrodes 228 other than the drain terminal 36. That is, the second ESD diode 43B may be electrically connected to the second terminal electrode 228 which needs protection from static electricity among the plurality of second terminal electrodes 228.

In this embodiment, the plurality of second ESD diodes 43B are interposed between the plurality of second terminal electrodes 228 and an arbitrary application end of low potential so that a forward direction current flows to the side of the plurality of second terminal electrodes 228 other than the drain terminal 36, the ground terminal 41 and the second ground terminal 233.

Further, at least one second ESD diode 43B is interposed between the active clamp circuit 20 and an arbitrary application end of low potential so that a forward direction current flows to the active clamp circuit 20 side. The anodes of the plurality of second ESD diodes 43B may be electrically connected to the ground terminal 41 (second ground terminal 233).

As described above, according to the embodiment, it is possible to provide the novel semiconductor device 1C having a diode high in versatility. That is, the semiconductor device 1C includes the chip 2, the diode region (temperature detecting region 9 and/or protection region 42), the plurality of diode trench structures 151 (trench structure) and the diode (temperature-sensitive diode 17 and/or ESD diode 43). The chip 2 has the first main surface 3. The diode region is arranged in the first main surface 3.

The plurality of diode trench structures 151 are formed in the first main surface 3 at an interval in the diode region. The plurality of diode trench structures 151 each have an electrode structure that includes the third upper electrode 157 (upper electrode) and the third lower electrode 158 (lower electrode) which are embedded in the trench 84 across an insulator in an up/down direction. The diode has a pn-junction portion which is formed in a surface layer portion of the first main surface 3 at a region between the plurality of diode trench structures 151.

This diode can have forward direction voltage characteristics in which a linear change occurs in response to a change in temperature. Further, although the diode is different in structure from a Zener diode, it can have the same breakdown voltage characteristics as a Zener diode. Thereby, this diode can be utilized as the temperature-sensitive diode 17 or the ESD diode 43.

Thus, it is possible to provide the novel semiconductor device 1C which has a diode high in versatility. This semiconductor device 1C eliminates a necessity for providing the output region 7 (main transistor 11 and monitor transistor 14), thus making it possible to simplify a wiring pattern and also reduce the number of manufacturing manhours.

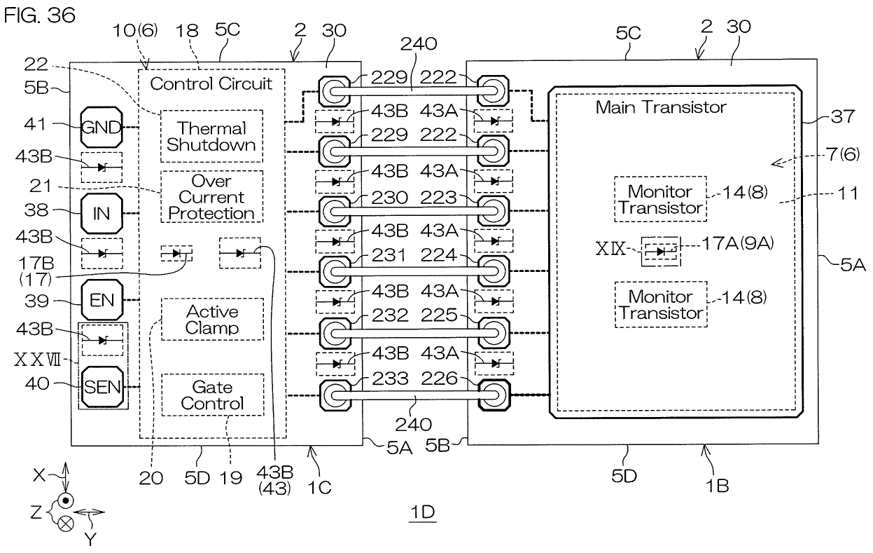

FIG. 36 is a schematic plan view which shows a semiconductor module 1D according to a fourth embodiment. With reference to FIG. 36, the semiconductor module 1D includes the semiconductor device 1B according to the second embodiment, the semiconductor device 1C according to the third embodiment and a plurality of conductive connection members 240. That is, the semiconductor module 1D has a structure in which the semiconductor device 1A according to the first embodiment is separated into the semiconductor device 1B and the semiconductor device 1C. Hereinafter, the semiconductor device 1B side may be referred to as an “output side,” and the semiconductor device 1C side may be referred to as a “control side.”

In this embodiment, the plurality of conductive connection members 240 are each constituted of a conducting wire (bonding wire). The plurality of conductive connection members 240 may include at least one among a copper wire, an aluminum wire and a gold wire. As a matter of course, the conductive connection member 240 may be a member other than the conducting wire (for example, a metal plate, metal clip, etc.). The plurality of conductive connection members 240 electrically connect each of the plurality of first terminal electrodes 221 of the semiconductor device 1B with a corresponding second terminal electrode 228 of the semiconductor device 1C in a one-to-one correspondence.

The semiconductor device 1C generates the n-number of the gate signals G and outputs the n-number of the gate signals G to the n-number of the main gate wirings 31 on the control side. The n-number of the gate signals G are input into the n-number of the first gate terminals 222 of the semiconductor device 1B via the n-number of the conductive connection members 240. Thereby, the n-number of the gate signals G are input into the first gate FG of the main transistor 11 via the main gate wiring 31 on the output side, and on/off control of the main transistor 11 is performed in a predetermined switching pattern. Further, on/off control of the monitor transistor 14 is performed at the same time in conjunction with the main transistor 11.

The output current IO generated by the main transistor 11 is output to the source terminal 37 via the main source wiring 33 on the output side and reaches the first monitor source terminal 223 via the monitor source wiring 34 on the output side. The output monitor current IOM is output to the second monitor source terminal 230 on the control side via the conductive connection member 240. Thereby, the output monitor current IOM is input into the overcurrent protection circuit 21 of the control circuit 18 via the monitor source wiring 34.

The overcurrent protection circuit 21 generates the overcurrent detecting signal SOD where the output monitor current IOM exceeds a predetermined threshold and outputs the overcurrent detecting signal SOD to the gate drive circuit 19. As in the case of the first embodiment, the gate drive circuit 19 generates the n-number of the gate signals G which control the n-number of the system transistors 12 in response to the overcurrent detecting signal SOD. Thereby, an overcurrent state of the output region 7 is eliminated.

On one hand, the first temperature-sensitive diode 17A of the semiconductor device 1B generates the first temperature detecting signal ST1 which detects the first temperature TE1 of the semiconductor device 1B (specifically, output region 7). The first temperature detecting signal ST1 generated by the first temperature-sensitive diode 17A is output to the first cathode terminal 225 via the cathode wiring 212 on the output side and reaches the second cathode terminal 232 of the semiconductor device 1C via the conductive connection member 240. Thereby, the first temperature detecting signal ST1 is input into the thermal shutdown circuit 22 of the control circuit 18 via the cathode wiring 212 on the control side.

On the other hand, the second temperature-sensitive diode 17B of the semiconductor device 1C generates the second temperature detecting signal ST2 which detects the second temperature TE2 of the semiconductor device 1C (specifically, control region 10). The second temperature detecting signal ST2 generated by the second temperature-sensitive diode 17B is input into the thermal shutdown circuit 22 of the control circuit 18 via the cathode wiring 212 on the control side. The thermal shutdown circuit 22 generates the difference signal ΔVf on the basis of the first temperature detecting signal ST1 and the second temperature detecting signal ST2.

The overcurrent protection circuit 21 generates the overheat detecting signal SOH when the difference signal ΔVf exceeds the threshold VT and outputs the overheat detecting signal SOH to the gate drive circuit 19. As in the case of the first embodiment, the gate drive circuit 19 generates the n-number of the gate signals G which control the n-number of the system transistors 12 in response to the overheat detecting signal SOH. Thereby, an overheat state of the output region 7 is eliminated.

As described above, according to the embodiment, it is possible to provide the novel semiconductor module 1D which has a diode high in versatility.

The present invention can be executed by still other embodiments. In each of the above-described embodiments, a specific structure of the two-system main transistor 11 and the two-system monitor transistor 14 is shown. Where the n-system main transistor 11 is adopted, the n-number of the system transistors 12 each include at least one unit cell 81.

Further, where the m-system (n-system) monitor transistor 14 is adopted, the m-number (the n-number) of the system monitor transistors 15 each include at least one unit cell 81. An electrical connection mode of the n-number of the system transistors 12 and the m-number (the n-number) of the system monitor transistors 15 is adjusted by the plurality of via electrodes 201 to 209, the plurality of main source wirings 33, the plurality of monitor source wirings 34, the plurality of main gate wirings 31, etc.

In each of the above-described embodiments, an example where the system monitor currents ISM of the plurality of system monitor transistors 15 are taken out as the output monitor current IOM from the first monitor drain FMD and the first monitor source FMS was shown. However, the second monitor source SMS of at least one system monitor transistor 15 may be electrically separated from the first monitor source FMS and may form a current path which is electrically independent of the first monitor source FMS.

That is, in the monitor transistor 14, a structure in which at least one system monitor current ISM is taken out individually from the output monitor current IOM may be adopted. Also, in the monitor transistor 14, the plurality of system monitor currents ISM may be taken out individually from the output monitor current IOM via a plurality of current paths or the same current path.

For example, where the three-system main transistor 11 including the first to third system transistors 12 is adopted, the output monitor current IOM may be constituted of the system monitor currents ISM of the first and second system transistors 12, and the system monitor current ISM of the third system transistor 12 may be taken out from a current path different from that of the output monitor current IOM.

In this case, the control circuit 18 including a current detection circuit for the third system transistor 12 may be adopted and the system monitor current ISM that is different from the output monitor current IOM may be input into the current detection circuit. The control circuit 18 may be configured so as to control the main transistor 11 on the basis of the system monitor current ISM input into the current detection circuit or may be configured so as to control a functional circuit other than the main transistor 11 (for example, a state detection circuit such as the overcurrent protection circuit 21 and the thermal shutdown circuit 22).

In each of the above-described embodiments, an example where the plurality of system monitor transistors are connected to the corresponding system transistor 12 in a one-to-one correspondence was shown. However, the plurality of first monitor gates FMG may be connected to one first gate FG.

That is, the monitor transistor 14 may include the plurality of system monitor transistors 15 which generate the plurality of system monitor currents ISM monitoring one system current IS. At least one or all of the plurality of system monitor currents ISM monitoring one system current IS may configure a part of the output monitor current IOM. At least one or all of the plurality of system monitor currents ISM monitoring one system current IS may configure the system monitor current ISM different from the output monitor current IOM.

In each of the above-described embodiments, a description of an example where the monitor transistor 14 includes the system monitor transistor 15 which is electrically connected to the system transistor 12 was given. However, the monitor transistor 14 may include at least one system monitor transistor 15 which is electrically independent of the system transistor 12.

That is, at least one first monitor gate FMG of the monitor transistor 14 may be controlled by at least one monitor gate signal MG which is electrically independent of the gate signal G. In this case, the monitor transistor 14 may be configured so as to generate the output monitor current IOM in which a current corresponding to at least one system monitor current ISM that is electrically independent is added to another system monitor current ISM.

In each of the above-described embodiments, an example where one gate drive circuit 19 is connected to the main transistor 11 and the monitor transistor 14 was shown. However, structure in which the gate drive circuit 19 is connected to the main transistor 11 and the second gate drive circuit 19 is connected to the monitor transistor 14. In this case, the monitor transistor 14 may be controlled so as to work in conjunction with the main transistor 11 or may be controlled so as not to work in conjunction with the main transistor 11.

In each of the above-described embodiments, a description of an example where one active clamp circuit 20 is connected to the main transistor 11 and the monitor transistor 14 was shown. However, a structure that the first active clamp circuit 20 is connected to the main transistor 11 and the second active clamp circuit 20 is connected to the monitor transistor 14 may be adopted.

In each of the above-described embodiments, an example where the first lower electrode 88A is fixed to the same potential as the first upper electrode 87A. However, a potential different from the first upper electrode 87A may be applied to the first lower electrode 88A. In this case, the first lower electrode 88A may be formed as a source electrode and the source potential may be applied to the first lower electrode 88A. According to this structure, it is possible to lower a parasitic capacitance between the chip 2 and the first lower electrode 88A. Thereby, the first unit transistor 13A (main transistor 11) can be improved in switching speed.

In each of the above-described embodiments, an example where the second lower electrode 88B is fixed at the same potential as the second upper electrode 87B was shown. However, a potential different from the second upper electrode 87B may be applied to the second lower electrode 88B. In this case, the second lower electrode 88B may be formed as a source electrode and the source potential may be applied to the second lower electrode 88B. According to this structure, it is possible to lower a parasitic capacitance between the chip 2 and the second lower electrode 88B. Thereby, the second unit transistor 13B (main transistor 11) can be improved in switching speed.

In each of the above-described embodiments, an example where the third lower electrode 158 is fixed at the same potential as the third upper electrode 157 was shown. However, the third upper electrode 157 and the third lower electrode 158 may be fixed at an anode potential, a cathode potential, a ground potential, a floating potential or other potentials (for example, a source potential) whenever necessary. The floating potential means a state that is not electrically connected to another member (that is, electrically floating state). As a matter of course, the third upper electrode 157 and the third lower electrode 158 may be fixed at potentials which are different from each other.

In each of the above-described embodiments, where the first upper electrode 87A and the first lower electrode 88A are fixed at the same potential, the first intermediate insulating film 89A may be removed from the first trench structure 82A. In this case, the first lower electrode 88A may be formed integrally with the first upper electrode 87A.

In each of the above-described embodiments, where the second upper electrode 87B and the second lower electrode 88B are fixed at the same potential, the second intermediate insulating film 89B may be removed from the second trench structure 82B. In this case, the second lower electrode 88B may be formed integrally with the second upper electrode 87B.

In each of the above-described embodiments, where the third upper electrode 157 and the third lower electrode 158 are fixed at the same potential, the third intermediate insulating film 159 may be removed from the diode trench structure 151. In this case, the third lower electrode 158 may be formed integrally with the third upper electrode 157.

In each of the above-described embodiments, a description of an example where the circuit region 6 includes the output region 7, the current detecting region 8, the temperature detecting region 9, the control region and the protection region 42 was given. However, the temperature detecting region 9 and the protection region 42 may be regarded as a region separated from the circuit region 6. That is, the temperature detecting region 9 may be regarded as a region which is arranged so as to detect a temperature at an arbitrary site of the circuit region 6, and the protection region 42 may be regarded as a region which is arranged so as to protect an arbitrary site of the circuit region 6.

In each of the above-described embodiments, an example where the first conductive type is a p-type and the second conductive type is an n-type was shown, however, the first conductive type may be an n-type and the second conductive type may be a p-type. S specific configuration of this case is obtained by replacing the n-type region with the p-type region and replacing the p-type region with the n-type region in the above description and the attached drawings. In each of the above-described embodiments, the first direction X and the second direction Y are defined by a direction in which the first to fourth side surfaces 5A to 5D of the chip 2 extend, however, the first direction X and the second direction Y may be an arbitrary direction as long as they keep a mutually intersecting (specifically, orthogonal) relationship.

Hereinafter, examples of features extracted from the specification and the drawings are shown. Hereinafter, a novel semiconductor device, semiconductor control device and semiconductor module having a diode high in versatility shall be provided. Hereinafter, although alphanumeric characters within parentheses express corresponding components, etc., in the above-described embodiments, these are not meant to limit the scopes of respective items (Clauses) to the embodiments.

In the following Clauses, the “semiconductor device,” the “semiconductor control device” and the “semiconductor module” may be replaced by an “electric circuit” or a “semiconductor circuit.” In these cases, a novel “electric circuit” or “semiconductor circuit” having a diode high in versatility can be provided.

[A1] A semiconductor device (1A, 1B, 1C) comprising: a chip (2) which has a main surface (3); a diode region (9, 42) which is arranged in the main surface (3); trench structures (151) which are formed in the main surface (3) at an interval in the diode region (9, 42), the trench structures (151) each having an electrode structure that includes an upper electrode (157) and a lower electrode (158) which are embedded in a trench (154) across an insulator (155, 156) in an up/down direction; and a diode (17, 43) which has a pn-junction portion that is formed in a surface layer portion of the main surface (3) at a region between the trench structures (151).

[A2] The semiconductor device (1A, 1B, 1C) according to A1, further comprising: a first conductive type (p-type) body region (150) which is formed in the surface layer portion of the main surface (3) in the diode region (9, 42); wherein the trench structures (151) are formed in the main surface (3) so as to penetrate through the body region (150), and the diode (17, 43) includes a first conductive type (p-type) first polarity region (161) which is formed in the body region (150) and a second conductive type (n-type) second polarity region (162) which is formed in the body region (150) so as to form the pn-junction portion with the first polarity region (161).

[A3] The semiconductor device (1A, 1B, 1C) according to A2, wherein the first polarity region (161) includes a high concentration region (161a) which has an impurity concentration higher than that of the body region (150) and a low concentration region (161b, 161c) which has an impurity concentration lower than that of the high concentration region (161a), and the second polarity region (162) forms the pn-junction portion with the low concentration region (161b, 161c) of the first polarity region (161).

[A4] The semiconductor device (1A, 1B, 1C) according to A3, wherein the low concentration region (161b, 161c) is constituted of a part of the body region (150).

[A5] The semiconductor device (1A, 1B, 1C) according to any one of A2 to A4, wherein the upper electrodes (157) of the trench structures (151) are embedded on the main surface (3) side with respect to a bottom portion of the body region (150), and the lower electrodes (158) of the trench structures (151) are embedded on the bottom wall side of the trench (154) with respect to the bottom portion of the body region (150).

[A6] The semiconductor device (1A, 1B, 1C) according to any one of A2 to A5, wherein the first polarity region (161) is fixed at the same potential as one of or both of the lower electrode (158) and the upper electrode (157) of the trench structures (151).

[A7] The semiconductor device (1A, 1B, 1C) according to any one of A1 to A6, wherein the insulator (155, 156) includes an upper insulating film (155) which covers an upper wall surface of the trench (154) with a first thickness (T1) and a lower insulating film (156) which covers a lower wall surface of the trench (154) with a second thickness (T2) exceeding the first thickness (T1), the upper electrode (157) is embedded on the upper wall surface side of the trench (154) across the upper insulating film (155), and the lower electrode (158) is embedded on the lower wall surface side of the trench (154) across the lower insulating film (156).

[A8] The semiconductor device (1A, 1B, 1C) according to any one of A1 to A7, further composing: a separation structure (131, 132, 133) which is formed in the main surface (3) so as to electrically separate the diode region (9, 42) from another region.

[A9] The semiconductor device (1A, 1B, 1C) according to A8, wherein the separation structure (131, 132, 133) includes a separation electrode (136, 146) which is embedded in a separation trench (134, 144) across a separation insulator (135, 145).

[A10] The semiconductor device (1A, 1B, 1C) according to any one of A1 to A9, wherein the diode region (9, 42) is a temperature detecting region (9), and the diode (17, 43) is a temperature-sensitive diode (17).

[A11] The semiconductor device (1A, 1B, 1C) according to A10, wherein the temperature-sensitive diode (17) has temperature characteristics in which a forward direction voltage linearly changes in response to a change in temperature.

[A12] The semiconductor device (1A, 1B, 1C) according to A10 or A11, further comprising: a device region (7) which is arranged in the main surface (3); and a functional device (11) which is formed in the device region (7); wherein the temperature detecting region (9) is arranged so as to be adjacent to the device region (7) in a plan view, and the temperature-sensitive diode (17) detects a temperature of the device region (7).

[A13] The semiconductor device (1A, 1B, 1C) according to A12, wherein the temperature detecting region (9) is arranged in a region which is surrounded by the device region (7) in a plan view.

[A14] The semiconductor device (1A, 1B, 1C) according to A12 or A13, wherein the functional device (11) includes a trench gate structure (82) which has an electrode structure including an upper gate electrode (87) and a lower gate electrode (88) which are embedded in a gate trench (84) across a gate insulator (85, 86) in an up/down direction.

[A15] The semiconductor device (1A, 1B, 1C) according to any one of A12 to A14, wherein the functional device (11) includes a plural-system gate divided transistor (11) that includes system transistors (12) each of which is formed in the main surface (3) so as to be individually controlled, and that generates a single output signal (IO) by selectively controlling the system transistors (12).

[A16] The semiconductor device (1A, 1B, 1C) according to any one of A1 to A9, further comprising a device region (7) which is arranged in the main surface (3); and a functional device (11) which is formed in the device region (7); wherein the diode region (9, 42) is a protection region (42), and the diode (17, 43) is an electrostatic breakdown protection diode (43).

[A17] The semiconductor device (1A, 1B, 1C) according to A16, further comprising; a terminal electrode (35, 221, 228) which is arranged on the main surface (3) so as to be electrically connected to the functional device (11); wherein the electrostatic breakdown protection diode (43) is electrically connected to the terminal electrode (35, 221, 228).

[A18] A semiconductor device (1A, 1B, 1C) comprising: a chip (2) which has a main surface (3); a temperature detecting region (9) which is arranged in the main surface (3); a protection region (42) which is arranged in a region different from the temperature detecting region (9) in the main surface (3); first trench structures (151) which are formed in the main surface (3) at an interval in the temperature detecting region (9), the first trench structures (151) each having an electrode structure including a first upper electrode (157) and a first lower electrode (158) which are embedded in a first trench (154) across a first insulator (155, 156) in an up/down direction; a temperature-sensitive diode (17) which has a first pn-junction portion that is formed in a surface layer portion of the main surface (3) at a region between the first trench structures (151); second trench structures (151) which are formed in the main surface (3) at an interval in the protection region (42), the second trench structures (151) each having an electrode structure including a second upper electrode (157) and a second lower electrode (158) which are embedded in a second trench (154) across a second insulator (155, 156) in an up/down direction; and an electrostatic breakdown protection diode (43) which has a second pn-junction portion that is formed in the surface layer portion of the main surface (3) at a region between the second trench structures (151).

[A19] The semiconductor device (1A, 1B, 1C) according to any one of A1 to A18, further comprising: a control region (10) which is arranged in the main surface (3); and a control circuit (18) which is formed in the control region (10).

[A20] A semiconductor module (1D) comprising: the semiconductor device (1B) according to any one of A1 to A18, and a control device (1C) which is configured so as to be electrically connected to the semiconductor device (1B) and control the semiconductor device (1B).

[B1] A semiconductor device (1A, 1B, 1C) comprising: a chip (2) which has a main surface (3); a circuit region (6) which is arranged in the main surface (3); a protection region (42) which is arranged in the main surface (3); an electric circuit (11, 18) which is formed in the circuit region (6); trench structures (151) which are formed in the main surface (3) at an interval in the protection region (42), wherein the trench structures (151) each have an electrode structure including an upper electrode (157) and a lower electrode (158) which are embedded in a trench (154) across an insulator (155, 156) in an up/down direction; and an electrostatic breakdown protection diode (43) which has a pn-junction portion formed in a surface layer portion of the main surface (3) at a region between the trench structures (151) and which is electrically connected to the electric circuit (11, 18).

[B2] The semiconductor device (1A, 1B, 1C) according to B1, further comprising: a terminal electrode (35, 221, 228) which is arranged on the main surface (3) so as to be electrically connected to the electric circuit (11, 18), wherein the electrostatic breakdown protection diode (43) is electrically connected to the terminal electrode (35, 221, 228).

[B3] The semiconductor device (1A, 1B, 1C) according to B2, wherein the electrostatic breakdown protection diode (43) is arranged at a position in a close proximity to the terminal electrode (35, 221, 228) in a plan view.

[B4] The semiconductor device (1A, 1B, 1C) according to B2 or B3, wherein the electrostatic breakdown protection diode (43) is arranged so as to be adjacent to the terminal electrode (35, 221, 228) in a plan view or so as to overlap with the terminal electrode (35, 221, 228) in a plan view.

[B5] The semiconductor device (1A, 1B, 1C) according to any one of B2 to B4, wherein the electrostatic breakdown protection diode (43) has an anode which is electrically connected to a reference potential or a ground potential and a cathode which is electrically connected to the terminal electrode (35, 221, 228).

[B6] The semiconductor device (1A, 1B, 1C) according to any one of B2 to B5, wherein the electrostatic breakdown protection diode (43) has an area less than an area of the terminal electrode (35, 221, 228) in a plan view.

[B7] The semiconductor device (1A, 1B, 1C) according to any one of B2 to B6, wherein the terminal electrodes (35, 221, 228) are arranged on the main surface (3), and the electrostatic breakdown protection diodes (43) are each electrically connected to the terminal electrodes (35, 221, 228).

[B8] The semiconductor device (1A, 1B, 1C) according to any one of B1 to B7, further comprising: a first conductive type (p-type) body region (150) which is formed in a surface layer portion of the main surface (3) in the protection region (42); wherein the trench structures (151) are formed in the main surface (3) so as to penetrate through the body region (150), and the electrostatic breakdown protection diode (43) includes a first conductive type (p-type) first polarity region (161) which is formed in the body region (150) and a second conductive type (n-type) second polarity region (162) which is formed in the body region (150) so as to form the pn-junction portion with the first polarity region (161).

[B9] The semiconductor device (1A, 1B, 1C) according to B8, wherein the first polarity region (161) includes a high concentration region (161a) which has an impurity concentration higher than that of the body region (150) and a low concentration region (161b, 161c) which has an impurity concentration lower than that of the high concentration region (161a), and the second polarity region (162) forms the pn-junction portion with the low concentration region (161b, 161c) of the first polarity region (161).

[B10] The semiconductor device (1A, 1B, 1C) according to B9, wherein the low concentration region (161b, 161c) is constituted of a part of the body region (150).

[B11] The semiconductor device (1A, 1B, 1C) according to B9 or B10, wherein the high concentration region (161a) is formed at an interval from a bottom portion of the body region (150) to the main surface (3) side, and the second polarity region (162) is formed at an interval from the bottom portion of the body region (150) to the main surface (3) side.

[B12] The semiconductor device (1A, 1B, 1C) according to any one of B8 to B11, wherein the upper electrodes (157) of the trench structures (151) are embedded on the main surface (3) side with respect to the bottom portion of the body region (150), and the lower electrodes (158) of the trench structures (151) are embedded on the bottom wall side of the trench (154) with respect to the bottom portion of the body region (150).

[B13] The semiconductor device (1A, 1B, 1C) according to any one of B8 to B12, wherein the first polarity region (161) is fixed at the same potential as one of or both of the lower electrode (158) and the upper electrode (157) of the trench structures (151).

[B14] The semiconductor device (1A, 1B, 1C) according to any one of B1 to B13, wherein the insulator (155, 156) includes an upper insulating film (155) which covers an upper wall surface of the trench (154) with a first thickness (T1) and a lower insulating film (156) which covers a lower wall surface of the trench (154) with a second thickness (T2) exceeding the first thickness (T1), the lower electrode (158) is embedded on the lower wall surface side of the trench (154) across the lower insulating film (156), and the upper electrode (157) is embedded on the upper wall surface side of the trench (154) across the upper insulating film (155).

[B15] The semiconductor device (1A, 1B, 1C) according to any one of B1 to B14, further comprising: a separation structure (131, 132, 133) which is formed in the main surface (3) so as to electrically separate the protection region (42) from another region.

[B16] The semiconductor device (1A, 1B, 1C) according to B15, wherein the separation structure (131, 132, 133) includes a separation electrode (136, 146) which is embedded in a separation trench (134, 144) across a separation insulator (135, 145).

[B17] The semiconductor device (1A, 1B, 1C) according to any one of B1 to B16, further comprising: a transistor region (7, 8) which is included in the circuit region (6); and a transistor (11, 14) which is formed in the main surface (3) in the transistor region (7, 8); wherein the transistor (11, 14) includes a trench gate structure (82) which has an electrode structure including an upper gate electrode (87) and a lower gate electrode (88) which are embedded in a gate trench (84) across a gate insulator (85, 86) in an up/down direction.

[B18] The semiconductor device (1A, 1B, 1C) according to B17, wherein the transistor (11, 14) is a gate divided transistor (11, 14) that includes system transistors (12, 15) each of which is formed in the main surface (3) so as to be individually controlled, and that generates a single output signal (IO, IOM) by selectively controlling the system transistors (12, 15).

[B19] The semiconductor device (1A, 1B, 1C) according to B17 or B18, further comprising: a control region (10) which is included in the circuit region (6); and a control circuit (18) which is formed in the control region (10) so as to be electrically connected to the transistor (11, 14) and configured so as to generate a control signal (G, MG) which controls the transistor (11, 14).

[B20] A semiconductor module (1D) comprising: the semiconductor device (1A, 1B, 1C) according to any one of B1 to B18; and a control device (1A, 1B, 1C) that includes a control circuit (18) which is configured so as to be electrically connected to the semiconductor device (1A, 1B, 1C) and generate a control signal (G, MG) which controls the electric circuit (11, 18).

[C1] A semiconductor device (1A, 1B, 1C) comprising: a chip (2) which has a main surface (3); temperature detecting regions (9) which are arranged in the main surface (3) at an interval; trench structures (151) which are formed in the main surface (3) at an interval in each of the temperature detecting regions (9), the trench structures (151) each having an electrode structure that includes an upper electrode (157) and a lower electrode (158) which are embedded in a trench (154) across an insulator (155, 156) in an up/down direction; and temperature-sensitive diodes (17) each of which has a pn-junction portion which is formed in a surface layer portion of the main surface (3) at a region between the trench structures (151) in the corresponding temperature detecting region (9) and detects a temperature of the corresponding temperature detecting region (9).

[C2] The semiconductor device (1A, 1B, 1C) according to C1, wherein the temperature-sensitive diodes (17) each have temperature characteristics in which a forward direction voltage linearly changes in response to a change in temperature.

[C3] The semiconductor device (1A, 1B, 1C) according to C2, wherein the temperature-sensitive diodes (17) each have temperature characteristics in which a forward direction voltage linearly decreases with an increase in temperature.

[C4] The semiconductor device (1A, 1B, 1C) according to any one of C1 to C3, further comprising: first conductive type (p-type) body regions (150) which are each formed in the surface layer portion of the main surface (3) in the corresponding temperature detecting region (9); wherein the trench structures (151) are each formed in the main surface (3) so as to penetrate through the corresponding body region (150) in corresponding the temperature detecting region (9), and the temperature-sensitive diodes (17) each include, in the corresponding temperature detecting region (9), a first conductive type (p-type) first polarity region (161) which is formed in the corresponding body region (150) and a second conductive type (n-type) second polarity region (162) which is formed in the corresponding body region (150) so as to form the pn-junction portion with the first polarity region (161).

[C5] The semiconductor device (1A, 1B, 1C) according to C4, wherein the first polarity regions (161) each includes a high concentration region (161a) which has an impurity concentration higher than that of the corresponding body region (150) and a low concentration region (161b, 161c) which has an impurity concentration lower than that of the high concentration region (161a), and the second polarity regions (162) each forms the pn-junction portion with the low concentration region (161b, 161c) of the first polarity region (161).

[C6] The semiconductor device (1A, 1B, 1C) according to C5, wherein the low concentration regions (161b, 161c) are each constituted of a part of the corresponding body region (150).

[C7] The semiconductor device (1A, 1B, 1C) according to any one of C1 to C6, further comprising: a device region (7, 8) which is arranged in the main surface (3); a control region (10) which is arranged in the main surface (3); a transistor (11, 14) which is formed in the device region (7, 8); and a control circuit (18) which is formed in the control region (10) so as to be electrically connected to the temperature-sensitive diodes (17) and the transistor (11, 14) and controls the transistor (11, 14) on the basis of an electric signal (ST1, ST2) from the temperature-sensitive diodes (17).

[C8] The semiconductor device (1A, 1B, 1C) according to C7, wherein the control circuit (18) is configured so as to restrict operation of the transistor (11, 14) when a difference value between the electric signals (ST1, ST2) from the temperature-sensitive diodes (17) exceeds a threshold.

[C9] The semiconductor device (1A, 1B, 1C) according to C7 or C8, wherein the temperature detecting regions (9) include a first temperature detecting region (9A) which is arranged at a position in a closer proximity to the device region (7) than the control region (10) and a second temperature detecting region (9B) which is arranged at a position in a closer proximity to the control region (10) than the device region (7).

[C10] The semiconductor device (1A, 1B, 1C) according to C9, wherein the first temperature detecting region (9A) is adjacent to the device region (7), and the second temperature detecting region (9B) is adjacent to the control region (10).

[C11] The semiconductor device (1A, 1B, 1C) according to C9 or C10, wherein the first temperature detecting region (9A) is arranged at an inner portion of the device region (7) view and the second temperature detecting region (9B) is arranged at an inner portion of the control region (10).

[C12] The semiconductor device (1A, 1B, 1C) according to any one of C7 to C11, wherein the transistor (11, 14) includes a trench gate structure (82) which has an electrode structure including an upper gate electrode (87) and a lower gate electrode (88) which are embedded in a gate trench (84) across a gate insulator (85, 86) in an up/down direction.

[C13] The semiconductor device (1A, 1B, 1C) according to any one of C7 to C12, wherein the transistor (11, 14) includes a gate divided transistor (11, 14) that includes system transistors (12, 15) each of which is formed in the main surface (3) so as to be individually controlled, and that generates a single output signal (IO, IOM) by selectively controlling the system transistors (12, 15).

[C14] The semiconductor device (1A, 1B, 1C) according to C13, wherein the gate divided transistor (11, 14) is configured so as to change an on resistance by individually controlling the system transistors (12, 15).

[C15] A semiconductor control device (1C) comprising: a chip (2) which has a main surface (3); a temperature detecting region (9) which is arranged in the main surface (3); a control region (10) which is arranged in the main surface (3); trench structures (151) which are formed in the main surface (3) at an interval in the temperature detecting region (9), the trench structures (151) each having an electrode structure that includes an upper electrode (157) and a lower electrode (158) which are embedded in a trench (154) across an insulator (155, 156) in an up/down direction; a temperature-sensitive diode (17) which has a pn-junction portion that is formed in a surface layer portion of the main surface (3) at a region between the trench structures (151) and generates an internal temperature detecting signal (ST2) which detects a temperature of the temperature detecting region (9); and a control circuit (18) which is configured so as to generate an electric signal on the basis of the internal temperature detecting signal (ST2) from the temperature-sensitive diode (17).

[C16] The semiconductor control device (1C) according to C15, wherein the temperature-sensitive diode (17) has temperature characteristics in which a forward direction voltage linearly changes in response to a change in temperature.

[C17] The semiconductor control device (1C) according to C15 or C16, wherein the temperature-sensitive diode (17) has temperature characteristics in which a forward direction voltage linearly decreases with an increase in temperature.

[C18] The semiconductor control device (1C) according to any one of C15 to C17, further comprising: a first conductive type (p-type) body region (150) which is formed in a surface layer portion of the main surface (3) in the temperature detecting region (9); wherein the trench structures (151) are formed in the main surface (3) so as to penetrate through the body region (150), and the temperature-sensitive diode (17) has a first conductive type (p-type) first polarity region (161) which is formed in the body region (150) and a second conductive type (n-type) second polarity region (162) which is formed in the body region (150) so as to form the pn-junction portion with the first polarity region (161).

[C19] The semiconductor control device (1C) according to C18, wherein the first polarity region (161) includes a high concentration region (161a) which has an impurity concentration higher than that of the body region (150) and a low concentration region (161b, 161c) which has an impurity concentration lower than that of the high concentration region (161a), and the second polarity region (162) forms the pn-junction portion with the low concentration region (161b, 161c) of the first polarity region (161).

[C20] The semiconductor control device (1C) according to C19, wherein the low concentration region (161b, 161c) is constituted of a part of the body region (150).

[C21] The semiconductor control device (1C) according to any one of C15 to C20, wherein the control circuit (18) is configured so that an external temperature detecting signal (ST1) which shows a temperature of the semiconductor device (1A, 1B, 1C) is input from the semiconductor device (1A, 1B, 1C) by being externally connected to the semiconductor device (1A, 1B, 1C) as a to-be-controlled object and configured so as to generate the electric signal on the basis of the internal temperature detecting signal (ST2) and the external temperature detecting signal (ST1).

[D1] A semiconductor module (1D) comprising: a semiconductor device (1B); and a semiconductor control device (1C) which is electrically connected to the semiconductor device (1B); wherein the semiconductor device (1B) including: a first chip (2); a first temperature detecting region (9A) which is arranged in the first chip (2); first trench structures (151) which are formed in the first chip (2) at an interval in the first temperature detecting region (9A), the trench structures (151) each having an electrode structure including a first upper electrode (157) and a first lower electrode (158) which are embedded in a first trench (154) across an insulator (155, 156) in an up/down direction; and first temperature-sensitive diode (17A) which has a first pn-junction portion which is formed in a surface layer portion of the first chip (2) at a region between the first trench structures (151), and which generates a first temperature detecting signal (ST1) which shows a temperature of the first temperature detecting region (9A); and the semiconductor control device (1C) including: a second chip (2); a second temperature detecting region (9B) which is arranged in the second chip (2); a control region (10) which is arranged in the second chip (2); second trench structures (151) which are formed in the second chip (2) an interval in the second temperature detecting region (9B), the second trench structures (151) each having an electrode structure including a second upper electrode (157) and a second lower electrode (158) which are embedded in a second trench (154) across an insulator (155, 156) in an up/down direction; a second temperature-sensitive diode (17B) which has a second pn-junction portion which is formed in a surface layer portion of the second chip (2) at a region between the second trench structures (151) and generates a second temperature detecting signal (ST2) which shows a temperature of the second temperature detecting region (9B); and a control circuit (18) which is formed in the control region (10) and generates an electric signal which controls the semiconductor device (1B) on the basis of the first temperature detecting signal (ST1) and the second temperature detecting signal (ST2).

[D2] The semiconductor module (1D) according to D1, wherein the first temperature-sensitive diode (17A) has temperature characteristics in which a forward direction voltage linearly changes in response to a change in temperature, and the second temperature-sensitive diode (17B) has temperature characteristics in which a forward direction voltage linearly changes in response to a change in temperature.

[D3] The semiconductor module (1D) according to D1 or D2, wherein the first temperature-sensitive diode (17A) has temperature characteristics in which a forward direction voltage linearly decreases with an increase in temperature, and the second temperature-sensitive diode (17B) has temperature characteristics in which a forward direction voltage linearly decreases with an increase in temperature.

[D4] The semiconductor module (1D) according to any one of D1 to D3, wherein the control circuit (18) is configured so as to restrict operation of the semiconductor device (1B) when a difference value between the first temperature detecting signal (ST1) and the second temperature detecting signal (ST2) exceeds a threshold.

[D5] The semiconductor module (1D) according to any one of D1 to D4, further comprising: a device region (7) which is arranged in the first chip (2); and a functional device (11, 12) which is formed in the device region (7); wherein the control circuit generates the electric signal which controls the functional device (11, 12).

[D6] The semiconductor module (1D) according to any one of D1 to D5, wherein the functional device (11, 12) is a transistor (11, 14) that includes a trench gate structure (82) which has an electrode structure including an upper gate electrode (87) and a lower gate electrode (88) which are embedded in a gate trench (84) across a gate insulator (85, 86) in an up/down direction.

[D7] The semiconductor module (1D) according to D6, wherein the transistor (11, 14) includes a gate divided transistor (11, 14) that includes system transistors (12, 15) each of which is formed in the first chip (2) so as to be individually controlled, and that generates a single output signal (IO, IOM) by selectively controlling the system transistors (12, 15).

[D8] The semiconductor module (1D) according to D7, wherein the gate divided transistor (11, 14) is configured so as to change an on resistance by individually controlling the system transistors (12, 15).

[E1] A semiconductor device (1A, 1B, 1C) comprising: a chip (2) which has a main surface (3); a current detecting region (8) which is arranged in the main surface (3); a diode region (9, 42) which is arranged in the main surface (3); a current monitor device (14) which is formed in the current detecting region (8) so as to generate a monitor current (IOM); trench structures (151) which are formed in the diode region (9, 42) at an interval, the trench structures (151) each having an electrode structure including an upper electrode (157) and a lower electrode (158) which are embedded in a trench (154) across an insulator (155, 156) in an up/down direction; and a diode (17, 43) which has a pn-junction portion that is formed in a surface layer portion of the main surface (3) at a region between the trench structures (151).

[E2] The semiconductor device (1A, 1B, 1C) according to E1, wherein the current monitor device (14) has monitor trench structures (82) which are formed in the current detecting region (8) and include an upper monitor electrode (87) and a lower monitor electrode (88) which are embedded in a monitor trench (84) across a monitor insulator (85, 86) in an up/down direction.

[E3] The semiconductor device (1A, 1B, 1C) according to E1 or E2, wherein the diode region (9, 42) is a temperature detecting region (9), and the diode (17, 43) is a temperature-sensitive diode (17) which generates a temperature detecting signal which shows a temperature of the temperature detecting region (9).

[E4] The semiconductor device (1A, 1B, 1C) according to E1 or E2, wherein the diode region (9, 42) is a protection region (42), and the diode (17, 43) is an electrostatic breakdown protection diode (43).

[E5] The semiconductor device (1A, 1B, 1C) according to any one of E1 to E4, further comprising: a control region (10) which is arranged in the main surface (3); and a control circuit (18) which is formed in the control region (10) so as to be electrically connected to the current monitor device (14) and the diode (17, 43).

While the embodiments of the present invention have been described in detail, these are merely specific examples used to clarify the technical contents of the present invention and the present invention should not be interpreted as being limited to these specific examples, and the scope of the present invention is to be limited by the appended claims.

What is claimed is:

1. A semiconductor device comprising:
a chip which has a main surface;
a diode region which is arranged in the main surface;
trench structures which are formed in the main surface at an interval in the diode region, the trench structures each having an electrode structure that includes an upper electrode and a lower electrode which are embedded in a trench across an insulator in an up/down direction; and
a diode which has a pn-junction portion that is formed in a surface layer portion of the main surface at a region between the trench structures.

2. The semiconductor device according to claim 1, further comprising:
a first conductive type body region which is formed in the surface layer portion of the main surface in the diode region;
wherein the trench structures are formed in the main surface so as to penetrate through the body region, and
the diode includes a first conductive type first polarity region which is formed in the body region and a second conductive type second polarity region which is formed in the body region so as to form the pn-junction portion with the first polarity region.

3. The semiconductor device according to claim 2,
wherein the first polarity region includes a high concentration region which has an impurity concentration higher than that of the body region and a low concentration region which has an impurity concentration lower than that of the high concentration region, and
the second polarity region forms the pn-junction portion with the low concentration region of the first polarity region.

4. The semiconductor device according to claim 3,
wherein the low concentration region is constituted of a part of the body region.

5. The semiconductor device according to claim 2,
wherein the upper electrodes of the trench structures are embedded on the main surface side with respect to a bottom portion of the body region, and
the lower electrodes of the trench structures are embedded on the bottom wall side of the trench with respect to the bottom portion of the body region.

6. The semiconductor device according to claim 2,
wherein the first polarity region is fixed at the same potential as one of or both of the upper electrode and the lower electrode of the trench structures.

7. The semiconductor device according to claim 1,
wherein the insulator includes an upper insulating film which covers an upper wall surface of the trench with a first thickness and a lower insulating film which covers a lower wall surface of the trench with a second thickness exceeding the first thickness,
the upper electrode is embedded on the upper wall surface side of the trench across the upper insulating film, and
the lower electrode is embedded on the lower wall surface side of the trench across the lower insulating film.

8. The semiconductor device according to claim 1, further comprising:
a separation structure which is formed in the main surface so as to electrically separate the diode region from another region.

9. The semiconductor device according to claim 8,
wherein the separation structure includes a separation electrode which is embedded in a separation trench across a separation insulator.

10. The semiconductor device according to claim 1,
wherein the diode region is a temperature detecting region, and
the diode is a temperature-sensitive diode.

11. The semiconductor device according to claim 10,
wherein the temperature-sensitive diode has temperature characteristics in which a forward direction voltage linearly changes in response to a change in temperature.

12. The semiconductor device according to claim 10, further comprising:
a device region which is arranged in the main surface; and
a functional device which is formed in the device region;
wherein the temperature detecting region is arranged so as to be adjacent to the device region, and
the temperature-sensitive diode detects a temperature of the device region.

13. The semiconductor device according to claim 12,
wherein the temperature detecting region is arranged in a region which is surrounded by the device region.

14. The semiconductor device according to claim 12,
wherein the functional device includes a trench gate structure which has an electrode structure including an upper gate electrode and a lower gate electrode which are embedded in a gate trench across a gate insulator in an up/down direction.

15. The semiconductor device according to claim 12,
wherein the functional device includes a plural-system gate divided transistor that includes system transistors, each of which is formed in the main surface so as to be individually controlled, and that generates a single output signal by selectively controlling the system transistors.

16. The semiconductor device according to claim 1, further comprising:
a device region which is arranged in the main surface; and
a functional device which is formed in the device region;
wherein the diode region is a protection region, and
the diode is an electrostatic breakdown protection diode.

17. The semiconductor device according to claim 16, further comprising:
a terminal electrode which is arranged on the main surface so as to be electrically connected to the functional device;
wherein the electrostatic breakdown protection diode is electrically connected to the terminal electrode.

18. A semiconductor device comprising:
a chip which has a main surface;
a temperature detecting region which is arranged in the main surface;
a protection region which is arranged in a region different from the temperature detecting region in the main surface;
first trench structures which are formed in the main surface at an interval in the temperature detecting region, the first trench structures each having an electrode structure including a first upper electrode and a first lower electrode which are embedded in a first trench across a first insulator in an up/down direction;
a temperature-sensitive diode which has a first pn-junction portion that is formed in a surface layer portion of the main surface at a region between the first trench structures;
second trench structures which are formed in the main surface at an interval in the protection region, the second trench structures each having an electrode structure including a second upper electrode and a second lower electrode which are embedded in a second trench across a second insulator in an up/down direction; and
an electrostatic breakdown protection diode that has a second pn-junction portion which is formed in the surface layer portion of the main surface at a region between the second trench structures.

19. The semiconductor device according to claim 1, further comprising:
a control region which is arranged in the main surface; and
a control circuit which is formed in the control region.

20. A semiconductor module comprising:
the semiconductor device according to claim 1; and
a control device which is electrically connected to the semiconductor device and controls the semiconductor device.
